(19) United States
(12) Patent Application Publication
(10) Pub. No.: US 2026/0268967 A1
(43) Pub. Date: Sep. 10, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Masashi FUJITA, Fuchu, Tokyo (JP); Yoshiyuki KUROKAWA, Sagamihara, Kanagawa (JP); Hiromichi GODO, Isehara, Kanagawa (JP)

(21) Appl. No.: 19/165,660

(22) PCT Filed: Mar. 18, 2024
(86) PCT No.: PCT/IB2024/052582

§ 371 Date: Sep. 16, 2025

(30) Foreign Application Priority Data
Mar. 24, 2023 (JP) 2023-048424

(51) Int. Cl. G11C 11/417; G11C 11/4074; H10D 1/68; H10D 30/67; H10D 86/40; H10D 86/80; H10W 20/41

(52) U.S. Cl. CPC G11C 11/417; G11C 11/4074; H10D 30/6706; H10D 30/6728; H10D 30/6731; H10D 30/6736; H10D 86/481; H10D 86/80; H10W 20/435; H10D 1/716

(57) ABSTRACT

A novel semiconductor device is provided. A power management portion and a data retention portion are provided in a first layer; a setting information retention portion, a power switch portion, and a backup portion are provided in a second layer over the first layer; the data retention portion has a function of retaining data; the power management portion has a function of supplying an instruction for controlling power gating to the power switch portion and supplying, to the setting information retention portion, setting information indicating whether to block power supply to the data retention portion by the power gating; the setting information retention portion has a function of retaining the setting information supplied from the power management portion; the power switch portion has a function of switching whether to block power supply to the data retention portion on the basis of the instruction and the setting information retained in the setting information retention portion; and the backup portion has a function of storing and retaining the data on the basis of a signal supplied from the power management portion.

### TECHNICAL FIELD

One embodiment of the present invention relates to a semiconductor device.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Specific examples of the technical field of one embodiment of the present invention disclosed in this specification and the like include a semiconductor device, a display apparatus, a light-emitting apparatus, a power storage device, an optical device, an imaging device, a lighting device, an arithmetic device, a control device, a memory device, an input device, an output device, an input/output device, a signal processing device, an arithmetic processing device, an electronic computer, an electronic device, driving methods thereof, and manufacturing methods thereof.

### BACKGROUND ART

It is known that the off-state current in the non-conduction state of a transistor including an oxide semiconductor in a channel formation region is extremely small. For example, Patent Document 1 discloses a low-power-consumption arithmetic processing device (e.g., CPU) utilizing a feature of a low off-state current of the transistor. Furthermore, for example, Patent Document 2 discloses a memory device (e.g., a main memory and a cache memory) that can retain stored contents for a long time by utilizing a feature of a low off-state current of the transistor.

The arithmetic processing device can reduce power consumption by way of power gating or the like by having a structure capable of backing up or recovering data retained in a flip-flop or the like, for example.

### REFERENCES

### Patent Documents

[Patent Document 1] Japanese Published Patent Application No. 2012-257187
[Patent Document 2] Japanese Published Patent Application No. 2011-151383

### SUMMARY OF THE INVENTION

### Problems to Be Solved by the Invention

In the case where a CPU has an unused register in some uses or under some processing conditions, for example, power is consumed by current consumption in a standby state (also referred to as static current consumption) of a flip-flop included in the register. Therefore, blocking power supply to the flip-flop can reduce power consumption.

An object of one embodiment of the present invention is to provide a semiconductor device with low power consumption. Another object of one embodiment of the present invention is to provide a semiconductor device with an increased operating speed. Another object of one embodiment of the present invention is to provide a miniaturized semiconductor device. Another object of one embodiment of the present invention is to provide a highly reliable semiconductor device. Another object of one embodiment of the present invention is to provide a novel semiconductor device.

Note that the description of the above objects does not preclude the existence of other objects. One embodiment of the present invention does not necessarily achieve all the above objects. Objects other than the objects listed above are apparent from the description of the specification, the drawings, the claims, and the like and can be derived from the description of the specification, the drawings, the claims, and the like.

### Means for Solving the Problems

(1)

One embodiment of the present invention is a semiconductor device including a power management portion, a setting information retention portion, a power switch portion, a data retention portion, and a backup portion. The power management portion and the data retention portion are provided in a first layer; the setting information retention portion, the power switch portion, and the backup portion are provided in a second layer over the first layer; the data retention portion has a function of retaining data; the power management portion has a function of supplying an instruction for controlling power gating to the power switch portion and supplying, to the setting information retention portion, setting information indicating whether to block power supply to the data retention portion by the power gating; the setting information retention portion has a function of retaining the setting information supplied from the power management portion; the power switch portion has a function of switching whether to block power supply to the data retention portion on the basis of the instruction and the setting information retained in the setting information retention portion; and the backup portion has a function of storing and retaining the data on the basis of a signal supplied from the power management portion.
(2)

In the above (1), at least part of the backup portion may be provided to overlap the data retention portion.
(3)

In the above (1), at least part of the power switch portion may be provided to overlap the data retention portion.
(4)

In any one of the above (1) to (3), transistors included in the setting information retention portion, the power switch portion, and the backup portion may include an oxide semiconductor in channel formation regions.
(5)

One embodiment of the present invention is a semiconductor device including a power management portion, a setting information retention portion, a power switch portion, a data retention portion, and a backup portion. The power management portion and the data retention portion are provided in a first layer; the setting information retention portion, the power switch portion, and the backup portion are provided in a second layer over the first layer; the data retention portion has a function of retaining data; the power management portion has a function of supplying an instruction for controlling power gating to the power switch portion and supplying, to the setting information retention portion, setting information indicating whether to block power supply to the data retention portion by the power gating; the setting information retention portion includes a first transistor and a first capacitor; one of a source and a drain of the first transistor is electrically connected to one terminal of the first capacitor; a first potential based on the setting information supplied from the power management portion is supplied to the other of the source and the drain of the first transistor; a signal which controls the conduction state of the first transistor is supplied from the power management portion to a gate of the first transistor; a second potential corresponding to the first potential is retained in the one terminal of the first capacitor; the power switch portion includes a second transistor and a third transistor; a gate of the second transistor is electrically connected to one of a source and a drain of the third transistor; one of a source and a drain of the second transistor is electrically connected to a first wiring through which a third potential is supplied; the other of the source and the drain of the second transistor is electrically connected to a second wiring for supplying a fourth potential corresponding to the third potential to the data retention portion; a signal based on the instruction is supplied to the other of the source and the drain of the third transistor; a signal based on the second potential is supplied to a gate of the third transistor; the backup portion includes a fourth transistor, a fifth transistor, and a second capacitor; one of a source and a drain of the fourth transistor is electrically connected to one of a source and a drain of the fifth transistor and one terminal of the second capacitor; the other of the source and the drain of the fourth transistor is electrically connected to the data retention portion through a third wiring; the other of the source and the drain of the fifth transistor is electrically connected to the data retention portion through a fourth wiring; a signal which controls the conduction state of the fourth transistor is supplied from the power management portion to a gate of the fourth transistor; a signal which controls the conduction state of the fifth transistor is supplied from the power management portion to a gate of the fifth transistor; and a fifth potential corresponding to the data is retained in the one terminal of the second capacitor.
(6)

In the above (5), at least part of the backup portion may be provided to overlap the data retention portion.
(7)

In the above (5), at least part of the power switch portion may be provided to overlap the data retention portion.
(8)

In any one of the above (5) to (7), the first transistor, the second transistor, the third transistor, the fourth transistor, and the fifth transistor may include an oxide semiconductor in channel formation regions.
(9)

One embodiment of the present invention is a semiconductor device including a power management portion, a setting information retention portion, a power switch portion, a data retention portion, and a backup portion. The power management portion, the power switch portion, and the data retention portion are provided in a first layer; the setting information retention portion and the backup portion are provided in a second layer over the first layer; the data retention portion has a function of retaining data; the power management portion has a function of supplying an instruction for controlling power gating to the power switch portion and supplying, to the setting information retention portion, setting information indicating whether to block power supply to the data retention portion by the power gating; the setting information retention portion has a function of retaining the setting information supplied from the power management portion; the power switch portion has a function of switching whether to block power supply to the data retention portion on the basis of the instruction and the setting information retained in the setting information retention portion; and the backup portion has a function of storing and retaining the data on the basis of a signal supplied from the power management portion.
(10)

In the above (9), at least part of the backup portion may be provided to overlap the data retention portion.
(11)

In the above (9), at least part of the setting information retention portion may be provided to overlap the power switch portion.
(12)

In any one of the above (9) to (11), transistors included in the setting information retention portion and the backup portion may include an oxide semiconductor in channel formation regions.
(13)

One embodiment of the present invention is a semiconductor device including a power management portion, a setting information retention portion, a power switch portion, a data retention portion, and a backup portion. The power management portion, the power switch portion, and the data retention portion are provided in a first layer; the setting information retention portion and the backup portion are provided in a second layer over the first layer; the data retention portion has a function of retaining data; the power management portion has a function of supplying an instruction for controlling power gating to the power switch portion and supplying, to the setting information retention portion, setting information indicating whether to block power supply to the data retention portion by the power gating; the setting information retention portion includes a first transistor and a first capacitor; one of a source and a drain of the first transistor is electrically connected to one terminal of the first capacitor; a first potential based on the setting information supplied from the power management portion is supplied to the other of the source and the drain of the first transistor; a signal which controls the conduction state of the first transistor is supplied from the power management portion to a gate of the first transistor; a second potential corresponding to the first potential is retained in the one terminal of the first capacitor; the power switch portion includes a second transistor and a third transistor; a gate of the second transistor is electrically connected to one of a source and a drain of the third transistor; one of a source and a drain of the second transistor is electrically connected to a first wiring through which a third potential is supplied; the other of the source and the drain of the second transistor is electrically connected to a second wiring for supplying a fourth potential corresponding to the third potential to the data retention portion; a signal based on the instruction is supplied to the other of the source and the drain of the third transistor; a signal based on the second potential is supplied to a gate of the third transistor; the backup portion includes a fourth transistor, a fifth transistor, and a second capacitor; one of a source and a drain of the fourth transistor is electrically connected to one of a source and a drain of the fifth transistor and one terminal of the second capacitor; the other of the source and the drain of the fourth transistor is electrically connected to the data retention portion through a third wiring; the other of the source and the drain of the fifth transistor is electrically connected to the data retention portion through a fourth wiring; a signal which controls the conduction state of the fourth transistor is supplied from the power management portion to a gate of the fourth transistor; a signal which controls the conduction state of the fifth transistor is supplied from the power management portion to a gate of the fifth transistor; and a fifth potential corresponding to the data is retained in the one terminal of the second capacitor.
(14)

In the above (13), at least part of the backup portion may be provided to overlap the data retention portion.
(15)

In the above (13), at least part of the setting information retention portion may be provided to overlap the power switch portion.
(16)

In any one of the above (13) to (15), the first transistor, the fourth transistor, and the fifth transistor may include an oxide semiconductor in channel formation regions.

### Effect of the Invention

One embodiment of the present invention can provide a semiconductor device with low power consumption. One embodiment of the present invention can provide a semiconductor device with an increased operating speed. One embodiment of the present invention can provide a miniaturized semiconductor device. One embodiment of the present invention can provide a highly reliable semiconductor device. One embodiment of the present invention can provide a novel semiconductor device.

Note that the descriptions of the above effects do not preclude the existence of other effects. One embodiment of the present invention does not necessarily achieve all the above effects. Effects other than the effects listed above are apparent from the description of the specification, the drawings, the claims, and the like and can be derived from the description of the specification, the drawings, the claims, and the like.

### BRIEF DESCRIPTION OF THE DRAWINGS

FIG. 1A is a block diagram illustrating a structure example of a semiconductor device. FIG. 1B is a schematic diagram illustrating a structure example of the semiconductor device.

FIG. 2A is a block diagram illustrating a structure example of a semiconductor device. FIG. 2B is a schematic diagram illustrating a structure example of the semiconductor device.

FIG. 3 is a block diagram illustrating a structure example of a semiconductor device.

FIG. 4A to FIG. 4E are circuit diagrams illustrating structure examples of a semiconductor device.

FIG. 5 is a circuit diagram illustrating a structure example of a semiconductor device.

FIG. 6A to FIG. 6H are circuit diagrams illustrating structure examples of a semiconductor device.

FIG. 7 is a timing chart showing an operation example of a semiconductor device.

FIG. 8 is a timing chart showing an operation example of a semiconductor device.

FIG. 9A is a block diagram illustrating a structural example of an electronic computer. FIG. 9B is a timing chart showing an operation example of the electronic computer.

FIG. 10A is a block diagram illustrating a structural example of an electronic computer. FIG. 10B and FIG. 10C are timing charts showing operation examples of the electronic computer.

FIG. 11 is a diagram illustrating a structure example of a semiconductor device.

FIG. 12A to FIG. 12C are diagrams illustrating a structure example of a semiconductor device.

FIG. 13 is a diagram illustrating a structure example of a semiconductor device.

FIG. 14A is a top view illustrating an example of a semiconductor device. FIG. 14B to FIG. 14D are cross-sectional views illustrating the example of the semiconductor device.

FIG. 15 is a cross-sectional view illustrating an example of a semiconductor device.

FIG. 16A to FIG. 16C are diagrams illustrating a structure example of a semiconductor device.

FIG. 17A and FIG. 17B are diagrams illustrating a structure example of a semiconductor device. FIG. 18 is a block diagram illustrating a structure example of a semiconductor device.

FIG. 19A to FIG. 19H are diagrams illustrating circuit structure examples of a memory cell.

FIG. 20A and FIG. 20B are perspective views illustrating structure examples of a semiconductor device.

FIG. 21 is a block diagram illustrating a CPU.

FIG. 22A and FIG. 22B are perspective views illustrating a semiconductor device.

FIG. 23A and FIG. 23B are perspective views each illustrating a semiconductor device.

FIG. 24A and FIG. 24B are diagrams each showing a hierarchy of a variety of memory devices.

FIG. 25A and FIG. 25B are diagrams illustrating examples of electronic components.

FIG. 26A and FIG. 26B are diagrams illustrating examples of an electronic device. FIG. 26C to FIG. 26E are diagrams illustrating examples of a large computer.

FIG. 27 is a diagram illustrating an example of a device for space.

FIG. 28 is a diagram illustrating an example of a storage system that can be used for a data center.

### MODE FOR CARRYING OUT THE INVENTION

In this specification and the like, a semiconductor device refers to a device that utilizes semiconductor characteristics, and means a circuit including a semiconductor element (e.g., a transistor or a diode) or a device including the circuit, for example. The semiconductor device also means any device that can function by utilizing semiconductor characteristics. For example, an integrated circuit including a semiconductor element, a chip provided with an integrated circuit, an electronic component including a packaged chip, and an electronic device provided with an electronic component are examples of a semiconductor device. For example, a display apparatus, a light-emitting apparatus, a power storage device, an optical device, an imaging device, a lighting device, an arithmetic device, a control device, a memory device, an input device, an output device, an input/output device, a signal processing device, an electronic computer, an electronic device, and the like themselves might be semiconductor devices, or might include semiconductor devices.

Embodiments are described below with reference to the drawings. Note that the embodiments can be implemented in many different modes. Thus, it will be readily understood by those skilled in the art that the modes and details can be changed in various ways without departing from the spirit and scope thereof. Thus, one embodiment of the present invention should not be interpreted as being limited to the description in the embodiments.

In this specification and the like, one embodiment of the present invention can be constituted by appropriately combining a structure described in an embodiment with any of the structures described in the other embodiments. In addition, in the case where a plurality of structures are described in one embodiment, the structures can be combined with each other as appropriate to constitute one embodiment of the present invention.

As for the drawings illustrating the embodiments, in the structures of the invention, the same reference numerals are used in common for the same portions or portions having similar functions in different drawings, and repeated description thereof is omitted in some cases. Furthermore, for example, the same hatching pattern is used for the portions having similar functions throughout the drawings, and the portions are not especially denoted by reference numerals in some cases. Moreover, some components are omitted in a perspective view or a top view (also referred to as a “plan view”), for example, for easy understanding of the drawings in some cases. For example, some hidden lines might also be omitted in the drawings. For example, a hatching pattern or the like might be omitted in the drawings.

In the drawings, the size, the layer thickness, or the region is exaggerated for clarity in some cases. Thus, the drawings are not limited to the drawings with the shown size, aspect ratio, and the like, for example. Note that the drawings schematically show ideal examples, and embodiments of the present invention are not limited to shapes, values, and the like shown in the drawings, for example. For example, in the actual manufacturing process, a layer, a resist mask, or the like might be unintentionally reduced in size by treatment such as etching, which is not shown in the drawings in some cases for easy understanding. For example, in the actual circuit operation, a fluctuation in voltage, current, or the like might be caused by noise, difference in timing, or the like, which is not shown in some cases for easy understanding.

In this specification, the drawings, and the like, components are classified on the basis of the functions, and shown as elements independent of one another in some cases. However, such components are sometimes hard to classify functionally, and there are a case where one component is associated with a plurality of functions and a case where a plurality of components are associated with one function. Accordingly, the component is not limited to that described in this specification, the drawings, and the like and can be explained with another term as appropriate depending on the situation.

In this specification, the drawings, and the like, when a plurality of components are denoted by the same reference numerals, and in particular need to be distinguished from each other, an identification sign such as “A”, “b”, “_1”, “[n]”, or “[m, n]” is sometimes added to the reference numerals, for example. When matters common to a plurality of components with identification signs are described or they do not need to be distinguished from each other, no identification sign is added in some cases.

Note that in this specification and the like, a “conduction state” or an “on state” of a transistor refers to a state where a source and a drain of the transistor can be regarded as being electrically short-circuited or a state where a current can be made to flow between the source and the drain. For example, the “conduction state” or the “on state” refers to a state where a voltage between a gate and a source is higher than a threshold voltage in an n-channel transistor, a state where a voltage between a gate and a source is lower than a threshold voltage in a p-channel transistor, or the like in some cases. A “non-conduction state”, a “cutoff state”, or an “off state” of a transistor refers to a state where a source and a drain of the transistor can be regarded as being electrically disconnected. For example, the “non-conduction state”, the “cutoff state”, or the “off state” refers to a state where a voltage between a gate and a source is lower than a threshold voltage in an n-channel transistor, a state where a voltage between a gate and a source is higher than a threshold voltage in a p-channel transistor, or the like in some cases.

In this specification and the like, a “gate voltage” refers to a voltage between a gate and a source, a “drain voltage” refers to a voltage between a drain and a source, and a “back gate voltage” refers to a voltage between a back gate and a source in some cases. In addition, a “drain current” refers to a current flowing between a drain and a source in some cases. The terms “high gate voltage,” “high drain voltage,” “high back gate voltage,” and the like of an n-channel transistor can be replaced with the terms “low gate voltage,” “low drain voltage,” “low back gate voltage,” and the like of a p-channel transistor, respectively, as appropriate in some cases. The terms “low gate voltage,” “low drain voltage,” “low back gate voltage,” and the like of an n-channel transistor can be replaced with the terms “high gate voltage,” “high drain voltage,” “high back gate voltage,” and the like of a p-channel transistor, respectively, as appropriate in some cases.

In this specification and the like, “off-state current” of a transistor refers to a drain current of the transistor in the off state unless otherwise specified. Note that in this specification and the like, an off-state current and a current flowing between a gate and a source/drain (also referred to as a gate leakage current) are sometimes referred to as a leakage current.

### Embodiment 1

A semiconductor device of one embodiment of the present invention will be described with reference to drawings. At least part of the semiconductor device of one embodiment of the present invention can be used in an electronic computer (also referred to as a computer in some cases), for example.

### Structure Example

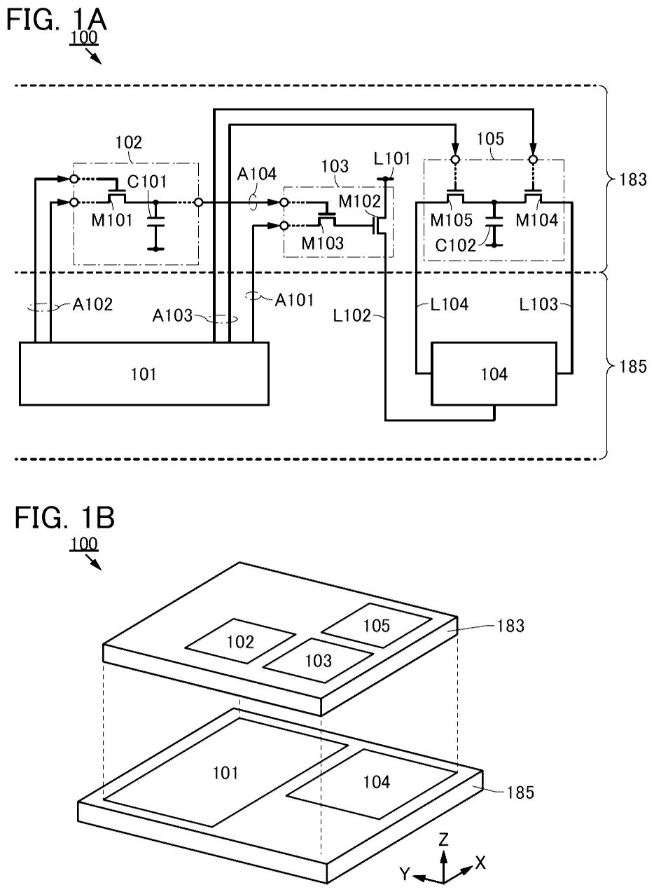

FIG. 1A is a block diagram illustrating a structure example of a semiconductor device 100 of one embodiment of the present invention.

As illustrated in FIG. 1A, the semiconductor device 100 includes a power management portion 101, a setting information retention portion 102, a power switch portion 103, a data retention portion 104, and a backup portion 105.

The power management portion 101 has a function of controlling power gating of the data retention portion 104. For example, the power management portion 101 has a function of supplying an instruction for controlling power gating to the power switch portion 103 (corresponding to an arrow A101). The power management portion 101 also has a function of supplying, to the setting information retention portion 102, setting information indicating whether to block power supply to the data retention portion 104 by power gating (corresponding to an arrow A102). In addition, the power management portion 101 has a function of supplying, to the backup portion 105, a signal for backing up data retained in the data retention portion 104 (corresponding to an arrow A103).

The setting information retention portion 102 has a function of storing and retaining the setting information supplied from the power management portion 101. The setting information retention portion 102 also has a function of supplying, to the power switch portion 103, a signal based on the setting information retained in the setting information retention portion 102 (corresponding to an arrow A104).

The setting information retention portion 102 includes a transistor M101 and a capacitor C101. One of a source and a drain of the transistor M101 is electrically connected to one terminal of the capacitor C101. The other terminal of the capacitor C101 is electrically connected to a wiring to which a constant potential is supplied.

In the setting information retention portion 102, a potential of a signal based on the setting information supplied from the power management portion 101 is supplied to the other of the source and the drain of the transistor M101, for example. In addition, a potential of a signal which controls the conduction state of the transistor M101 is supplied from the power management portion 101 to a gate of the transistor M101. The potential of the signal based on the setting information is stored and retained in the one terminal of the capacitor C101 in accordance with the potential of the signal supplied to the gate of the transistor M101. That is, the setting information is stored and retained in the setting information retention portion 102.

When the potential of the signal based on the setting information is retained in the setting information retention portion 102, the potential may vary owing to parasitic capacitance such as the gate capacitance of the transistor M101, for example. That is, the potential retained at the one terminal of the capacitor C101 corresponds to the potential of the signal based on the setting information.

Thus, the electrostatic capacitance of the capacitor C101 may be made larger than the parasitic capacitance such as the gate capacitance of the transistor M101 so that the variation amount of the potential can be smaller than the threshold voltage of the transistor M101 or the like, for example.

The power switch portion 103 has a function of switching whether to block power supply to the data retention portion 104 on the basis of the instruction supplied from the power management portion 101 and the setting information retained in the setting information retention portion 102.

The power switch portion 103 includes a transistor M102 and a transistor M103. A gate of the transistor M102 is electrically connected to one of a source and a drain of the transistor M103.

One of a source and a drain of the transistor M102 is electrically connected to a wiring L101 to which a power supply potential is supplied. The other of the source and the drain of the transistor M102 is electrically connected to a wiring L102 for supplying the power supply potential to the data retention portion 104.

In the power switch portion 103, the potential of the signal based on the instruction supplied from the power management portion 101 is supplied to the other of the source and the drain of the transistor M103, for example. In addition, the potential of the signal based on the setting information retained in the setting information retention portion 102 (i.e., the potential retained at the one terminal of the capacitor C101) is supplied to a gate of the transistor M103. That is, a potential of a signal which controls the conduction state of the transistor M102 is supplied to the gate of the transistor M102 on the basis of the instruction and the setting information.

When the transistor M102 is brought into the conduction state, the power supply potential supplied to the wiring L101 is supplied to the wiring L102. Then, the power supply potential is supplied to the data retention portion 104. That is, power is supplied. Alternatively, the transistor M102 is brought into the non-conduction state, in which case the wiring L102 is brought into a floating state (also referred to as floating in some cases). Then, power supply to the data retention portion 104 is blocked.

An n-channel transistor can be used as the transistor M102, for example. In the case where an n-channel transistor is used as the transistor M102 in the semiconductor device 100, whether to block supply of a low power supply potential to the data retention portion 104 can be controlled, for example.

Note that when the power supply potential supplied to the wiring L101 is supplied to the wiring L102 in the power switch portion 103, the power supply potential may vary (voltage drop may occur) owing to parasitic resistance such as on-state resistance of the transistor M102, for example. That is, the power supply potential supplied to the wiring L102 corresponds to the power supply potential supplied to the wiring L101.

With this being the case, for example, the on-state resistance of the transistor M102 may be made lower than those of the other transistors included in the semiconductor device 100 so that the variation amount of the power supply potential can be sufficiently small. That is, for example, the channel width of the transistor M102 may be made larger than those of the other transistors included in the semiconductor device 100.

Specifically, the on-state resistance of the transistor M102 may be lower than that of each of the transistor M101, the transistor M103, a transistor M104, and a transistor M105, for example. That is, for example, the channel width of the transistor M102 may be larger than that of each of the transistor M101, the transistor M103, the transistor M104, and the transistor M105.

For another example, the on-state resistance of the transistor M102 may be lower than that of each of the transistors included in the power management portion 101 and the data retention portion 104. That is, for example, the channel width of the transistor M102 may be larger than that of each of the transistors included in the power management portion 101 and the data retention portion 104.

The data retention portion 104 has a function of storing and retaining data. For example, in the case where the semiconductor device 100 is used in an electronic computer, the data retention portion 104 can have a function of a register. That is, the data retention portion 104 can include a flip-flop circuit prepared in a standard circuit library, for example.

The backup portion 105 has a function of storing and retaining the data retained in the data retention portion 104 on the basis of the signal supplied from the power management portion 101.

The backup portion 105 includes the transistor M104, the transistor M105, and a capacitor C102. One of a source and a drain of the transistor M104 is electrically connected to one of a source and a drain of the transistor M105 and one terminal of the capacitor C102. The other terminal of the capacitor C102 is electrically connected to a wiring to which a constant potential is supplied.

The other of the source and the drain of the transistor M104 is electrically connected to the data retention portion 104 through a wiring L103. The other of the source and the drain of the transistor M105 is electrically connected to the data retention portion 104 through a wiring L104.

In the backup portion 105, a potential of a signal which controls the conduction state of the transistor M104 is supplied from the power management portion 101 to a gate of the transistor M104, for example. In accordance with the potential of the signal, the data retained in the data retention portion 104 is written to and retained in the backup portion 105 through the wiring L103. That is, a potential corresponding to the data retained in the data retention portion 104 is written to and retained in the one terminal of the capacitor C102.

Moreover, a potential of a signal which controls the conduction state of the transistor M105 is supplied from the power management portion 101 to a gate of the transistor M105, for example. In accordance with the potential of the signal, the data retained in the backup portion 105 (i.e., the potential retained at the one terminal of the capacitor C102) is written back to the data retention portion 104 through the wiring L104.

Note that when the potential corresponding to the data retained in the data retention portion 104 is retained in the backup portion 105, the potential may vary owing to parasitic capacitance such as the gate capacitance of the transistor M104 and the gate capacitance of the transistor M105, for example.

Thus, the electrostatic capacitance of the capacitor C102 may be made larger than the parasitic capacitance such as the gate capacitance of the transistor M104 and the gate capacitance of the transistor M105 so that the variation amount of the potential can be smaller than the threshold voltages of the transistor M104, the transistor M105, and the like, for example.

FIG. 1B is a schematic diagram illustrating an example of the layer structure of the semiconductor device 100 and the placement of components.

As illustrated in FIG. 1B, the semiconductor device 100 includes a layer 185 and a layer 183. The layer 183 is provided to be stacked over the layer 185.

Note that in the following description, the X direction, the Y direction, and the Z direction are defined for easy understanding of the positional relationship of components. The X direction, the Y direction, and the Z direction are perpendicular to each other. The Z direction refers to the direction in which the layer 183 is stacked over the layer 185. The X direction and the Y direction are the directions along the surfaces of the layer 185 and the layer 183. Note that in this specification and the like, the Z direction may be referred to as the vertical direction or the height direction.

Each of the layer 185 and the layer 183 can include a variety of materials such as a conductor, a semiconductor, and an insulator, for example. A variety of elements such as a capacitor and a transistor can be provided in each of the layer 185 and the layer 183, for example.

For example, a transistor including a single crystal semiconductor, a polycrystalline semiconductor, a microcrystalline semiconductor, or an amorphous semiconductor in a channel formation region can be used as the transistor provided in each of the layer 185 and the layer 183. Furthermore, as the semiconductor, for example, a compound semiconductor (e.g., silicon germanium or gallium arsenide), an oxide semiconductor, or the like as well as a single element semiconductor whose main component is a single element (e.g., silicon or germanium) can be used.

Transistors of a variety of kinds can be used as the transistor. For example, a MOS field-effect transistor, a junction field-effect transistor, a bipolar transistor, or the like can be used.

A transistor with any of a variety of other structures can be used as the transistor. For example, a transistor having any of a variety of structures such as a planar type, a staggered type, a FIN-type, a TRI-GATE type, a top-gate type, a bottom-gate type, and a dual-gate type (a structure in which gates are placed on the opposite sides with a channel formation region therebetween (placed above and below the channel formation region, for example)) can be used. For example, a vertical transistor (a transistor whose channel length direction is in the vertical direction (also referred to as the height direction or the direction perpendicular to a formation surface)) can be used.

Note that a semiconductor including a channel formation region of the transistor provided in the layer 185 and a semiconductor including a channel formation region of the transistor provided in the layer 183 may contain the same material or different materials. The transistor provided in the layer 185 and the transistor provided in the layer 183 may have the same structure or different structures.

In one embodiment of the present invention, the layer 185 can be provided in a substrate containing silicon. That is, a Si transistor (a transistor including silicon in a channel formation region) can be provided in the layer 185. For example, by electrically connecting a gate of an n-channel Si transistor and a gate of a p-channel Si transistor in the layer 185, a CMOS circuit (e.g., a circuit that operates complementarily, a CMOS logic gate, a CMOS logic circuit, or the like) can be formed.

Furthermore, in one embodiment of the present invention, an OS transistor (a transistor including an oxide semiconductor in a channel formation region) can be provided in the layer 183. An OS transistor features an extremely low off-state current because the band gap of the oxide semiconductor where the channel is formed is greater than or equal to 2 eV. The off-state current value per micrometer of channel width of an OS transistor in a room-temperature environment can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor in a room-temperature environment is higher than or equal to 1 fA (1×10⁻¹⁵ A) and lower than or equal to 1 pA (1×10⁻¹² A). Thus, the off-state current of an OS transistor is lower than that of a Si transistor by approximately ten orders of magnitude. Thus, for example, in the case where a wiring electrically connected to one of a source and a drain of the OS transistor is floating, charge accumulated in the wiring can be retained for a long period. When a memory cell is formed using an OS transistor, data written to the memory cell can be retained for a long period, for example.

The off-state current of an OS transistor hardly increases even in a high-temperature environment. Specifically, the off-state current hardly increases even at an environment temperature higher than or equal to room temperature and lower than or equal to 200° C. Furthermore, the on-state current of an OS transistor is unlikely to decrease even in a high-temperature environment. Meanwhile, the on-state current of a Si transistor decreases in a high-temperature environment. That is, an OS transistor has a higher on-state current than a Si transistor in a high-temperature environment. In an OS transistor, the ratio between on-state current and off-state current is large even at an environmental temperature higher than or equal to 125° C. and lower than or equal to 150° C.; thus, an excellent switching operation can be performed. Accordingly, a semiconductor device including an OS transistor achieves a stable operation and high reliability even in a high-temperature environment.

Moreover, the OS transistor has high source-drain breakdown voltage (also referred to as drain breakdown voltage). Accordingly, a semiconductor device including an OS transistor achieves a stable operation and high reliability even when being driven with high voltage.

Although not illustrated, the semiconductor device 100 may have a structure in which a wiring layer is provided as appropriate between the layer 185 and the layer 183. The wiring layer can be provided with a wiring for electrically connecting various elements, for example.

In the semiconductor device 100 of one embodiment of the present invention, the power management portion 101 and the data retention portion 104 can be provided in the layer 185, and the setting information retention portion 102, the power switch portion 103, and the backup portion 105 can be provided in the layer 183, for example. That is, the semiconductor device 100 can include the power management portion 101 and the data retention portion 104 which are provided in the layer 185, and the setting information retention portion 102, the power switch portion 103, and the backup portion 105 which are provided in the layer 183 over the layer 185. Thus, Si transistors can be used for the power management portion 101 and the data retention portion 104, and OS transistors can be used for the setting information retention portion 102, the power switch portion 103, and the backup portion 105, for example.

In the semiconductor device, at least part of the setting information retention portion 102 can be provided to overlap the power management portion 101 or the data retention portion 104, or can be provided not to overlap the power management portion 101 or the data retention portion 104. Furthermore, at least part of the power switch portion 103 can be provided to overlap the power management portion 101 or the data retention portion 104, or can be provided not to overlap the power management portion 101 or the data retention portion 104. Furthermore, at least part of the backup portion 105 can be provided to overlap the power management portion 101 or the data retention portion 104, or can be provided not to overlap the power management portion 101 or the data retention portion 104.

One embodiment of the present invention can have a structure in which at least part of the backup portion 105 is provided to overlap the data retention portion 104 in the semiconductor device 100, for example. With such a structure, the distance between wirings electrically connected to each other (the wiring L103 and the wiring L104) can be shortened. Thus, energy (access energy) necessary for writing data from the data retention portion 104 to the backup portion 105 and writing back data from the backup portion 105 to the data retention portion 104 can be reduced. Thus, power consumption due to power gating in the semiconductor device 100 can be reduced.

For another example, at least part of the setting information retention portion 102 and at least part of the power switch portion 103 can be provided to overlap the data retention portion 104. With such a structure, the setting information retention portion 102 and the power switch portion 103 can be placed near the data retention portion 104.

Here, in the semiconductor device 100, the power switch portion 103 is preferably placed near the data retention portion 104. This can shorten a wiring for supplying a power supply potential to the data retention portion 104 (the wiring L102). Thus, the influence of a voltage drop due to parasitic resistance (also referred to as IR drop in some cases) can be reduced. Accordingly, the semiconductor device can be miniaturized and power consumption of the semiconductor device can be reduced.

The setting information retention portion 102 is preferably placed near the power switch portion 103. This can inhibit signal delay of a signal based on the setting information supplied from the setting information retention portion 102 to the power switch portion 103. Thus, the number of buffers for inhibiting the signal delay can be reduced. Furthermore, a leakage current due to the buffers can be reduced. Accordingly, the semiconductor device can be miniaturized and power consumption of the semiconductor device can be reduced.

The number of buffers can be, for example, less than or equal to 8, less than or equal to 4, less than or equal to 2, or 1. Alternatively, a structure that does not include any buffer can be employed.

The distance between the setting information retention portion 102 and the power switch portion 103 can be, for example, greater than or equal to 1 time and less than or equal to 64 times, less than or equal to 16 times, or less than or equal to 4 times the minimum feature size of wirings.

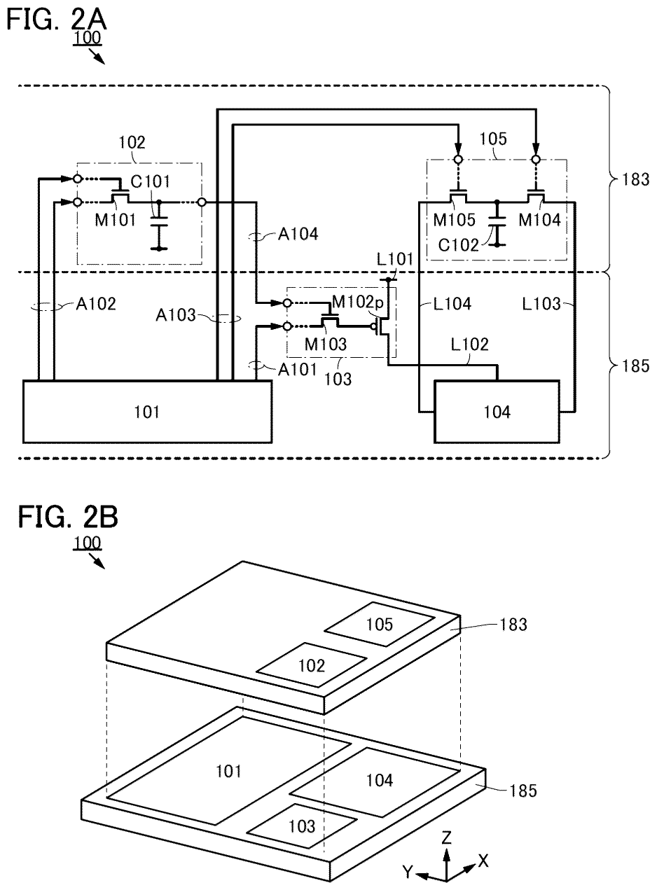

FIG. 2A and FIG. 2B are a block diagram and a schematic diagram illustrating a variation example of the semiconductor device 100.

The semiconductor device 100 illustrated in FIG. 2A and FIG. 2B is different from the semiconductor device 100 illustrated in FIG. 1A and FIG. 1B in that the power switch portion 103 is provided in the layer 185, and in that a transistor M102p is included instead of the transistor M102 in the power switch portion 103.

As the transistor M102p, a p-channel transistor can be used, for example. In the case where a p-channel transistor is used as the transistor M102p, whether to block supply of a high power supply potential to the data retention portion 104 can be controlled, for example. With such a structure, supply of a low power supply potential to the data retention portion 104 can be stabilized and the operation of the data retention portion 104 can be stabilized. Accordingly, the reliability of the semiconductor device can be increased.

In the case where the on-state resistance of an n-channel transistor is lower than that of a p-channel transistor of the same size as the n-channel transistor, the n-channel transistor may be used as the transistor M102p, for example. In the case of using an n-channel transistor, the channel width of the transistor M102p can be smaller than that of the case of using a p-channel transistor. Accordingly, the semiconductor device can be miniaturized.

In the case where an n-channel transistor is used as the transistor M102p in the semiconductor device 100, a structure capable of controlling whether to block supply of a low power supply potential to the data retention portion 104 may be employed, for example.

The semiconductor device 100 may include, instead of the transistor M103, an analog switch including an n-channel transistor and a p-channel transistor in the power switch portion 103. When an analog switch is used instead of the transistor M103, a variation in on-state resistance can be inhibited by the potential of a signal supplied to a gate of the transistor M102p through the analog switch. Thus, the operation of the power switch portion 103 can be stabilized. Accordingly, the reliability of the semiconductor device can be increased.

In the semiconductor device 100 of one embodiment of the present invention, the power management portion 101, the power switch portion 103, and the data retention portion 104 can be provided in the layer 185, and the setting information retention portion 102 and the backup portion 105 can be provided in the layer 183, for example. That is, the semiconductor device includes the power management portion 101, the power switch portion 103, and the data retention portion 104 which are provided in the layer 185, and the setting information retention portion 102 and the backup portion 105 which are provided in the layer 183 over the layer 185. Thus, Si transistors can be used for the power management portion 101, the power switch portion 103, and the data retention portion 104, and OS transistors can be used for the setting information retention portion 102 and the backup portion 105, for example.

In the semiconductor device, at least part of the setting information retention portion 102 can be provided to overlap the power management portion 101, the power switch portion 103, or the data retention portion 104, or can be provided not to overlap the power management portion 101, the power switch portion 103, or the data retention portion 104. Furthermore, at least part of the backup portion 105 can be provided to overlap the power management portion 101, the power switch portion 103, or the data retention portion 104, or can be provided not to overlap the power management portion 101, the power switch portion 103, or the data retention portion 104.

One embodiment of the present invention can have a structure in which at least part of the setting information retention portion 102 is provided to overlap the power switch portion 103 in the semiconductor device 100, for example. With such a structure, the setting information retention portion 102 can be placed near the power switch portion 103. Accordingly, as described above, the semiconductor device can be miniaturized and power consumption of the semiconductor device can be reduced.

### Specific Example

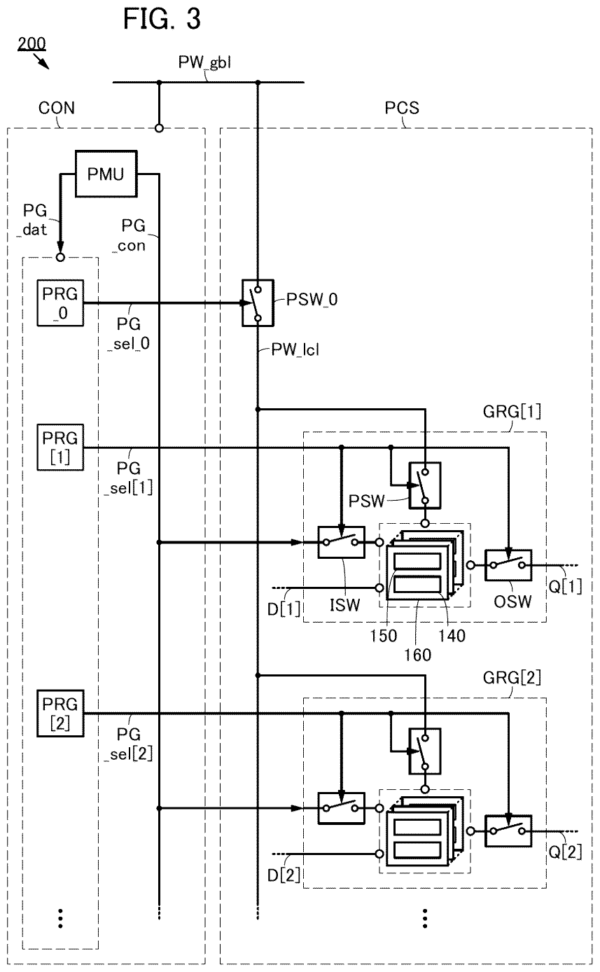

FIG. 3 is a block diagram illustrating a structure example of a semiconductor device 200 of one embodiment of the present invention. The semiconductor device 200 is a structure example of the case where the above-described semiconductor device 100 is used in an electronic computer.

As illustrated in FIG. 3, the semiconductor device 200 includes a control portion CON and an arithmetic processing portion PCS. The control portion CON includes a power management unit PMU, one or a plurality of setting registers PRG (a setting register PRG[1] and a setting register PRG[2] are representatively illustrated), and a setting register PRG_0. The arithmetic processing portion PCS includes one or a plurality of general registers GRG (a general register GRG[1] and a general register GRG[2] are representatively illustrated) and a switch circuit group PSW_0.

Although not illustrated, the arithmetic processing portion PCS includes an arithmetic portion including an arithmetic logic unit (ALU) or the like, a control portion including an instruction decoder (ID) or the like, and dedicated registers (e.g., a program counter (PC), an instruction register (IR), and a status register (SR)), for example.

Note that in one embodiment of the present invention, the structure of the general register GRG described below can also be applied to a dedicated register (not illustrated) included in the arithmetic processing portion PCS.

The general register GRG includes a register unit 160, a switch circuit group PSW, a switch circuit group ISW, and a switch circuit group OSW. The register unit 160 includes a scan flip-flop circuit 140 and a backup circuit 150.

The general register GRG can include one or a plurality of register units 160 in accordance with the number of bits of data that can be processed at a time by the arithmetic processing portion PCS (e.g., 1 bit, 2 bits, 4 bits, 8 bits, 16 bits, 32 bits, or 64 bits). Here, for easy description, description is given on the assumption that the general register GRG includes one register unit 160.

Here, the structure of the semiconductor device 200 corresponds to the above-described structure of the semiconductor device 100 illustrated in FIG. 1A and the like. That is, the power management unit PMU corresponds to the power management portion 101, the setting register PRG corresponds to the setting information retention portion 102, the switch circuit portion PSW corresponds to the power switch portion 103, the scan flip-flop circuit 140 corresponds to the data retention portion 104, and the backup circuit 150 corresponds to the backup portion 105.

Power is supplied from a power line group PW gbl to the control portion CON. In addition, power is supplied from the power line group PW_gbl to a power line group PW_lcl through the switch circuit group PSW_0. Furthermore, power is supplied from the power line group PW_lcl to the register unit 160 through the switch circuit group PSW.

A signal based on an instruction (an instruction for controlling power gating) supplied from the power management unit PMU is supplied to a wiring group PG_con. Furthermore, the signal is input from the wiring group PG_con to the register unit 160 through the switch circuit group ISW.

Data is input from a wiring D (a wiring D[1] and a wiring D[2] are representatively illustrated) to the register unit 160. In addition, data is output from the register unit 160 to a wiring Q (a wiring Q[1] and a wiring Q[2] are representatively illustrated) through the switch circuit group OSW.

Note that the data input from the wiring D is supplied from an arithmetic portion (not illustrated) included in the arithmetic processing portion PCS, for example. The data output to the wiring Q is supplied to the arithmetic portion, for example.

Setting information (setting information indicating whether to block power supply to the register unit 160 by power gating) supplied from the power management unit PMU through a wiring group PG_dat is stored and retained in the setting register PRG. A signal based on the setting information retained in the setting register PRG is supplied to a wiring group PG_sel (a wiring group PG_sel[1] and a wiring group PG_sel[2] are representatively illustrated).

In addition, setting information (setting information indicating whether to block power supply to the power line group PW_lcl by power gating) supplied from the power management unit PMU is stored and retained in the setting register PRG_0. A signal based on the setting information retained in the setting register PRG_0 is supplied to a wiring group PG_sel_0.

In the switch circuit group PSW, whether to block power supply from the power line group PW_lcl to the register unit 160 is controlled by the signal supplied from the wiring group PG sel.

In the switch circuit group ISW, whether to block input of the signal from the wiring group PG_con to the register unit 160 is controlled by the signal supplied from the wiring group PG sel.

In the switch circuit group OSW, whether to block output of the data from the register unit 160 to the wiring Q is controlled by the signal supplied from the wiring group PG_sel.

In the switch circuit group PSW_0, whether to block power supply from the power line group PW_gbl to the power line group PW_Icl is controlled by the signal supplied from the wiring group PG_sel_0.

In the semiconductor device 200 of one embodiment of the present invention, by rewriting setting information retained in the setting register PRG_0, whether to block power supply to the power line group PW_lcl, that is, whether to block power supply to the entire arithmetic processing portion PCS can be controlled. In addition, by rewriting setting information retained in the setting register PRG, whether to block power supply to the register unit 160, that is, whether to block power supply to the general register GRG can be controlled.

Here, in the semiconductor device 200, the plurality of setting registers PRG and the plurality of general registers GRG correspond one-to-one. Thus, by rewriting the retained setting information on the setting register PRG basis, whether to block power supply can be controlled on the general register GRG basis.

In the semiconductor device 200, whether to block power supply to the corresponding general register GRG can be confirmed by reading the setting information retained in the setting register PRG.

In the semiconductor device 200 of one embodiment of the present invention, only the unused general register GRG can be individually powered off (power supply is blocked) in accordance with the usage and processing conditions of the arithmetic processing portion PCS, for example. In other words, fine-grained power gating on the general register GRG basis can be performed. Thus, power consumption of the arithmetic processing portion PCS in the semiconductor device 200 can be reduced. Thus, for example, power consumption of an electronic computer that uses the semiconductor device 200 can be reduced.

In the semiconductor device 200, for example, an instruction to perform power gating is supplied from a control portion included in the arithmetic processing portion PCS to the power management unit PMU; thus, power gating can be controlled by the power management unit PMU.

A specific structure example of the general register GRG will be described later.

In one embodiment of the present invention, as the setting register PRG, a flip-flop circuit prepared in a standard circuit library may be used, or a structure including a retention circuit described below can be used.

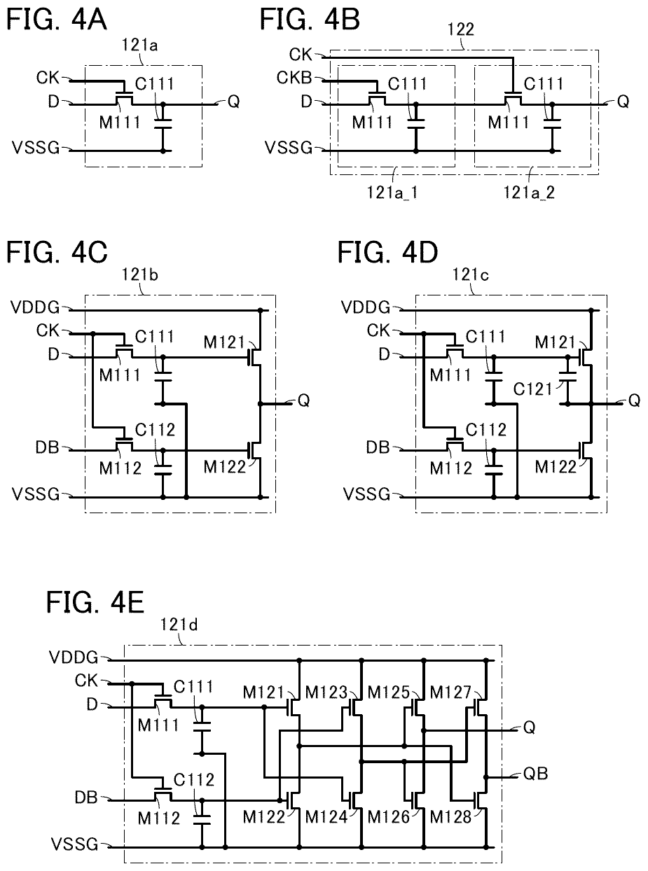

FIG. 4A to FIG. 4E are circuit diagrams each illustrating a structure example of the retention circuit that can be used as the setting register PRG.

A retention circuit 121a illustrated in FIG. 4A includes a transistor M111 and a capacitor C111. Ann-channel transistor can be used as the transistor M111, for example. One of a source and a drain of the transistor M111 is electrically connected to one terminal of the capacitor C111 and the wiring Q. The other of the source and the drain of the transistor M111 is electrically connected to the wiring D. A gate of the transistor M111 is electrically connected to a wiring CK. The other terminal of the capacitor C111 is electrically connected to a wiring VSSG.

When the wiring CK is supplied with a signal that brings the transistor M111 into the conduction state, the retention circuit 121a stores data supplied to the wiring D in the wiring Q, and then when the wiring CK is supplied with a signal that brings the transistor M111 into the non-conduction state, the data stored in the wiring Q can be retained. That is, the retention circuit 121a can have a function of a latch.

A retention circuit 122 illustrated in FIG. 4B includes two retention circuits 121a (a retention circuit 121a_1 and a retention circuit 121a_2). In the retention circuit 122, the wiring Q of one of the retention circuits 121a (the retention circuit 121a_1) and the wiring D of the other of the retention circuits 121a (the retention circuit 121a_2) are electrically connected to each other. A gate of the transistor M111 included in the retention circuit 121a_1 is electrically connected to a wiring CKB, and a gate of the transistor M111 included in the retention circuit 121a_2 is electrically connected to the wiring CK.

In the retention circuit 122, an inverted signal of a signal for the wiring CK is supplied to the wiring CKB. With such a structure, data supplied to the wiring D can be stored in the wiring Q in synchronization with the rising edge of the signal supplied to the wiring CK, and the data can be retained. That is, the retention circuit 122 can have a function of a flip-flop.

A retention circuit 121b illustrated in FIG. 4C is a variation example of the retention circuit 121a, further including a transistor M112, a capacitor C112, a transistor M121, and a transistor M122. As the transistor M112, the transistor M121, and the transistor M122, n-channel transistors can be used, for example. One of a source and a drain of the transistor M111 is electrically connected to one terminal of the capacitor C111. The other of the source and the drain of the transistor M111 is electrically connected to the wiring D. One of a source and a drain of the transistor M112 is electrically connected to one terminal of the capacitor C112. The other of the source and the drain of the transistor M112 is electrically connected to a wiring DB. A gate of the transistor M111 and a gate of the transistor M112 are electrically connected to the wiring CK. The other terminal of the capacitor C111 and the other terminal of the capacitor C112 are electrically connected to the wiring VSSG. A gate of the transistor M121 is electrically connected to the one of the source and the drain of the transistor M111. A gate of the transistor M122 is electrically connected to the one of the source and the drain of the transistor M112. One of a source and a drain of the transistor M121 and one of a source and a drain of the transistor M122 are electrically connected to the wiring Q. The other of the source and the drain of the transistor M121 is electrically connected to a wiring VDDG. The other of the source and the drain of the transistor M122 is electrically connected to the wiring VSSG.

In the retention circuit 121b, inverted data of the data on the wiring D is supplied to the wiring DB. The transistor M121 and the transistor M122 can function as a buffer circuit. With such a structure, the current output capability can be increased, and even in the case where the load on the wiring Q is large, sufficient driving is possible.

A retention circuit 121c illustrated in FIG. 4D is a variation example of the retention circuit 121b, further including a capacitor C121. One terminal of the capacitor C121 is electrically connected to the gate of the transistor M121, and the other terminal of the capacitor C121 is electrically connected to the one of the source and the drain of the transistor M121.

In the retention circuit 121c, the capacitor C121 can function as a bootstrap capacitor. Such a structure can further increase current output capability.

A retention circuit 121d illustrated in FIG. 4E is a variation example of the retention circuit 121b, further including a transistor M123, a transistor M124, a transistor M125, a transistor M126, a transistor M127, and a transistor M128. As the transistor M123, the transistor M124, the transistor M125, the transistor M126, the transistor M127, and the transistor M128, n-channel transistors can be used, for example. A gate of the transistor M123 is electrically connected to the gate of the transistor M122. A gate of the transistor M124 is electrically connected to the gate of the transistor M121. The one of the source and the drain of the transistor M121 and the one of the source and the drain of the transistor M122 are electrically connected to a gate of the transistor M125 and a gate of the transistor M128. One of a source and a drain of the transistor M123 and one of a source and a drain of the transistor M124 are electrically connected to a gate of the transistor M126 and a gate of the transistor M127. One of a source and a drain of the transistor M125 and one of a source and a drain of the transistor M126 are electrically connected to the wiring Q. One of a source and a drain of the transistor M127 and one of a source and a drain of the transistor M128 are electrically connected to the wiring QB. The other of the source and the drain of the transistor M123, the other of the source and the drain of the transistor M125, and the other of the source and the drain of the transistor M127 are electrically connected to the wiring VDDG. The other of the source and the drain of the transistor M124, the other of the source and the drain of the transistor M126, and the other of the source and the drain of the transistor M128 are electrically connected to the wiring VSSG.

In the retention circuit 121b, inverted data of the data on the wiring Q is supplied to the wiring QB. With such a structure, a circuit for generating inverted data does not need to be provided additionally even in the case where inverted data is necessary; thus, the circuit scale can be reduced.

In the case where at least one of the retention circuits 121a to 121d and 122 is used as the setting register PRG in one embodiment of the present invention, for example, the transistor M111 and the capacitor C111 respectively correspond to the transistor M101 and the capacitor C101 included in the above-described setting information retention portion 102 illustrated in FIG. 1A and the like.

That is, OS transistors can be used as the transistors included in the retention circuit 121a to the retention circuit 121d and the retention circuit 122, for example. OS transistors have characteristics of having an extremely low off-state current and characteristics that the off-state current hardly increases and the on-state current is unlikely to decrease even in a high-temperature environment. Thus, data stored in the retention circuit can be retained for a long period.

Thus, in the case where the retention circuit is used in the setting register PRG, for example, stored setting information can be retained for a long period. In addition, a leakage current can be extremely low as compared with the case of using a flip-flop circuit prepared in a standard circuit library, for example. Thus, power consumption of the semiconductor device can be reduced.

Note that one embodiment of the present invention is not limited to the retention circuit 121a to the retention circuit 121d and the retention circuit 122, and a retention circuit in which those structures are combined as appropriate can be used.

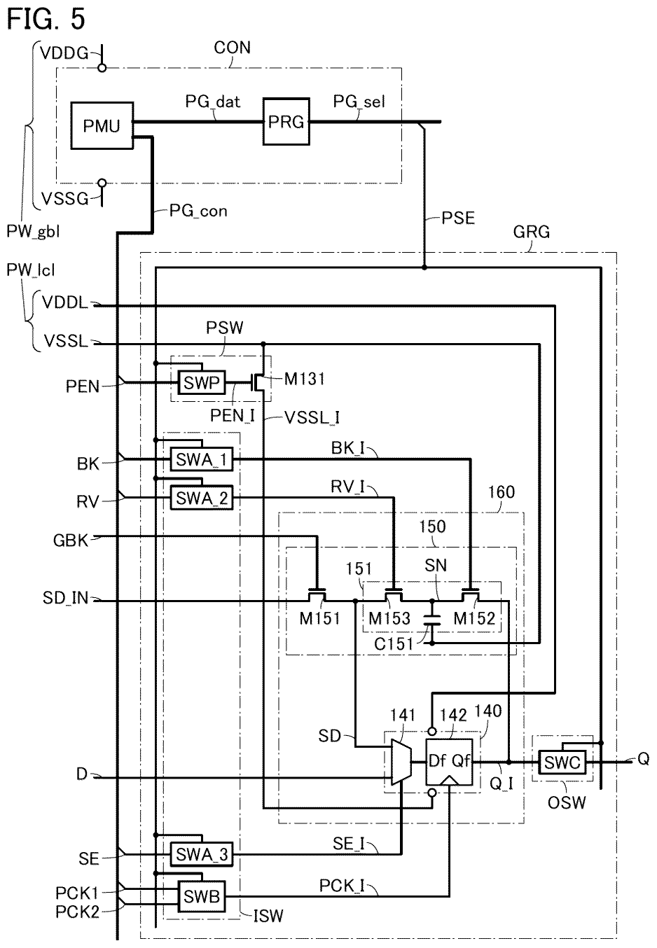

FIG. 5 is a circuit diagram illustrating a specific structure example of the semiconductor device 200. FIG. 5 illustrates selected part of the semiconductor device 200 illustrated in FIG. 3.

As illustrated in FIG. 5, the power line group PW_gbl includes the wiring VDDG and the wiring VSSG. The power line group PW_Icl includes a wiring VDDL and a wiring VSSL.

A high power supply potential is supplied from the wiring VDDG to the control portion CON, and a low power supply potential is supplied from the wiring VSSG to the control portion CON. A high power supply potential is supplied from the wiring VDDL to the general register GRG, and a low power supply potential is supplied from the wiring VSSL to the general register GRG.

The wiring group PG_con includes a wiring PCK1, a wiring PCK2, a wiring BK, a wiring RV, a wiring SE, and a wiring PEN. The wiring group PG_sel includes a wiring PSE. Note that the wiring group PG_sel may include a wiring to which an inverted signal of a signal supplied to the wiring PSE is supplied (not illustrated).

A specific structure example of the general register GRG is described.

As illustrated in FIG. 5, in the general register GRG, the switch circuit group PSW includes one switch circuit SWP and a transistor M131. The switch circuit group ISW includes three switch circuits SWA (a switch circuit SWA_1, a switch circuit SWA_2, and a switch circuit SWA_3) and one switch circuit SWB. The switch circuit group OSW includes a switch circuit SWC.

A signal is supplied from the wiring PEN to a wiring PEN_I through the switch circuit SWP. A signal is supplied from the wiring BK to a wiring BK_I through the switch circuit SWA_1. A signal is supplied from the wiring RV to a wiring RV_I through the switch circuit SWA_2. A signal is supplied from the wiring SE to a wiring SE_I through the switch circuit SWA_3. A signal is supplied from the wiring PCK1 or the wiring PCK2 to a wiring PCK_I through the switch circuit SWB. Data is output from a wiring Q_I to the wiring Q through the switch circuit SWC.

Data is input from the wiring D. Furthermore, data is input from a wiring SD_IN, and a signal is supplied from a wiring GBK.

A control signal is supplied from the wiring PSE to each of the switch circuit SWP, the switch circuit SWA, the switch circuit SWB, and the switch circuit SWC. Furthermore, an inverted signal of the control signal may be supplied.

In the switch circuit group PSW, one of a source and a drain of the transistor M131 is electrically connected to the wiring VSSL. The other of the source and the drain of the transistor M131 is electrically connected to a wiring VSSL_I. A gate of the transistor M131 is electrically connected to the wiring PEN_I.

The transistor M131 has a function of switching whether to block power supply to the register unit 160. Therefore, it is preferable that the transistor M131 have a sufficiently high on-state current and a sufficiently low off-state current.

Here, the transistor M131 corresponds to the transistor M103 included in the above-described power switch portion 103 illustrated in FIG. 1A and the like.

In one embodiment of the present invention, an OS transistor can be used as the transistor M131, for example. An OS transistor has characteristics of having an extremely low off-state current and characteristics that the off-state current hardly increases and the on-state current is unlikely to decrease even in a high-temperature environment.

In the case where an OS transistor is used as the transistor M131, a leakage current in the register unit 160 can be extremely low during power-off of the general register GRG (the block of power supply). Thus, power consumption of the arithmetic processing portion PCS in the semiconductor device 200 can be reduced. Thus, for example, power consumption of an electronic computer that uses the semiconductor device 200 can be reduced.

Note that the on-state resistance of the transistor M131 may be made sufficiently lower than those of the other transistors included in the semiconductor device 200, for example, so that the on-state current of the transistor M131 can be sufficiently high. That is, for example, the channel width of the transistor M131 may be made sufficiently larger than the channel widths of the other transistors included in the semiconductor device 200.

For example, the on-state resistance (or channel width) of the transistor M131 may be made sufficiently lower (or larger) than the on-state resistance (or channel width) of each transistor included in the register unit 160.

A specific structure example of the register unit 160 is described.

As illustrated in FIG. 5, the register unit 160 includes the scan flip-flop circuit 140 and the backup circuit 150.

The scan flip-flop circuit 140 includes a selector circuit 141 and a flip-flop circuit 142. The backup circuit 150 includes a retention circuit 151 and a transistor M151. The retention circuit 151 includes a transistor M152, a transistor M153, and a capacitor C151.

The scan flip-flop circuit 140 is supplied with power by being supplied with a high power supply potential from the wiring VDDL and a low power supply potential from the wiring VSSL_I.

A variety of signals for controlling the operation of the register unit 160 are supplied to the wiring BK_I, the wiring RV_I, the wiring SE_I, the wiring PCK_I, and the wiring GBK.

The register unit 160 can store and retain data input from the wiring D or data input from a wiring SD in the flip-flop circuit 142 in the scan flip-flop circuit 140 in synchronization with a clock signal supplied to the wiring PCK_I and output the data to the wiring Q_I. The data retained in the flip-flop circuit 142 is written to the retention circuit 151 in the backup circuit 150 through the wiring Q_I in response to a signal supplied to the wiring BK_I and then retained. This operation is referred to as, for example, saving, storing, backup, or the like in some cases. The data retained in the retention circuit 151 is written back to the flip-flop circuit 142 through the wiring SD in response to a signal supplied to the wiring RV_I and then retained. This operation is referred to as, for example, loading, restoration, recovery, or the like in some cases.

The flip-flop circuit 142 has a function of storing and retaining data supplied to an input terminal Df in synchronization with the clock signal supplied to the wiring PCK_I and outputting the data from an output terminal Qf. For the flip-flop circuit 142, a flip-flop circuit prepared in a standard circuit library can be used. For example, a positive edge-triggered D flip-flop can be used.

The selector circuit 141 has a function of transmitting data supplied to the wiring D or the wiring SD to the flip-flop circuit 142 in response to a signal supplied to the wiring SE_I. Data that is input from the outside of the general register GRG (e.g., the arithmetic portion included in the arithmetic processing portion PCS) is supplied to the wiring D. Data retained in the retention circuit 151 in the backup circuit 150 or data that is input from the wiring SD_IN is supplied to the wiring SD. Data for a scan test is supplied to the wiring SD_IN.

When power gating is performed, the backup circuit 150 can retain the state of the scan flip-flop circuit 140 in the retention circuit 151.

As illustrated in FIG. 5, the retention circuit 151 is electrically connected to each of the wiring Q_I and the wiring SD. In the retention circuit 151, a terminal (wiring) electrically connected to the wiring Q_I is an input terminal, and a terminal (wiring) electrically connected to the wiring SD is an output terminal. That is, in the register unit 160, the output terminal Qf of the flip-flop circuit 142 is electrically connected to the input terminal of the retention circuit 151, and the input terminal Df of the flip-flop circuit 142 is electrically connected to the output terminal of the retention circuit 151 through the selector circuit 141.

In the retention circuit 151, one of a source and a drain of the transistor M152 is electrically connected to one terminal of the capacitor C151. One of a source and a drain of the transistor M153 is electrically connected to the one terminal of the capacitor C151. The other terminal of the capacitor C151 is electrically connected to the wiring VSSL. The other of the source and the drain of the transistor M152 is electrically connected to the input terminal of the retention circuit 151 (i.e., the wiring Q_I). The other of the source and the drain of the transistor M153 is electrically connected to the output terminal of the retention circuit 151 (i.e., the wiring SD). A gate of the transistor M152 is electrically connected to the wiring BK_I. A gate of the transistor M153 is electrically connected to a wiring RV_I.

Note that in the retention circuit 151, a wiring in which the one of the source and the drain of the transistor M152, the one of the source and the drain of the transistor M153, and the one terminal of the capacitor C151 are electrically connected to one another is sometimes described as a wiring SN.

In the backup circuit 150, one of a source and a drain of the transistor M151 is electrically connected to the wiring SD. The other of the source and the drain of the transistor M151 is electrically connected to the wiring SD_IN.

A gate of the transistor M151 is electrically connected to the wiring GBK. A signal which controls whether a scan test is performed is supplied to the wiring GBK.

Here, the transistor M152, the transistor M153, and the capacitor C151 respectively correspond to the transistor M104, the transistor M105, and the capacitor C102 included in the above-described backup portion illustrated in FIG. 1A and the like.

In one embodiment of the present invention, OS transistors can be used as the transistor M151, the transistor M152, and the transistor M153, for example. OS transistors have characteristics of having an extremely low off-state current and characteristics that the off-state current hardly increases and the on-state current is unlikely to decrease even in a high-temperature environment.

Accordingly, the retention circuit 151 can retain data written to the wiring SN for a long period by bringing the transistor M152 and the transistor M153 into the non-conduction state. For example, data can be continuously retained even in a state where power supply to the scan flip-flop circuit 140 is blocked by power gating. That is, the retention circuit 151 can be used as a nonvolatile memory.

Here, when data retained in the wiring SN is written back to the flip-flop circuit 142 in the register unit 160, the potential of the data may vary owing to the parasitic capacitance of the wiring SD. Under the circumstances, the electrostatic capacitance of the capacitor C151 may be set larger than the parasitic capacitance of the wiring SD so that the amount of variation in the potential of the data can be smaller than the logical threshold of the flip-flop circuit 142 or the like, for example.

For another structure example of the register unit 160, a structure where a Si transistor is used as the transistor M151 may be employed.

In one embodiment of the present invention, the backup circuit 150 can be provided in the register unit 160 without changing the circuit structure and layout of the scan flip-flop circuit 140. That is, the backup circuit 150 is a circuit of great versatility.

In the register unit 160, the backup circuit 150 is provided to be stacked over the scan flip-flop circuit 140; thus, the distance of wirings electrically connecting the scan flip-flop circuit 140 and the backup circuit 150 to each other can be shortened. Thus, energy (access energy) necessary for data saving and data loading can be reduced. Accordingly, power consumption due to power gating in the register unit 160 can be reduced.

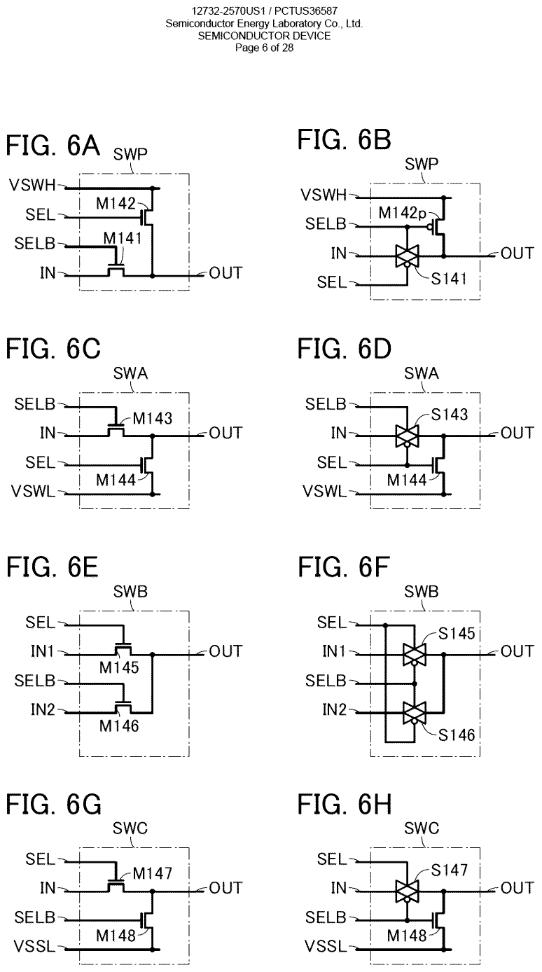

FIG. 6A to FIG. 6H are circuit diagrams each illustrating a structure example of the switch circuit SWP, the switch circuit SWA, the switch circuit SWB, or the switch circuit SWC.

The switch circuit SWP illustrated in FIG. 6A includes a transistor M141 and a transistor M142. As the transistor M141 and the transistor M142, n-channel transistors can be used, for example. One of a source and a drain of the transistor M141 and one of a source and a drain of the transistor M142 are electrically connected to a wiring OUT. The other of the source and the drain of the transistor M141 is electrically connected to a wiring IN. The other of the source and the drain of the transistor M142 is electrically connected to a wiring VSWH. A gate of the transistor M141 is electrically connected to a wiring SELB. A gate of the transistor M142 is electrically connected to a wiring SEL.

The wiring IN functions as an input terminal of the switch circuit SWP. The wiring OUT functions as an output terminal of the switch circuit SWP. The wiring SEL and the wiring SELB respectively function as a non-inverting control terminal and an inverting control terminal of the switch circuit SWP. An inverted signal of a signal for the wiring SEL is supplied to the wiring SELB.

The switch circuit SWP illustrated in FIG. 6B is a variation example of the switch circuit SWP illustrated in FIG. 6A, and includes an analog switch S141 instead of the transistor M141 and a transistor M142p instead of the transistor M142. As the analog switch S141, an analog switch circuit prepared in a standard circuit library can be used, for example. As the transistor M142p, a p-channel transistor can be used, for example. A non-inverting control terminal of the analog switch S141 is electrically connected to the wiring SELB. An inverting control terminal of the analog switch S141 is electrically connected to the wiring SEL. A gate of the transistor M142p is electrically connected to the wiring SELB.

The switch circuit SWA illustrated in FIG. 6C includes a transistor M143 and a transistor M144. As the transistor M143 and the transistor M144, n-channel transistors can be used, for example. One of a source and a drain of the transistor M143 and one of a source and a drain of the transistor M144 are electrically connected to the wiring OUT. The other of the source and the drain of the transistor M143 is electrically connected to the wiring IN. The other of the source and the drain of the transistor M144 is electrically connected to a wiring VSWL. A gate of the transistor M143 is electrically connected to the wiring SELB. A gate of the transistor M144 is electrically connected to the wiring SEL.

The wiring IN functions as an input terminal of the switch circuit SWA. The wiring OUT functions as an output terminal of the switch circuit SWA. The wiring SEL and the wiring SELB respectively function as a non-inverting control terminal and an inverting control terminal of the switch circuit SWA. The wiring SELB is supplied with an inverted signal of a signal for the wiring SEL.

The switch circuit SWA illustrated in FIG. 6D is a variation example of the switch circuit SWA illustrated in FIG. 6C, and includes an analog switch S143 instead of the transistor M143. As the analog switch S143, an analog switch circuit prepared in a standard circuit library can be used, for example. A non-inverting control terminal of the analog switch S143 is electrically connected to the wiring SELB. An inverting control terminal of the analog switch S143 is electrically connected to the wiring SEL.

The switch circuit SWB illustrated in FIG. 6E includes a transistor M145 and a transistor M146. As the transistor M145 and the transistor M146, n-channel transistors can be used, for example. One of a source and a drain of the transistor M145 and one of a source and a drain of the transistor M146 are electrically connected to the wiring OUT. The other of the source and the drain of the transistor M145 is electrically connected to a wiring IN1. The other of the source and the drain of the transistor M146 is electrically connected to a wiring IN2. A gate of the transistor M145 is electrically connected to the wiring SEL. A gate of the transistor M146 is electrically connected to the wiring SELB.

The wiring IN1 functions as a first input terminal of the switch circuit SWB. The wiring IN2 functions as a second input terminal of the switch circuit SWB. The wiring OUT functions as an output terminal of the switch circuit SWB. The wiring SEL and the wiring SELB respectively function as a non-inverting control terminal and an inverting control terminal of the switch circuit SWB. An inverted signal of a signal for the wiring SEL is supplied to the wiring SELB.

The switch circuit SWB illustrated in FIG. 6F is a variation example of the switch circuit SWB illustrated in FIG. 6E, and includes an analog switch S145 instead of the transistor M145 and an analog switch S146 instead of the transistor M146. As each of the analog switch S145 and the analog switch S146, an analog switch circuit prepared in a standard circuit library can be used, for example. A non-inverting control terminal of the analog switch S145 and an inverting control terminal of the analog switch S146 are electrically connected to the wiring SEL. An inverting control terminal of the analog switch S145 and a non-inverting control terminal of the analog switch S146 are electrically connected to the wiring SELB.

The switch circuit SWC illustrated in FIG. 6G includes a transistor M147 and a transistor M148. As the transistor M147 and the transistor M148, n-channel transistors can be used, for example. One of a source and a drain of the transistor M147 and one of a source and a drain of the transistor M148 are electrically connected to the wiring OUT. The other of the source and the drain of the transistor M147 is electrically connected to the wiring IN. The other of the source and the drain of the transistor M148 is electrically connected to the wiring VSSL. A gate of the transistor M147 is electrically connected to the wiring SEL. A gate of the transistor M148 is electrically connected to the wiring SELB.

The wiring IN functions as an input terminal of the switch circuit SWC. The wiring OUT functions as an output terminal of the switch circuit SWC. The wiring SEL and the wiring SELB respectively function as a non-inverting control terminal and an inverting control terminal of the switch circuit SWC. An inverted signal of a signal for the wiring SEL is supplied to the wiring SELB.

The switch circuit SWC illustrated in FIG. 6H is a variation example of the switch circuit SWC illustrated in FIG. 6G, and includes an analog switch S147 instead of the transistor M147. As the analog switch S147, an analog switch circuit prepared in a standard circuit library can be used, for example. A non-inverting control terminal of the analog switch S147 is electrically connected to the wiring SEL. An inverting control terminal of the analog switch S147 is electrically connected to the wiring SELB.

The switch circuit SWP, the switch circuit SWA, the switch circuit SWB, and the switch circuit SWC illustrated in FIG. 6A, FIG. 6C, FIG. 6E, and FIG. 6G, respectively, in one embodiment of the present invention have structures that can be used in the case where the power switch portion 103 is provided in the layer 183 as illustrated in FIG. 1A and FIG. 1B mentioned above, for example, and OS transistors can be used as the transistors, for example.

In this case, the transistor M141 corresponds to the transistor M103 included in the above-described power switch portion 103 illustrated in FIG. 1A.

The switch circuit SWP, the switch circuit SWA, the switch circuit SWB, and the switch circuit SWC illustrated in FIG. 6B, FIG. 6D, FIG. 6F, and FIG. 6H, respectively have structures that can be used in the case where the power switch portion 103 is provided in the layer 185 as illustrated in FIG. 2A and FIG. 2B mentioned above, for example, and Si transistors can be used as the transistors, for example.

### Operation Example

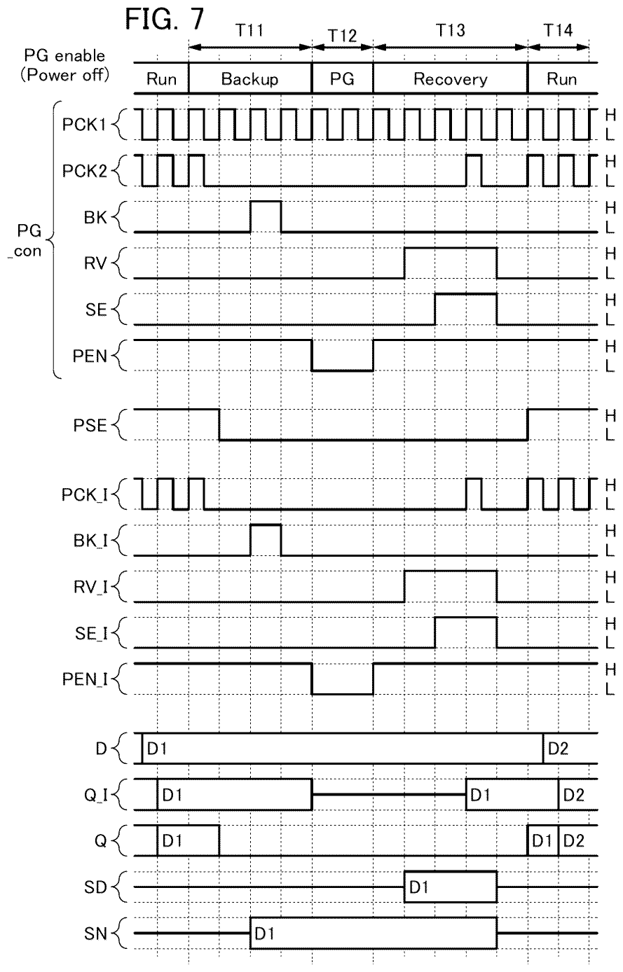

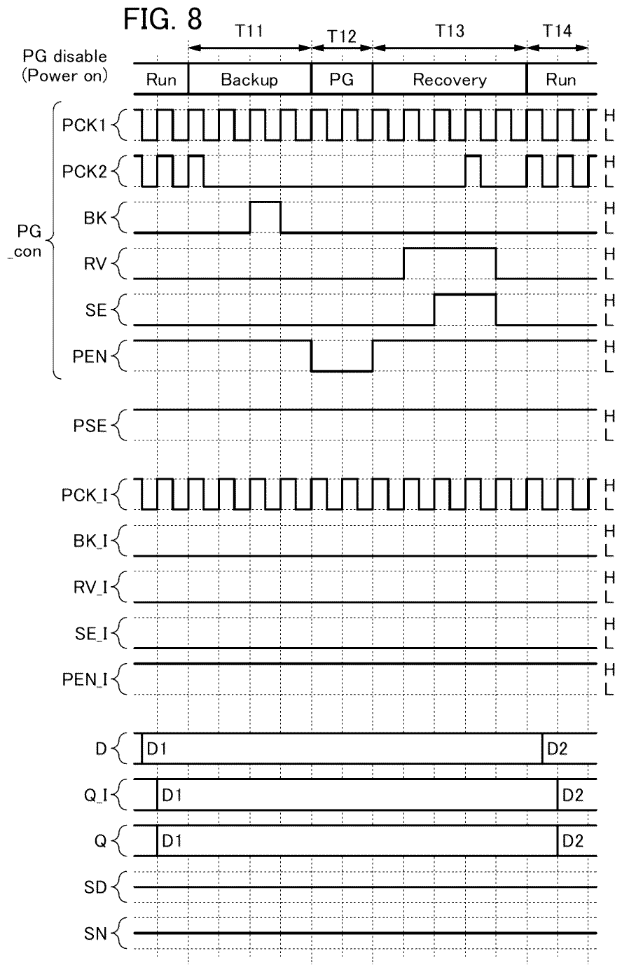

FIG. 7 and FIG. 8 are timing charts showing operation examples of the general register GRG illustrated in FIG. 5. FIG. 7 shows an operation example of a case where the general register GRG is powered off by power gating (Power off), that is, a case where setting information that enables power gating is retained in the setting register PRG (PG enable). FIG. 8 shows an operation example of a case where the general register GRG is not powered off by power gating (Power on), that is, a case where setting information that disables power gating is retained in the setting register PRG (PG disable).

As for the potentials corresponding to binary data in the following description, the potential corresponding to “1” of binary data is a high power supply potential VDD, and the potential corresponding to “0” of binary data is a low power supply potential VSS. A difference between the potential VDD and the potential VSS is larger than the threshold voltage of a transistor. Note that the potential VSS may be a ground potential, for example. The potential of a signal is a potential H or a potential L. The potential H is a potential which, when being supplied to a gate of an n-channel transistor, makes the transistor in the conduction state and, when being supplied to a gate of a p-channel transistor, makes the transistor in the non-conduction state. The potential L is a potential which, when being supplied to a gate of an n-channel transistor, makes the transistor in the non-conduction state and, when being supplied to a gate of a p-channel transistor, makes the transistor in the conduction state. The potential H can be, for example, a potential equal to or higher than the potential VDD. The potential L can be, for example, a potential equal to or lower than the potential VSS.

Note that each of the potential H and the potential L does not necessarily have the same potential in a plurality of signals. The plurality of signals may have different potentials H and different potentials L from one another in accordance with the threshold voltages of the transistors to which the signals are supplied. For example, each of the potential H and the potential L may differ between a signal supplied to a gate of the transistor provided in the layer 185 and a signal supplied to a gate of the transistor provided in the layer 183.

It is assumed in the following description of the operation that the flip-flop circuit 142 stores data supplied to the input terminal Df in synchronization with the timing at which the clock signal supplied to the wiring PCK_I switches from the potential L to the potential H (the rising edge) and outputs the data from the output terminal Qf. In addition, the potential L is assumed to be supplied to the wiring GBK. The potential H is assumed to be supplied to the wiring VSWH, and the potential L is assumed to be supplied to the wiring VSWL. Furthermore, the potential VDD is assumed to be supplied to the wiring VDDL and the wiring VDDG, and the potential VSS is assumed to be supplied to the wiring VSSL and the wiring VSSG.

The timing charts in FIG. 7 and FIG. 8 each show the states (the potential H or the potential L) of signals supplied to the wiring PCK1, the wiring PCK2, the wiring BK, the wiring RV, the wiring SE, the wiring PEN, and the wiring PSE in the operation periods (a period T11 to a period T14). In addition, changes in the potentials of the wiring PCK_I, the wiring BK_I, the wiring RV_I, the wiring SE_I, and the wiring PEN_I are shown. In addition, the states of data supplied to the wiring D, the wiring Q_I, the wiring Q, the wiring SD, and the wiring SN are shown.

A period immediately before the period T11 is a period in which a normal operation (Run) is performed. The period T11 is a period in which the normal operation is stopped and backup (Backup) is performed. A period T12 is a period in which power gating (PG) is performed. A period T13 is a period in which recovery (Recovery) is performed. The period T14 is a period in which the normal operation (Run) is restarted.

Immediately before the period T11, a clock signal is assumed to be supplied to each of the wiring PCK1 and the wiring PCK2. In addition, the potential L is assumed to be supplied to each of the wiring BK, the wiring RV, and the wiring SE. In addition, the potential H is assumed to be supplied to the wiring PEN.

Moreover, the potential H is assumed to be supplied to the wiring PSE. Thus, the potential H is supplied to the output terminal of the switch circuit SWP, the potential L is supplied to the output terminal of the switch circuit SWA, the potential of the first input terminal is supplied to the output terminal of the switch circuit SWB, and the potential of the input terminal is supplied to the output terminal of the switch circuit SWC. In other words, the clock signal is supplied from the wiring PCK1 to the wiring PCK_I, the potential L is supplied to the wiring BK_I, the potential L is supplied to the wiring RV_I, the potential L is supplied to the wiring SE_I, and the potential H is supplied to the wiring PEN_I. Data is supplied from the wiring Q_I to the wiring Q.

Accordingly, the transistor M131 is in the conduction state, and the potential VSS is supplied from the wiring VSSL to the wiring VSSL_I. That is, power is supplied to the scan flip-flop circuit 140. In synchronization with the rising edge of the clock signal supplied from the wiring PCK1 to the wiring PCK_I, data D1 supplied to the wiring D is stored in the scan flip-flop circuit 140 and output to the wiring Q_I. The data D1 is supplied from the wiring Q_I to the wiring Q. The state of data supplied to the wiring SD and the wiring SN is indefinite. Note that in the following description, unless otherwise particularly specified, the previous state is maintained.

### Case Where Power Gating Is Enabled

First, with reference to FIG. 7, the case where the general register GRG is powered off by power gating, i.e., the case where setting information that enables power gating is retained in the setting register PRG is described. In this case, it is assumed that the potential L is supplied to the wiring PSE in a period during which power gating is performed on the basis of the setting information.

In the period T11, the potential L is supplied to the wiring PSE. Accordingly, the potential of the input terminal is supplied to the output terminal of the switch circuit SWP, the potential of the input terminal is supplied to the output terminal of the switch circuit SWA, the potential of the second input terminal is supplied to the output terminal of the switch circuit SWB, and the potential L is supplied to the output terminal of the switch circuit SWC. In other words, the clock signal is supplied from the wiring PCK2 to the wiring PCK_I, the signal is supplied from the wiring BK to the wiring BK_I, the signal is supplied from the wiring RV to the wiring RV_I, the signal is supplied from the wiring SE to the wiring SE_I, and the signal is supplied from the wiring PEN to the wiring PEN_I. The potential VSS is supplied to the wiring Q.

In addition, the clock signal supplied to the wiring PCK2 is stopped. Thus, the clock signal supplied to the wiring PCK_I is also stopped.

Next, the potential H is supplied from the wiring BK to the wiring BK_I. Then, the data D1 output to the wiring Q_I is stored in the wiring SN of the retention circuit 151. After that, the potential L is supplied from the wiring BK to the wiring BK_I. Then, the data D1 stored in the wiring SN is retained.

In the period T12, the potential L is supplied from the wiring PEN to the wiring PEN_I. Then, the transistor M131 is brought into the non-conduction state, and the wiring VSSL_I is brought into a floating state. That is, power supply to the scan flip-flop circuit 140 is blocked. That is, the power is off.

At this time, the data D1 stored in the scan flip-flop circuit 140 is lost. The data D1 stored in the wiring SN of the retention circuit 151 is retained.

In the period T13, the potential H is supplied from the wiring PEN to the wiring PEN_I. Then, the transistor M131 is brought into the conduction state, and the potential VSS is supplied from the wiring VSSL to the wiring VSSL_I. That is, power supply to the scan flip-flop circuit 140 is restarted. That is, the power is on.

Next, the potential H is supplied from the wiring RV to the wiring RV_I. Then, the data D1 retained in the wiring SN of the retention circuit 151 is supplied to the wiring SD. Furthermore, the potential H is supplied from the wiring SE to the wiring SE_I. Then, the wiring SD is selected in the selector circuit 141.

Next, a pulse signal is supplied from the wiring PCK2 to the wiring PCK_I. Then, the data D1 supplied to the wiring SD is stored in the scan flip-flop circuit 140 in synchronization with the rising edge of the pulse signal and is output to the wiring Q_I. After that, the potential L is supplied from the wiring RV to the wiring RV_I, and the potential L is supplied from the wiring SE to the wiring SE_I.

In the period T14, the clock signal supplied to the wiring PCK2 is restarted. The potential H is supplied to the wiring PSE. Accordingly, the clock signal is supplied from the wiring PCK1 to the wiring PCK_I, the potential L is supplied to the wiring BK_I, the potential L is supplied to the wiring RV_I, the potential L is supplied to the wiring SE_I, and the potential H is supplied to the wiring PEN_I. The data D1 is supplied from the wiring Q_I to the wiring Q.

After that, data D2 is assumed to be supplied to the wiring D. In that case, the data D2 supplied to the wiring D is stored in the scan flip-flop circuit 140 in synchronization with the rising edge of the clock signal supplied from the wiring PCK1 to the wiring PCK_I and is output to the wiring Q_I. The data D2 is supplied from the wiring Q_I to the wiring Q.

### Case Where Power Gating Is Disabled

Next, with reference to FIG. 8, the case where the general register GRG is not powered off by power gating, i.e., the case where setting information that disables power gating is retained in the setting register PRG is described. In this case, it is assumed that the potential H remains supplied to the wiring PSE in a period during which power gating is performed on the basis of the setting information.

In the period T11, the clock signal supplied to the wiring PCK2 is stopped. Next, the wiring BK is supplied with the potential H, and then is supplied with the potential L. During this period, the clock signal keeps being supplied from the wiring PCK1 to the wiring PCK_I. In addition, the potential L remains supplied to the wiring BK_I. The data D1 remains supplied from the wiring Q_I to the wiring Q.

In the period T12, the potential L is supplied to the wiring PEN. During this period, the potential H remains supplied to the wiring PEN_I. Accordingly, the transistor M131 remains in the conduction state, and the potential VSS remains supplied from the wiring VSSL to the wiring VSSL_I. That is, power keeps being supplied to the scan flip-flop circuit 140. In other words, the power is not turned off.

During this period, the clock signal keeps being supplied from the wiring PCK1 to the wiring PCK_I. The data D1 stored in the scan flip-flop circuit 140 remains retained. Thus, the data D1 remains supplied from the wiring Q_I to the wiring Q.

In the period T13, the potential H is supplied to the wiring PEN. Next, the potential H is supplied to the wiring RV, and the potential H is supplied to the wiring SE. Next, the pulse signal is supplied to the wiring PCK2, and then the potential L is supplied to the wiring RV and the potential L is supplied to the wiring SE. During this period, the clock signal keeps being supplied from the wiring PCK1 to the wiring PCK_I. The potential L remains supplied to the wiring RV_I, and the potential L remans supplied to the wiring SE_I. The data D1 remains supplied from the wiring Q_I to the wiring Q.

In the period T14, the clock signal supplied to the wiring PCK2 is restarted. After that, the data D2 is assumed to be supplied to the wiring D. In that case, the data D2 supplied to the wiring D is stored in the scan flip-flop circuit 140 in synchronization with the rising edge of the clock signal supplied from the wiring PCK1 to the wiring PCK_I and is output to the wiring Q_I. The data D2 is supplied from the wiring Q_I to the wiring Q.

As described above, the general register GRG can operate in the manner shown in the timing chart of FIG. 7 or FIG. 8 on the basis of the setting information retained in the setup register PRG.

Thus, by rewriting retained setting information on the setting register PRG basis (the setting registers PRG correspond to the plurality of general registers GRG one-to-one), whether to block power supply at the time of power gating can be controlled individually for each of the general registers GRG. In other words, fine-grained power gating on the general register GRG basis can be performed.

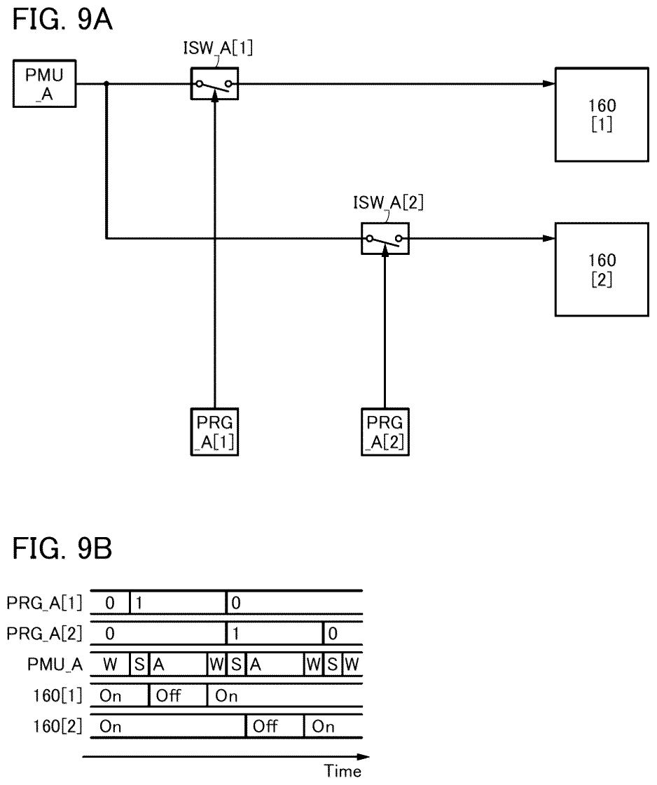

FIG. 9A and FIG. 9B are a block diagram and a timing chart illustrating an example of switching of power gating.

A semiconductor device illustrated in FIG. 9A includes, for example, two register units 160 (a register unit 160[1] and a register unit 160[2]), a power management unit PMU_A, two setting registers PRG_A (a setting register PRG_A[1] and a setting register PRG_A[2]), and two switch circuit groups ISW_A (a switch circuit group ISW_A[1] and a switch circuit group ISW_A[2]).

The semiconductor device illustrated in FIG. 9A can operate in the manner shown in the timing chart of FIG. 9B. In this case, power gating of the two register units 160 is controlled by the power management unit PMU_A.

In the timing chart illustrated in FIG. 9B, first, setting information (“0”) that disables power gating is retained in the setting register PRG_A[1] and the setting register PRG_A[2]. At this time, the power management unit PMU_A is in the standby state (“W”). In addition, power is supplied to each of the register unit 160[1] and the register unit 160[2]. That is, the power is on (“ON”).

Next, the power management unit PMU_A is brought into the register setting state (“S”). Then, setting information (“1”) that enables power gating is stored and retained in the setting register PRG_A[1].

Next, the power management unit PMU_A is brought into the operating state (“A”). Then, the switch circuit group ISW_A[1] and the switch circuit group ISW_A[2] are controlled on the basis of the setting information in the setting register PRG_A[1] and the setting register PRG_A[2], and power supply to the register unit 160[1] is blocked. That is, the power is turned off (“Off”).

Next, the switch circuit group ISW_A[1] and the switch circuit group ISW_A[2] are controlled, and power supply to the register unit 160[1] is restarted. That is, the power is turned on (“ON”). Then, the power management unit PMU_A is brought into the standby state (“W”).

Next, the power management unit PMU_A is brought into the register setting state (“S”). Then, setting information (“0”) that disables power gating is stored and retained in the setting register PRG_A[1]. In addition, setting information (“1”) that enables power gating is stored and retained in the setting register PRG_A[2].

Next, the power management unit PMU_A is brought into the operating state (“A”). Then, the switch circuit group ISW_A[1] and the switch circuit group ISW_A[2] are controlled on the basis of the setting information in setting register PRG_A[1] and the setting register PRG_A[2], and power supply to the register unit 160[2] is blocked. That is, the power is turned off (“Off”).

Next, the switch circuit group ISW_A[1] and the switch circuit group ISW_A[2] are controlled, and power supply to the register unit 160[2] is restarted. That is, the power is turned on (“ON”). Then, the power management unit PMU_A is brought into the standby state (“W”).

Next, the power management unit PMU_A is brought into the register setting state (“S”). Then, the setting information (“0”) that disables power gating is stored and retained in the setting register PRG_A[2]. Then, the power management unit PMU_A is brought into the standby state (“W”).

As described above, the power management unit PMU_A performs a series of power gating operations on the register unit 160[1] and then performs a series of power gating operations on the register unit 160[2].

In this case, when the power gating is switched, a time lag corresponding to the period of the standby state (“W”) and the period of the register setting state (“S”) occurs. Therefore, the operation as described below is also possible in one embodiment of the present invention.

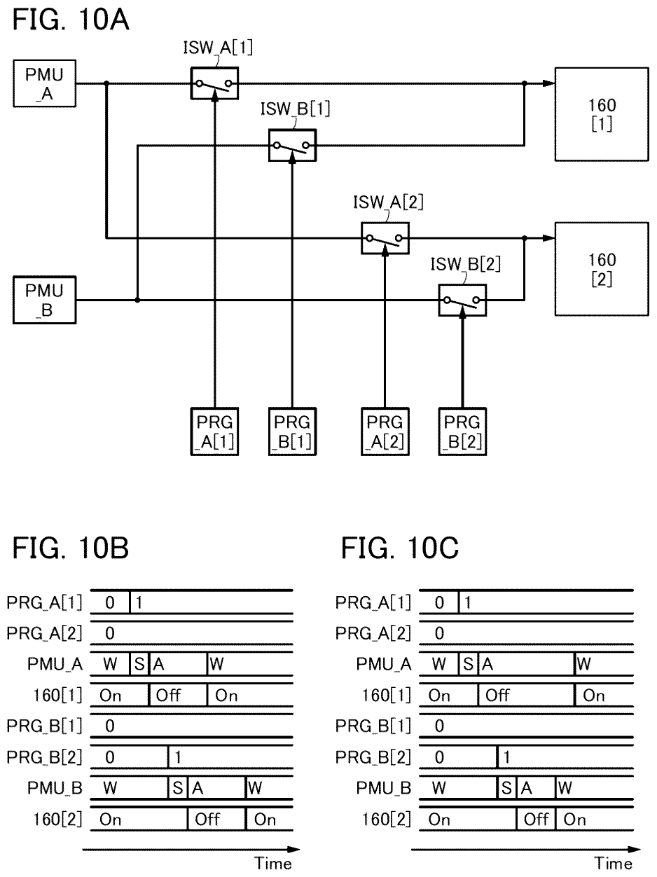

FIG. 10A to FIG. 10C are a block diagram and timing charts illustrating another example of switching of power gating in the above-described semiconductor device 200.

A semiconductor device illustrated in FIG. 10A includes, for example, a power management unit PMU_B, two setting registers PRG_B (a setting register PRG_B[1] and a setting register PRG_B[2]), and two switch circuit groups ISW_B (a switch circuit group ISW_B[1] and a switch circuit group ISW_B[2]), in addition to the structure illustrated in FIG. 9A.

The semiconductor device illustrated in FIG. 10A can operate in the manner shown in the timing chart of FIG. 10B. In this case, power gating of the two register units 160 is controlled by the power management unit PMU_A and the power management unit PMU_B.

In the timing chart illustrated in FIG. 10B, first, setting information (“0”) that disables power gating is retained in the setting register PRG_A[1], the setting register PRG_A[2], the setting register PRG_B[1], and the setting register PRG_B[2]. At this time, the power management unit PMU_A and the power management unit PMU_B are each in the standby state (“W”). In addition, power is supplied to each of the register unit 160[1] and the register unit 160[2]. That is, the power is on (“ON”).

Next, the power management unit PMU_A is brought into the register setting state (“S”). Then, setting information (“1”) that enables power gating is stored and retained in the setting register PRG_A[1].

Next, the power management unit PMU_A is brought into the operating state (“A”). Then, the switch circuit group ISW_A[1] and the switch circuit group ISW_A[2] are controlled on the basis of the setting information in the setting register PRG_A[1] and the setting register PRG_A[2], and power supply to the register unit 160[1] is blocked. That is, the power is turned off(“Off”).

Next, the power management unit PMU_B is brought into the register setting state (“S”). Then, setting information (“1”) that enables power gating is stored and retained in the setting register PRG_B[2].

Next, the power management unit PMU_B is brought into the operating state (“A”). Then, the switch circuit group ISW_B[1] and the switch circuit group ISW_B[2] are controlled on the basis of the setting information in the setting register PRG_B[1] and the setting register PRG_B[2], and power supply to the register unit 160[2] is blocked. That is, the power is turned off(“Off”).

Next, the switch circuit group ISW_A[1] and the switch circuit group ISW_A[2] are controlled, and power supply to the register unit 160[1] is restarted. That is, the power is turned on (“ON”). Then, the power management unit PMU_A is brought into the standby state (“W”).

Next, the switch circuit group ISW_B[1] and the switch circuit group ISW_B[2] are controlled, and power supply to the register unit 160[2] is restarted. That is, the power is turned on (“ON”). Then, the power management unit PMU_B is brought into the standby state (“W”).

The semiconductor device illustrated in FIG. 10A can also operate in the manner shown in the timing chart of FIG. 10C.

In the timing chart shown in FIG. 10C, a series of power gating operations by the power management unit PMU_B is performed in a period during which the power management unit PMU_A is in the operating state (“A”).

As described above, a series of power gating operations for the register unit 160[1] by the power management unit PMU_A and a series of power gating operations for the register unit 160[2] by the power management unit PMU_B are performed in parallel. Accordingly, the operation can be performed without occurrence of a time lag for the period of the standby state (“W”) and the period of the register setting state (“S”).

The semiconductor device according to one embodiment of the present invention is not limited to the semiconductor devices described in this embodiment. At least part of the structure examples, the operation examples, the drawings corresponding thereto, and the like described in this embodiment as an example can be combined as appropriate with the other structure examples, the other operation examples, the other drawings, the other embodiments, and the like described in this specification and the like.

### Embodiment 2

In this embodiment, structure examples of a transistor and a capacitor that can be used in the semiconductor device described in the above embodiment are described.

### Structure Example 1 of Transistor and Capacitor

A structure example of a transistor and a capacitor of one embodiment of the present invention will be described.

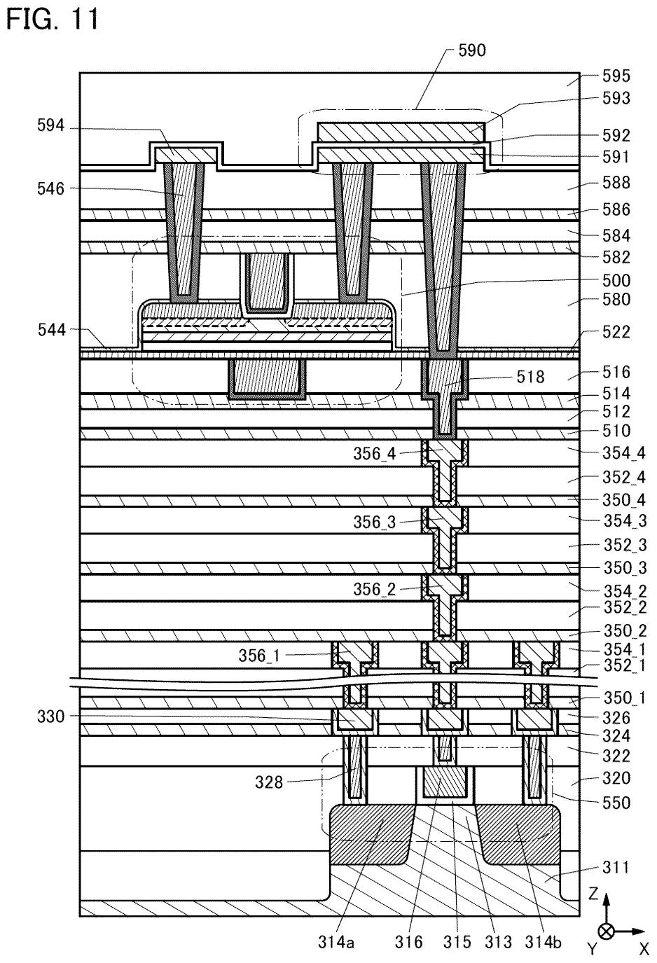

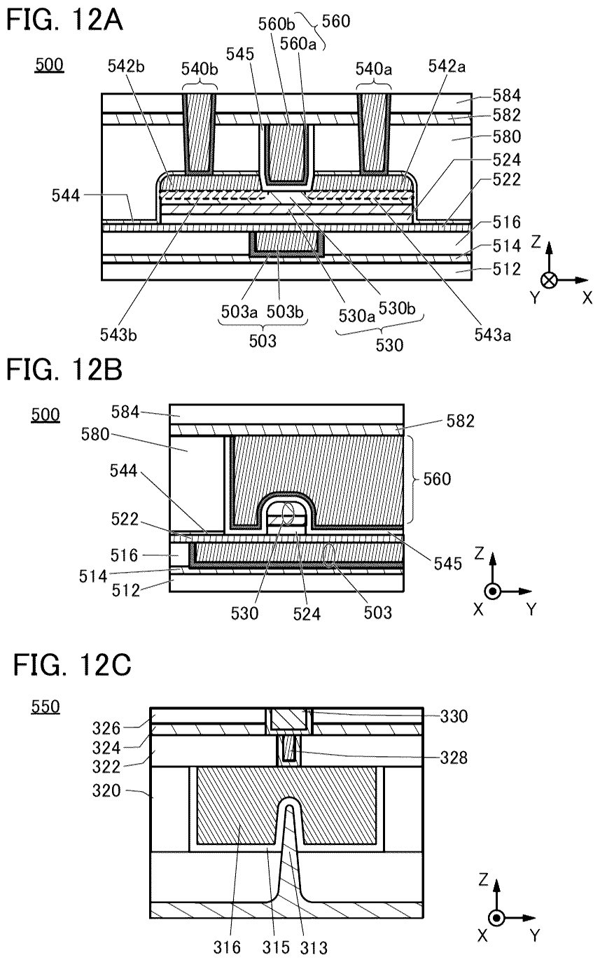

FIG. 11 is a cross-sectional view of a semiconductor device including a transistor 550, a transistor 500, and a capacitor 590. FIG. 12A is a cross-sectional view of the transistor 500 in the channel length direction (shown as the X direction). FIG. 12B is a cross-sectional view of the transistor 500 in the channel width direction (shown as the Y direction). FIG. 12C is a cross-sectional view of the transistor 550 in the channel width direction (shown as the Y direction). Note that FIG. 11 illustrates a cross-sectional view of the transistor 550 in the channel length direction (shown as the X direction).

As illustrated in FIG. 11, the transistor 500 is provided above the transistor 550. The capacitor 590 is provided above the transistor 550 and the transistor 500.

Note that in one embodiment of the present invention, the transistor 550, the transistor 500, and the capacitor 590 can be used in the semiconductor device 100 illustrated in FIG. 1B and the like in Embodiment 1 described above. In that case, the transistor 550 corresponds to the transistor included in the layer 185, the transistor 500 corresponds to the transistor included in the layer 183, and the capacitor 590 corresponds to the capacitor included in the layer 183.

### Transistor 550

As illustrated in FIG. 11, the transistor 550 is provided over a substrate 311 and includes a conductor 316 functioning as a gate electrode, an insulator 315 functioning as a gate insulating film, a semiconductor region 313 functioning as a channel formation region, a low-resistance region 314a functioning as one of a source region and a drain region, and a low-resistance region 314b functioning as the other of the source region and the drain region.

As illustrated in FIG. 12C, in the transistor 550, a top surface and a side surface in the channel width direction of the semiconductor region 313, which is formed of part of the substrate 311, are covered with the conductor 316 with the insulator 315 therebetween.

Such a Fin-type transistor 550 can have an increased effective channel width and thus have improved on-state characteristics. In addition, contribution of an electric field of a gate electrode can be increased, so that the off-state characteristics of the transistor 550 can be improved.

Note that the transistor 550 may be either a p-channel transistor or an n-channel transistor. For example, by electrically connecting a gate of the n-channel transistor 550 and a gate of the p-channel transistor 550, a CMOS circuit (e.g., a circuit that operates complementarily, a CMOS logic gate, or a CMOS logic circuit) can be formed.

The transistor 550 preferably contains a semiconductor such as a silicon-based semiconductor, further preferably contains single crystal silicon in a region of the semiconductor region 313 where a channel is formed, a region in the vicinity thereof, the low-resistance region 314a functioning as one of the source region and the drain region, the low-resistance region 314b functioning as the other of the source region and the drain region, and the like, for example. Alternatively, the transistor 550 may be formed using a material containing germanium, silicon germanium, gallium arsenide, gallium aluminum arsenide, or the like, for example. Alternatively, the transistor 550 may contain silicon whose effective mass is controlled by applying stress to the crystal lattice and thereby changing the lattice spacing. Alternatively, the transistor 550 may be a high electron mobility transistor (HEMT) using gallium arsenide, gallium aluminum arsenide, or the like, for example.

The low-resistance region 314a and the low-resistance region 314b contain an element that imparts n-type conductivity, such as arsenic or phosphorus, or an element that imparts p-type conductivity, such as boron, for example, in addition to a semiconductor material used for the semiconductor region 313.

As the conductor 316, a semiconductor material such as silicon containing the element that imparts n-type conductivity, such as arsenic or phosphorus, or the element that imparts p-type conductivity, such as boron, can be used, for example. Alternatively, a conductive material such as a metal material, an alloy material, or a metal oxide material can be used, for example.

Note that since the work function depends on the material of a conductor, the threshold voltage of the transistor can be adjusted by selecting the material of the conductor.

A material such as titanium nitride or tantalum nitride is preferably used as the conductor 316, for example. Furthermore, in order to ensure both conductivity and embeddability, it is preferable to use stacked layers of metal materials such as tungsten and aluminum. It is particularly preferable to use tungsten in stacked layers in terms of heat resistance.

An insulator 320, an insulator 322, an insulator 324, and an insulator 326 are sequentially stacked and provided to cover the transistor 550.

As the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride can be used, for example. It is particularly preferably to use silicon oxide or silicon oxynitride in terms of thermal stability.

In this specification and the like, silicon oxynitride refers to a material that has a higher oxygen content than a nitrogen content, and silicon nitride oxide refers to a material that has a higher nitrogen content than an oxygen content. Moreover, in this specification and the like, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, the top surface of the insulator 322 may be planarized by planarization treatment using a chemical mechanical polishing (CMP) method or the like to improve planarity.

In addition, for the insulator 324, it is preferable to use an insulator having a barrier property that prevents diffusion of hydrogen, impurities, or the like from the substrate 311, the transistor 550, or the like into a region where the transistor 500 is provided.

As the insulator having a barrier property against hydrogen, silicon nitride formed by a CVD method can be used, for example. For the insulating layer 354, a metal oxide such as aluminum oxide, hafnium oxide, or tantalum oxide can be used, for example.

Here, for example, diffusion of hydrogen into a semiconductor element including an oxide semiconductor, such as the transistor 500, degrades the characteristics of the semiconductor element in some cases. Thus, an insulator that inhibits diffusion of hydrogen is preferably used between the transistor 500 and the transistor 550. The insulator that inhibits hydrogen diffusion is specifically an insulator from which a small amount of hydrogen is released.

The dielectric constant of the insulator 326 is preferably lower than that of the insulator 324. For example, the relative permittivity of the insulator 326 is preferably lower than 4, further preferably lower than 3. In addition, the relative permittivity of the insulator 326 is, for example, preferably lower than or equal to 0.7 times, further preferably lower than or equal to 0.6 times the relative permittivity of the insulator 326. When a material with a low dielectric constant is used for an interlayer film, parasitic capacitance generated between wirings can be reduced.

A conductor (e.g., a conductor 328 and a conductor 330) is embedded in the insulator 320, the insulator 322, the insulator 324, and the insulator 326.

The conductor 328 and the conductor 330 each have a function of a plug or a wiring.

In this specification and the like, a plurality of structures of conductors functioning as plugs or wirings are collectively denoted by the same reference numeral in some cases. Furthermore, a wiring and a plug may be a single component. That is, part of a conductor functions as a wiring in some cases and part of a conductor functions as a plug in other cases.

For each of the plugs or the wirings (e.g., the conductor 328, the conductor 330, and the like), a single layer or stacked layers of a conductive material such as a metal material, an alloy material, a metal nitride material, or a metal oxide material can be used, for example.

It is particularly preferable to use, as each of the plugs or wiring, a high-melting-point material that has both heat resistance and conductivity. As such a material, tungsten, molybdenum, copper, or the like can be used, for example. Furthermore, as each of the plugs or wirings, a low-resistance conductive material that can reduce wiring resistance is preferably used. As such a material, aluminum, copper, or the like can be used, for example.

A wiring layer may be provided over the insulator 326 and the conductor 330. For example, in FIG. 11, an insulator 350_1, an insulator 352_1, and an insulator 354_1 are sequentially stacked and provided. Furthermore, a conductor 356_1 is embedded in the insulator 350_1, the insulator 352_1, and the insulator 354_1.

The conductor 356_1 functions as a plug or a wiring. The conductor 356_1 can be formed using a material similar to those for the conductor 328, the conductor 330, or the like, for example. It is particularly preferable to use a conductor having a barrier property against hydrogen.

As the insulator 350_1, the insulator 352_1, and the insulator 354_1, materials similar to those of the insulator 324, the insulator 322, the insulator 326, and the like can be used, for example. It is particularly preferable to use an insulator having a barrier property against hydrogen.

Here, the conductor having a barrier property against hydrogen is formed in an opening included in the insulator 350_1 having a barrier property against hydrogen. With this structure, the transistor 550 and the transistor 500 can be separated by the conductor having a barrier property against hydrogen. Thus, diffusion of hydrogen from the transistor 550 into the transistor 500 can be inhibited.

For the conductor having a barrier property against hydrogen, tantalum nitride or the like may be used, for example. Stacked layers of tantalum nitride and tungsten, which has high conductivity, may be used. When the conductor is stacked layers of tantalum nitride and tungsten, the conductor can inhibit diffusion of hydrogen while the conductivity as a wiring is ensured.

In other words, when the conductor 356_1 is stacked layers of tantalum nitride and tungsten, the conductor 356_1 can inhibit diffusion of hydrogen from the transistor 550 while the conductivity as a wiring is ensured. In that case, the tantalum nitride layer of the conductor 356_1 having a barrier property against hydrogen is preferably in contact with the insulator 350_1 having a barrier property against hydrogen.

A wiring layer may be provided over the insulator 354_1 and the conductor 356_1. For example, in FIG. 11, an insulator 350_2, an insulator 352_2, and an insulator 354_2 are sequentially stacked and provided. Furthermore, a conductor 356_2 is embedded in the insulator 350_2, the insulator 352_2, and the insulator 354_2.

The conductor 356 2 functions as a plug or a wiring. As the conductor 356_2, a material similar to that of the conductor 356_1 or the like can be used, for example. It is particularly preferable that a conductor having a barrier property against hydrogen be contained.

As the insulator 350_2, the insulator 352_2, and the insulator 354_2, materials similar to those of the insulator 350_1, the insulator 352_1, the insulator 354_1, and the like can be used, for example. It is particularly preferable to use an insulator having a barrier property against hydrogen.

A wiring layer may be provided over the insulator 354_2 and the conductor 356_2. For example, in FIG. 11, an insulator 350_3, an insulator 352_3, and an insulator 354_3 are sequentially stacked and provided. Furthermore, a conductor 356_3 is embedded in the insulator 350_3, the insulator 352_3, and the insulator 354_3.

The conductor 356_3 functions as a plug or a wiring. As the conductor 356_3, a material similar to that of the conductor 356_1 or the like can be used, for example. It is particularly preferable that a conductor having a barrier property against hydrogen be contained.

As the insulator 350_3, the insulator 352_3, and the insulator 354_3, materials similar to those of the insulator 350_1, the insulator 352_1, the insulator 354_1, and the like can be used, for example. It is particularly preferable to use an insulator having a barrier property against hydrogen.

A wiring layer may be provided over the insulator 354_3 and the conductor 356_3. For example, in FIG. 11, an insulator 350_4, an insulator 352_4, and an insulator 354_4 are sequentially stacked and provided. Furthermore, a conductor 356_4 is embedded in the insulator 350_4, the insulator 352_4, and the insulator 354_4.

The conductor 356 4 functions as a plug or a wiring. As the conductor 356_4, a material similar to that of the conductor 356_1 or the like can be used, for example. It is particularly preferable that a conductor having a barrier property against hydrogen be contained.

As the insulator 350_4, the insulator 352_4, and the insulator 354_4, materials similar to those of the insulator 350_1, the insulator 352_1, the insulator 354_1, and the like can be used, for example. It is particularly preferable to use an insulator having a barrier property against hydrogen.

Although an example in which four wiring layers which are each similar to the wiring layer including the conductor 356_1 are provided is described here, there is no limitation thereto. No wiring layer including the conductor 356_1 may be provided, three or less wiring layers which are each similar to the wiring layer including the conductor 356_1 may be provided, or five or more wiring layers which are each similar to the wiring layer including the conductor 356_1 may be provided.

Note that the transistor 550 illustrated in FIG. 11 is an example and the structure is not limited thereto.

### Transistor 500

Next, a structure of a transistor that can be used as the transistor 500 provided over the insulator 354_4 will be described with reference to the transistor 500 illustrated in FIG. 11, FIG. 12A, and FIG. 12B.

As illustrated in FIG. 11, an insulator 510, an insulator 512, an insulator 514, and an insulator 516 are provided to be stacked in this order over the insulator 354_4.

An insulator having a barrier property against oxygen, hydrogen, or the like is preferably used for any of the insulator 510, the insulator 512, the insulator 514, and the insulator 516.

For example, for the insulator 510 and the insulator 514, it is preferable to use an insulator having a barrier property that prevents diffusion of hydrogen, impurities, or the like from the substrate 311, a region where the transistor 550 is provided, or the like into a region where the transistor 500 is provided. For the insulator 510 and the insulator 514, a material similar to that for the insulator 324 or the like can be used, for example.

For the insulator having a barrier property against hydrogen, a metal oxide such as aluminum oxide, hafnium oxide, or tantalum oxide is preferably used, for example.

Aluminum oxide especially has a high barrier property against both oxygen and impurities such as hydrogen and water. Accordingly, aluminum oxide can prevent entry of impurities such as hydrogen and water into the transistor 500 during and after the manufacturing of the transistor, and can inhibit release of oxygen from the oxide included in the transistor 500. Thus, aluminum oxide is suitably used for a protective film of the transistor 500.

Using a material with a relatively low permittivity for the insulator 512 and the insulator 516 can reduce the parasitic capacitance generated between wirings. For the insulator 512 and the insulator 516, a material similar to that for the insulator 326 or the like can be used, for example.

A conductor 518, a conductor included in the transistor 500 (e.g., a conductor 503 illustrated in FIG. 12A or the like), and the like are embedded in the insulator 510, the insulator 512, the insulator 514, and the insulator 516, for example.

The conductor 518 has a function of a plug or a wiring. The conductor 518 can be formed using a material similar to those for the conductor 328, the conductor 330, and the like, for example.

In particular, the conductor 518 in regions in contact with the insulator 510 and the insulator 514 is preferably a conductor having a barrier property against both oxygen and impurities such as hydrogen and water. With such a structure, the transistor 550 and the transistor 500 can be separated by a conductor having a barrier property against both oxygen and impurities such as hydrogen and water; thus, diffusion of hydrogen from the transistor 550 into the transistor 500 can be inhibited.

The transistor 500 is provided above the insulator 516.

As illustrated in FIG. 12A and FIG. 12B, the transistor 500 includes the conductor 503 placed to be embedded in the insulator 514 and the insulator 516, an insulator 522 placed over the insulator 516 and the conductor 503, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and is provided with an opening formed to overlap with a region between the conductor 542a and the conductor 542b, an insulator 545 placed along the opening, and a conductor 560 placed on a formation surface of the insulator 545.

Note that the oxide 530a and the oxide 530b are sometimes collectively referred to as an oxide 530. The oxide 530 has a function of a semiconductor film including a channel formation region of the transistor 500.

The conductor 503 is placed to overlap with the oxide 530 and the conductor 560.

Here, the conductor 503 preferably includes a conductor 503a provided to be in contact with the insulator 514 and the insulator 516 and a conductor 503b provided to be embedded inside the conductor 503a. An insulator 544 is preferably placed between the insulator 580 and the oxide 530a, the oxide 530b, the conductor 542a, and the conductor 542b. The conductor 560 preferably includes a conductor 560a provided inside the insulator 545 and a conductor 560b provided to be embedded inside the conductor 560a. An insulator 582 is preferably placed over the insulator 580, the conductor 560, and the insulator 545.

Although the transistor 500 illustrated in FIG. 12A and FIG. 12B has a structure in which two layers of the conductor 503a and the conductor 503b are stacked as the conductor 503, one embodiment of the present invention is not limited thereto. For example, the conductor 503 may have a single-layer structure or a stacked-layer structure of three or more layers.

Although end portions of the conductor 542a and the conductor 542b and end portions of the oxide 530 are aligned with each other in the illustrated structure, there is not limitation thereto. For example, the conductor 542a and the conductor 542b may extend beyond the end portions of the oxide 530.

Although the oxide 530 having a structure in which two layers of the oxide 530a and the oxide 530b are stacked is illustrated, the oxide 530 is not limited thereto. For example, the oxide 530 may have a single-layer structure or a stacked-layer structure of three or more layers.

Although the conductor 560 having a structure in which two layers of the conductor 560a and the conductor 560b are stacked is illustrated, the conductor 560 is not limited thereto. For example, the conductor 560 may have a single-layer structure or a stacked-layer structure of three or more layers.

Here, in the transistor 500, the conductor 560 has a function of a gate electrode, the insulator 545 has a function of a gate insulating film, and the conductor 542a and the conductor 542b each have a function of one or the other of a source electrode and a drain electrode.

As described above, the conductor 560 is formed to be embedded in an opening formed in a region that is of the insulator 580 and sandwiched between the conductor 542a and the conductor 542b (the opening is also referred to as an opening of the insulator 580 in some cases). Thus, the placement of the conductor 560, the conductor 542a, and the conductor 542b with respect to the opening of the insulator 580 is selected in a self-aligned manner. That is, in the transistor 500, the gate electrode can be placed between the source electrode and the drain electrode in a self-aligned manner. With this structure, the conductor 560 can be formed without an alignment margin. Hence, the area occupied by the transistor 500 can be reduced. Accordingly, miniaturization and high integration of the semiconductor device can be achieved.

Since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. Thus, the switching speed of the transistor 500 can be improved. Accordingly, frequency characteristics of the semiconductor device can be improved.

A shorter gate length of the transistor 500 is required for miniaturization of the semiconductor device, but in that case it is necessary to prevent a reduction in the conductivity of the conductor 560. When the conductor 560 is made thick to achieve this, the conductor 560 might have a shape with a high aspect ratio. Providing the conductor 560 such that the conductor 560 is embedded in the opening of the insulator 580 enables the conductor 560 having a shape with a high aspect ratio to be formed without collapsing during the process.

Here, the conductor 560 has a function of a first gate (also simply referred to as a top gate) electrode and the conductor 503 has a function of a second gate (also referred to a back gate) electrode, in some cases. In that case, the insulator 545 has a function of a first gate insulating film, and the insulator 522 and the insulator 524 have a function of a second gate insulating film.

As described above, the conductor 503 is placed to overlap with the oxide 530 and the conductor 560. Thus, when a potential is applied to the conductor 560 and the conductor 503, an electric field generated from the conductor 560 and an electric field generated from the conductor 503 are connected, so that the channel formation region formed in the oxide 530 can be covered.

In that case, in the transistor 500, by changing a potential applied to the conductor 503 independently of a potential applied to the conductor 560, the threshold voltage of the transistor 500 can be controlled, for example. In particular, when a negative potential is applied to the conductor 503, the threshold voltage of the transistor 500 can be increased, and the off-state current can be reduced. Thus, for example, by applying a negative potential to the conductor 503, a drain current at the time when the potential applied to the conductor 560 is 0 V (sometimes referred to as a cutoff current) can be reduced.

In this specification and the like, a transistor structure in which a channel formation region is electrically surrounded by an electric field of a gate electrode is referred to as a surrounded channel (S-channel) structure. The S-channel structure disclosed in this specification and the like can be regarded as having a structure different from a Fin-type structure or a planar structure. Meanwhile, the S-channel structure disclosed in this specification and the like can be regarded as a kind of a Fin-type structure or a kind of a planar structure. In this specification and the like, a Fin-type structure refers to a structure in which at least two surfaces (specifically, two surfaces, three surfaces, four surfaces, or the like) of a channel are covered with a gate electrode. With the use of a Fin-type structure and an S-channel structure, a transistor with high resistance to a short-channel effect can be obtained. In other words, a transistor in which a short-channel effect is unlikely to occur can be obtained.

When the transistor has the above-described S-channel structure, the channel formation region can be electrically surrounded by an electric field of a gate electrode. Since the S-channel structure is a structure with the channel formation region electrically surrounded by an electric field of a gate electrode, the S-channel structure is, in a sense, equivalent to a GAA (Gate All Around) structure or an LGAA (Lateral Gate All Around) structure. When the transistor has an S-channel structure, a GAA structure, or an LGAA structure, the channel formation region that is formed at the interface between the semiconductor film and the gate insulating film or in the vicinity of the interface can be formed in the entire bulk of the semiconductor film. Accordingly, the density of current flowing through the transistor can be improved, which can be expected to improve the on-state current of the transistor or increase the field-effect mobility of the transistor.

In addition, the conductor 503 has a structure similar to that of the conductor 518; as described above, the conductor 503a is formed in contact with the insulator 514 and the insulator 516, and the conductor 503b is formed on the inner side.

As the conductor 503a, a conductive material having a barrier property against impurities such as hydrogen (e.g., at least one of a hydrogen atom, a hydrogen molecule, and the like), water, and copper (a conductive material having a function of inhibiting diffusion of the impurities; i.e., a conductive material through which the impurities do not easily pass) is preferably used, for example. As the conductor 503a, a conductive material having a barrier property against oxygen (e.g., at least one of an oxygen atom, an oxygen molecule, and the like) (a conductive material having a function of inhibiting diffusion of oxygen; i.e., a conductive material through which oxygen does not easily pass) is preferably used. That is, the conductor 503a preferably has a barrier property against either one or all of the above impurities and the above oxygen.

When the conductor 503a has a barrier property against oxygen as described above, a reduction in the conductivity of the conductor 503b due to oxidation can be inhibited, for example. Thus, the conductor 503 can also have a function of a wiring.

In that case, a conductive material having high conductivity is preferably used as the conductor 503b. For example, a conductive material containing tungsten, copper, or aluminum as its main component can be used.

Here, as the insulator in contact with the oxide 530, an insulator that contains oxygen more than oxygen in the stoichiometric composition is preferably used. Such oxygen is easily released from the insulator by heating. In this specification and the like, oxygen released by heating is sometimes referred to as “excess oxygen”.

The insulator 524 is in contact with the oxide 530. Thus, a region containing excess oxygen (also referred to as an “excess-oxygen region”) is preferably formed in the insulator 524.

When such an insulator containing excess oxygen is provided to be in contact with the oxide 530, oxygen vacancies (also referred to as V_{O}) in the oxide 530 can be reduced and the reliability of the transistor 500 can be increased.

In the oxide 530, defects of oxygen vacancies which hydrogen enters in the oxide 530 (hereinafter, sometimes referred to as V_{O}H) serve as donors and generate electrons serving as carriers in some cases. In other cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in an oxide semiconductor is easily transferred by a stress such as heat or an electric field, for example; thus, a large amount of hydrogen in an oxide semiconductor might reduce the reliability of a transistor. In one embodiment of the present invention, V_{O}H in the oxide 530 is preferably reduced as much as possible so that the oxide 530 becomes a highly purified intrinsic or substantially highly purified intrinsic oxide.

It is important to remove impurities such as hydrogen and water in an oxide semiconductor (this treatment is also referred to as “dehydration” or “dehydrogenation treatment”) and to compensate for oxygen vacancies by supplying oxygen to the oxide semiconductor (this treatment is also referred to as “oxygen adding treatment”) in order to obtain an oxide semiconductor whose V_{O}H is sufficiently reduced. For example, when an oxide semiconductor with sufficiently reduced impurities such as V_{O}H is used for a channel formation region of a transistor, stable electrical characteristics can be given.

Moreover, in the case where the insulator 524 includes an excess-oxygen region, the insulator 522 preferably has a barrier property against oxygen. When the insulator 522 has a barrier property against oxygen, impurities, and the like, diffusion of oxygen contained in the oxide 530 to the insulator 516 side can be inhibited, for example. Furthermore, for example, the conductor 503 can be inhibited from reacting with oxygen included in the insulator 524, the oxide 530, and the like.

Here, it is preferable in a transistor using an oxide semiconductor in a semiconductor film that a channel formation region of the transistor include fewer oxygen vacancies or have a lower concentration of impurities (e.g., concentration of hydrogen, nitrogen, a metal element, and the like) than a source region and a drain region. In addition, in some cases, V_{O}H is formed with hydrogen in the vicinity of an oxygen vacancy and an electron serving as a carrier is generated; therefore, it is also preferable that the amount of V_{O}H be small. Hence, the channel formation region of the transistor is a high-resistance region having a low carrier concentration. Accordingly, the channel formation region of the transistor can be regarded as an i-type (intrinsic) or substantially i-type region.

The source region and the drain region of the transistor preferably include more oxygen vacancies, include more V_{O}H, or have a higher impurity concentration than the channel formation region. Thus, the source region and the drain region of the transistor are n-type regions that have a higher carrier concentration and a lower resistance than the channel formation region.

The metal oxide used as the oxide semiconductor preferably has a band gap of 2 eV or higher, further preferably 2.5 eV or higher. With the use of a metal oxide having a wide band gap as the oxide semiconductor, the off-state current of the transistor can be reduced.

As the insulator 522, an insulator of a high dielectric constant (high-k) material (a material with a high relative permittivity) is preferably used.

As miniaturization and high integration of transistors progress, a problem such as gate leakage current sometimes arises because of a thin gate insulating film, for example. When a high-k material is used as an insulator functioning as a gate insulating film, a gate potential during transistor operation can be reduced while the physical thickness is maintained.

As the insulator functioning as a gate insulating film, it is preferable to use a single layer or stacked layers of an insulator containing aluminum oxide, hafnium oxide, an oxide containing aluminum and hafnium (hafnium aluminate), tantalum oxide, zirconium oxide, lead zirconate titanate (PZT), strontium titanate (SrTiO₃), or barium strontium titanate (BST), for example.

An insulator containing an oxide of one or both of aluminum and hafnium is preferably used since it is an insulator having a barrier property against oxygen and impurities. Aluminum oxide, hafnium oxide, an oxide containing aluminum and hafnium (hafnium aluminate), or the like is preferably used as the insulator, for example.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators having been subjected to nitriding treatment may be used. Stacked layers in which silicon oxide, silicon oxynitride, or silicon nitride is stacked over these insulators may be used.

In the case where the insulator 522 is formed using such a material, the insulator 522 can function as an insulator that inhibits release of oxygen from the oxide 530 and mixing of impurities such as hydrogen from the periphery of the transistor 500 into the oxide 530.

Although the transistor 500 illustrated in FIG. 12A and FIG. 12B has a structure in which two layers of the insulator 522 and the insulator 524 are stacked as the second gate insulating film, there is no limitation thereto. For example, a single-layer structure or a stacked-layer structure of three or more layers may be employed. In that case, either a structure in which the same materials are stacked or a structure in which different materials are stacked may be employed.

In the transistor 500, a metal oxide functioning as an oxide semiconductor is used as the oxide 530 including a channel formation region. As the oxide semiconductor, a single layer or stacked layers of a metal oxide can be used.

The metal oxide preferably contains at least one of indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin.

It is particularly preferable that an oxide containing indium (In), gallium (Ga), and zinc (Zn) (also referred to as “IGZO”) be used as the metal oxide. Alternatively, an oxide containing indium (In), aluminum (Al), and zinc (Zn) (also referred to as “IAZO”) may be used. Further alternatively, an oxide containing indium (In), aluminum (Al), gallium (Ga), and zinc (Zn) (also referred to as “IAGZO”) may be used. Further alternatively, an oxide containing indium (In), tin (Sn), and zinc (Zn) (also referred to as “ITZO (registered trademark)”) may be used. Further alternatively, an oxide containing indium (In), gallium (Ga), zinc (Zn), and tin (Sn) (also referred to as “IGZTO”) may be used.

When the metal oxide is an In—M—Zn oxide, the proportion of the number of In atoms is preferably higher than or equal to the proportion of the number of M atoms in the In—M—Zn oxide. Examples of the atomic ratio of the metal elements in such an In—M—Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn =5:1:8 or a composition in the neighborhood thereof, In:M:Zn=6:1:6 or a composition in the neighborhood thereof, and In:M:Zn=5:2:5 or a composition in the neighborhood thereof. The proportion of the number of In atoms may be lower than the proportion of the number of M atoms in the In—M—Zn oxide. Examples of the atomic ratio of the metal elements in such an In—M—Zn oxide include In:M:Zn=1:3:2 or a composition in the neighborhood thereof and In:M:Zn=1:3:4 or a composition in the neighborhood thereof. Note that a composition in the neighborhood includes the range of ±30 % of an intended atomic ratio.

For example, when the atomic ratio is described as In:Ga:Zn=4:2:3 or a composition in the neighborhood thereof, the case is included where the content ratio of each element is as follows: Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where the content ratio of each element is as follows: Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where the content ratio of each element is as follows: Ga is greater than 0.1 and less than or equal to 2 and Zn is greater than 0.1 and less than or equal to 2 with In being 1.

In the case where stacked metal oxides are used, for example, a three-layer stacked structure in which a metal oxide where the atomic ratio of metal elements is In:Ga:Zn=1:1:1 is a first layer, a metal oxide where the atomic ratio of metal elements is In: Zn=4:1 is a second layer, and a metal oxide where the atomic ratio of metal elements is In:Ga:Zn=1:1:1 is a third layer can be employed. Note that the band gaps of the first-layer and third-layer metal oxides are preferably larger than the band gap of the second-layer metal oxide. With this structure, the main current path can be the second-layer metal oxide, so that what is called a buried channel structure can be obtained.

A sputtering method or an atomic layer deposition (ALD) method can be used for forming the metal oxide. In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The oxide semiconductor preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single crystal oxide semiconductor. As the oxide semiconductor, the CAAC-OS or the nc-OS is preferably used, and the CAAC-OS is particularly preferably used.

The CAAC-OS preferably includes a plurality of layered crystal regions and the c-axis is preferably aligned in a normal direction of a surface where the CAAC-OS is deposited. For example, the oxide semiconductor preferably includes layered crystals parallel or substantially parallel to the formation surface. With this structure, the layered crystals of the oxide semiconductor are formed parallel or substantially parallel to the channel length direction of the transistor, so that the on-state current of the transistor can be increased.

In the oxide 530, the oxide 530a is provided under the oxide 530b. This can inhibit diffusion of impurities into the oxide 530b from the components formed below the oxide 530a.

The oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a junction portion of the oxide 530a and the oxide 530b. In other words, the energy level of the conduction band minimum at the junction portion of the oxide 530a and the oxide 530b continuously changes or is continuously connected. To change the energy level gradually, the density of defect states in a mixed layer formed at an interface between the oxide 530a and the oxide 530b may be made low.

Specifically, when the oxide 530a and the oxide 530b include a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like can be used as the oxide 530b.

At this time, the oxide 530b serves as a main carrier path. When the oxide 530a has the above-described structure, the density of defect states at the interface between the oxide 530a and the oxide 530b can be made low. Thus, the influence of interface scattering on carrier conduction is small, and the transistor 500 can have an increased on-state current.

The conductor 542a and the conductor 542b functioning as the source electrode and the drain electrode are provided over the oxide 530b.

For the conductor 542a and the conductor 542b, for example, it is possible to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of these metal elements as its component; an alloy containing a combination of these metal elements; or the like. For example, it is particularly preferable to use tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like, which are each a conductive material that is not easily oxidized or a material that maintains its conductivity even after absorbing oxygen. Moreover, in terms of having a barrier property against oxygen, hydrogen, and the like, a metal nitride film of tantalum nitride or the like is preferably used, for example.

Although the transistor 500 illustrated in FIG. 12A and FIG. 12B has a structure in which the conductor 542a and the conductor 542b have a single-layer structure, there is no limitation thereto. The conductor 542a and the conductor 542b may have a structure in which two or more layers are stacked, for example.

For the conductor 542a and the conductor 542b, a structure in which a tantalum nitride film and a tungsten film are stacked, a structure in which a titanium film and an aluminum film are stacked, a structure in which an aluminum film is stacked over a tungsten film, a structure in which a copper film is stacked over a copper-magnesium-aluminum alloy film, a structure in which a copper film is stacked over a titanium film, or a structure in which a copper film is stacked over a tungsten film may be employed, for example.

For another example, the conductor 542a and the conductor 542b may each have a three-layer structure in which an aluminum film or a copper film is stacked over a titanium film or a titanium nitride film and a titanium film or a titanium nitride film is stacked thereover, a three-layer structure in which an aluminum film or a copper film is stacked over a molybdenum film or a molybdenum nitride film and a molybdenum film or a molybdenum nitride film is stacked thereover, or the like.

Note that a transparent conductive material containing indium oxide, tin oxide, or zinc oxide may be used for the conductor 542a and the conductor 542b, for example.

Here, as illustrated in FIG. 12A, a region 543a is sometimes formed at and in the vicinity of the interface with the conductor 542a in the oxide 530, as a low-resistance region. In addition, a region 543b is sometimes formed at and in the vicinity of the interface with the conductor 542b in the oxide 530, as a low-resistance region. In that case, the region 543a functions as one of a source region and a drain region, and the region 543b functions as the other of the source region and the drain region. A channel formation region is formed in a region sandwiched between the region 543a and the region 543b.

When the conductor 542a and the conductor 542b are provided in contact with the oxide 530 in this manner, the oxygen concentration in each of the region 543a and the region 543b sometimes decreases. In addition, a metal compound layer that includes the metal included in the conductor 542a and the conductor 542b and the component of the oxide 530 is sometimes formed in the region 543a and the region 543b. In such a case, the carrier concentration in the region 543a and the region 543b increases, and the region 543a and the region 543b become low-resistance regions.

The insulator 544 is provided to cover the conductor 542a and the conductor 542b and inhibits oxidation of the conductor 542a and the conductor 542b. In that case, the insulator 544 may be provided to cover the side surface of the oxide 530 and the side surface of the insulator 524 and to be in contact with the insulator 522.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used for the insulator 544, for example. It is also possible to use silicon nitride oxide, silicon nitride, or the like, for example.

Alternatively, an insulator containing an oxide of one or both of aluminum and hafnium may be used. Aluminum oxide, hafnium oxide, an oxide containing aluminum and hafnium (hafnium aluminate), or the like can be used, for example. For example, it is particularly preferable to use hafnium aluminate because it has high heat resistance and is unlikely to be crystallized by heat treatment in a later step.

Note that the insulator 544 is not necessarily provided when the conductor 542a and the conductor 542b are oxidation-resistant materials or materials that do not significantly lose their conductivity even after absorbing oxygen.

The insulator 544 can inhibit impurities such as water and hydrogen contained in the insulator 580 from diffusing into the oxide 530b. In addition, oxidation of the conductor 542a and the conductor 542b due to excess oxygen contained in the insulator 580 can be inhibited.

Like the above-described insulator 524, the insulator 545 is preferably formed using an insulator that contains excess oxygen and releases oxygen by heating. This allows oxygen to be effectively supplied to the channel formation region of the oxide 530b from the insulator 545.

Specifically, as the insulator 545, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used, for example. In particular, silicon oxide or silicon oxynitride having thermal stability is preferably used.

As the insulator 545, as in the above-described insulator 524, an insulator having a reduced concentration of impurities such as hydrogen and water in the insulator 545 is preferably used. Note that the thickness of the insulator 545 is preferably greater than or equal to 1 nm and less than or equal to 20 nm.

Here, in order that excess oxygen contained in the insulator 545 can be efficiently supplied to the oxide 530, a metal oxide may be provided between the insulator 545 and the conductor 560. The metal oxide preferably has a barrier property against oxygen. Accordingly, diffusion of excess oxygen from the insulator 545 into the conductor 560 is inhibited. Thus, a reduction in the amount of excess oxygen supplied to the oxide 530 can be inhibited. Moreover, oxidation of the conductor 560 due to excess oxygen can be inhibited. As the metal oxide, a material that can be used for the insulator 544 may be used, for example.

Although the transistor 500 illustrated in FIG. 12A and FIG. 12B has a structure in which the insulator 545 is a single layer, there is no limitation thereto. For example, the insulator 545 functioning as the first gate insulating film may have a structure in which two or more layers are stacked, like the insulator 522 and the insulator 524 functioning as the second gate insulating film. For example, the insulator 545 may have a structure in which a high-k material and a thermally stable material are stacked. This can reduce the gate voltage during the operation of the transistor 500 while keeping the physical thickness of the insulator 545.

As the conductor 560a included in the conductor 560, a conductive material having a barrier property against impurities such as hydrogen, water, nitrogen, nitrogen oxide (e.g., N₂O, NO, and NO₂), and copper is preferably used, for example. Furthermore, a conductive material having a barrier property against oxygen is preferably used. When the conductor 560a has a barrier property against oxygen, it is possible to inhibit a reduction in conductivity of the conductor 560b due to oxidation caused by oxygen contained in the insulator 545.

As a conductive material having a barrier property against oxygen, tantalum, tantalum nitride, ruthenium, ruthenium oxide, or the like is preferably used, for example.

As the conductor 560a, an oxide semiconductor that can be used as the oxide 530 can be used. In that case, by depositing the conductor 560b by a sputtering method, the conductor 560a can have a reduced electrical resistance value to become a conductor. Such a conductor can be referred to as an OC (Oxide Conductor) electrode.

The conductor 560 can also have a function of a wiring. Thus, as the conductor 560b, a conductive material having high conductivity, is preferably used as in the conductor 503b. For example, a conductive material containing tungsten, copper, or aluminum as its main component can be used.

Note that the conductor 560b may have a structure in which different materials are stacked. For example, a structure in which titanium or titanium nitride and the above conductive material are stacked may be employed.

The insulator 580 is provided over the conductor 542a and the conductor 542b with the insulator 544 therebetween.

The insulator 580 preferably includes an excess-oxygen region.

For example, as the insulator 580, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like can be used. It is particularly preferably to use silicon oxide or silicon oxynitride in terms of thermal stability. Moreover, it is preferable to use silicon oxide or porous silicon oxide, in which case an excess-oxygen region can be easily formed in a later step.

In the case where the insulator 580 including an excess-oxygen region is provided, oxygen is released by heating, so that oxygen in the insulator 580 can be efficiently supplied to the oxide 530. The concentration of impurities such as hydrogen and water in the insulator 580 is preferably lowered.

The insulator 582 is preferably provided in contact with the top surface of the insulator 580, the top surface of the conductor 560, and the top surface of the insulator 545. When the insulator 582 is deposited by a sputtering method, excess-oxygen regions can be provided in the insulator 545 and the insulator 580. Accordingly, oxygen can be supplied from the excess-oxygen regions to the oxide 530.

A metal oxide containing one kind or two or more kinds selected from hafnium, aluminum, gallium, yttrium, zirconium, tungsten, titanium, tantalum, nickel, germanium, magnesium, and the like can be used as the insulator 582, for example.

In particular, aluminum oxide has a high barrier property against impurities such as hydrogen, and even a thin aluminum oxide film having a thickness greater than or equal to 0.5 nm and less than or equal to 3.0 nm can inhibit diffusion of impurities such as hydrogen. Accordingly, aluminum oxide deposited by a sputtering method has a function of an oxygen supply source and can also have a function of an insulator having a barrier property against impurities such as hydrogen.

An insulator 584 functioning as an interlayer film is preferably provided over the insulator 582. As in the insulator 524 or the like, the insulator 584 preferably has a reduced concentration of impurities such as hydrogen and water, for example.

A conductor 540a and a conductor 540b are provided in openings formed in the insulator 584, the insulator 582, the insulator 580, and the insulator 544. In this case, the conductor 540a and the conductor 540b are provided to face each other with the conductor 560 therebetween. The conductor 540a and the conductor 540b each have a structure similar to that of a conductor 546 described later.

An insulator 586 is provided over the insulator 584.

The insulating material having a barrier property against oxygen, hydrogen, and the like is preferably used as the insulator 586. As the insulator 586, a material similar to that of the insulator 324, the insulator 514, or the like can be used, for example.

An insulator 588 is provided over the insulator 586.

When a material with a relatively low dielectric constant is used for the insulator 588, parasitic capacitance between wirings can be reduced, for example. As the insulator 588, a material similar to that of the insulator 320, the insulator 512, the insulator 516, or the like can be used, for example.

The conductor 546 and the like are embedded in the insulator 522, the insulator 524, the insulator 544, the insulator 580, the insulator 582, the insulator 584, the insulator 586, and the insulator 588, for example.

The conductor 546 has a function of a plug or a wiring. As the conductor 546, a material similar to that of the conductor 328 and the conductor 330, the conductor 518, or the like can be used, for example.

Note that after the transistor 500 is formed, an opening may be formed to surround the transistor 500 and an insulator having a high barrier property against hydrogen and water may be formed to cover the opening. Surrounding the transistor 500 by the insulator having a high barrier property can prevent entry of hydrogen and water from the outside. Alternatively, a plurality of the transistors 500 may be collectively surrounded by the insulator having a high barrier property against hydrogen or water. When an opening is formed to surround the transistor 500, for example, an opening reaching the insulator 522 or the insulator 514 may be formed, and the insulator having a high barrier property may be formed to be in contact with the insulator 522 or the insulator 514. In this way, these formation steps can also serve as some of the manufacturing steps of the transistor 500. As the insulator having a high barrier property against hydrogen and water, a material similar to that of the insulator 522, the insulator 514, or the like may be used, for example.

### Capacitor 590

As illustrated in FIG. 11, the capacitor 590 is provided above the transistor 500. The capacitor 590 includes a conductor 591 over the conductor 546, an insulator 592 over the conductor 591, and a conductor 593 over the insulator 592. The conductor 593 functions as one of a pair of electrodes (sometimes referred to as an upper electrode), the conductor 591 functions as the other of the pair of electrodes (sometimes referred to as a lower electrode), and the insulator 592 functions as a dielectric. That is, the capacitor 590 forms a MIM (Metal-Insulator-Metal) capacitor.

A conductor 594 may be provided over the conductor 546. The conductor 594 has a function of a plug or a wiring. The conductor 591 has a function of an electrode of the capacitor 590. Note that the conductor 594 and the conductor 591 can be formed in the same process.

For the conductor 594 and the conductor 591, a metal film containing an element selected from molybdenum, titanium, tantalum, tungsten, aluminum, copper, chromium, neodymium, and scandium; or a metal nitride film containing any of the above elements as its component (a tantalum nitride film, a titanium nitride film, a molybdenum nitride film, or a tungsten nitride film) can be used, for example. Alternatively, for example, it is possible to use indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the capacitor 590 illustrated in FIG. 11 has a structure in which the conductor 594 and the conductor 591 each have a single-layer structure, one embodiment of the present invention is not limited thereto. For example, each of the conductor 594 and the conductor 591 may have a structure in which two or more layers are stacked.

For the conductor, for example, a structure where, between a conductor having a barrier property against hydrogen and a conductor having high conductivity, a conductor that is highly adhesive to both of the conductors is provided may be used.

For the insulator 592, a high dielectric constant (high-k) material (material with a high relative permittivity) is preferably used. Using such a high dielectric constant material as the insulator 592 allows the insulator to be thick enough to inhibit a gate leakage current and a sufficiently high electrostatic capacitance of the capacitor including the insulator to be ensured.

As the insulator of high dielectric constant material, an oxide, an oxynitride, a nitride oxide, or a nitride containing one or more kinds of metal element selected from aluminum, hafnium, zirconium, gallium, and the like can be used, for example. These materials may contain silicon. Stacked insulators formed of any of these materials can also be used.

As the insulator of a high permittivity material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example.

Stacked insulators formed of any of the above materials can also be used. In that case, a structure in which a high dielectric constant material and a material having a higher dielectric strength than the high dielectric constant material are stacked is preferably used.

For example, as the insulator, an insulator in which zirconium oxide, aluminum oxide, and zirconium oxide are stacked in this order can be used, for example. For another example, an insulator in which zirconium oxide, aluminum oxide, zirconium oxide, and aluminum oxide are stacked in this order can be used. Alternatively, an insulator in which hafnium zirconium oxide, aluminum oxide, hafnium zirconium oxide, and aluminum oxide are stacked in this order can be used, for example. The use of stacked insulators with relatively high dielectric strength, such as aluminum oxide, as the insulator can increase the dielectric strength and inhibit electrostatic breakdown of the capacitor including the insulator.

The conductor 593 is provided to overlap with the conductor 591 with the insulator 592 therebetween.

As the conductor 593, a conductive material such as a metal material, an alloy material, or a metal oxide material can be used, for example.

As the conductor 593, a high-melting-point material that has both heat resistance and conductivity is preferably used, for example. As such a material, tungsten, molybdenum, or the like can be used, for example; tungsten is particularly preferably used. In the case where the conductor 593 is formed in the same step as another conductor or the like, for example, copper, aluminum, or the like may be used in terms of being a low-resistance metal material.

An insulator 595 is provided over the conductor 593 and the insulator 592. As the insulator 595, a material similar to that of the insulator 320 or the like can be used, for example. The insulator 595 may have a function of a planarization film that covers roughness due to underlying layers.

### Variation Example of Transistor 500

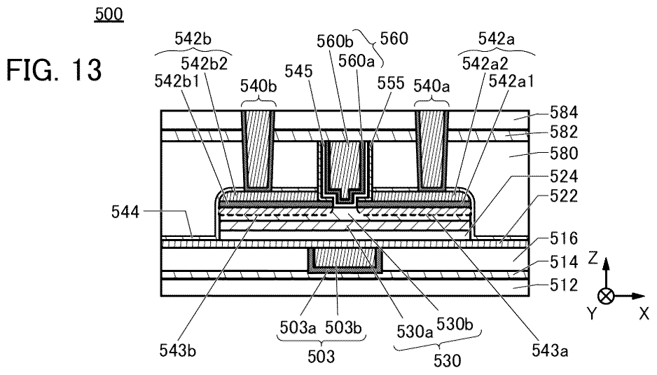

The transistor that can be used in one embodiment of the present invention is not limited to the transistor 500 illustrated in FIG. 12. For example, the transistor 500 having a structure illustrated in FIG. 13 may be used. The transistor 500 illustrated in FIG. 13 is different from the transistor illustrated in FIG. 12 in that an insulator 555 is used and that the conductor 542a and the conductor 542b have a stacked-layer structure.

As illustrated in FIG. 13, the conductor 542a has a stacked-layer structure of a conductor 542a1 and a conductor 542a2 over the conductor 542a1. The conductor 542b has a stacked-layer structure of a conductor 542b1 and a conductor 542b2 over the conductor 542b1.

The conductor 542a1 and the conductor 542b1 in contact with the oxide 530b are preferably conductors that are not easily oxidized, such as a metal nitride, for example. Thus, excessive oxidation of the conductor 542a and the conductor 542b due to oxygen contained in the oxide 530b can be prevented.

In addition, the conductor 542a2 and the conductor 542b2 are preferably conductors that have higher conductivity than the conductor 542a1 and the conductor 542b1. This allows the conductor 542a and the conductor 542b to function as wirings or electrodes having high conductivity.

In this manner, it is possible to provide the conductor 542a and the conductor 542b having a function of wirings or electrodes in contact with the top surface of the oxide 530.

As the conductor 542a1 and the conductor 542b1, a metal nitride is preferably used. It is particularly preferable to use a conductive material that is not easily oxidized or a material that maintains conductivity even after absorbing oxygen.

As the conductor 542a1 and the conductor 542b1, a nitride containing tantalum, a nitride containing titanium, a nitride containing molybdenum, a nitride containing tungsten, a nitride containing tantalum and aluminum, a nitride containing titanium and aluminum, or the like is preferably used, for example. It is particularly preferable to use a nitride containing tantalum. As another example, ruthenium, ruthenium oxide, ruthenium nitride, an oxide containing strontium and ruthenium, an oxide containing lanthanum and nickel, or the like may be used.

In addition, the conductor 542a2 and the conductor 542b2 preferably have higher conductivity than the conductor 542a1 and the conductor 542b1. For example, the film thickness of the conductor 542a2 and the conductor 542b2 is preferably larger than the film thickness of the conductor 542a1 and the conductor 542b1. As the conductor 542a2 and the conductor 542b2, a conductor that can be used as the conductor 560b may be used. With such a structure, resistance of the conductor 542a2 and the conductor 542b2 can be reduced.

For example, tantalum nitride or titanium nitride can be used for the conductor 542a1 and the conductor 542b1, and tungsten can be used for the conductor 542a2 and the conductor 542b2.

As illustrated in FIG. 13, in the transistor 500, the insulator 555 is formed to be in contact with the side surface of an opening formed in the insulator 580 and the insulator 544 and to separate the conductor 542a1 and the conductor 542b1 from each other using a mask. Here, the opening overlaps with a region between the conductor 542a2 and the conductor 542b2. In addition, parts of the conductor 542a1 and the conductor 542b1 are formed to protrude inside the opening. Thus, the insulator 555 is in contact with, in the opening, the top surface of the conductor 542a1, the top surface of the conductor 542b1, the side surface of the conductor 542a2, and the side surface of the conductor 542b2. Furthermore, the insulator 545 is in contact with the top surface of the oxide 530 in a region between the conductor 542a1 and the conductor 542b1.

Thus, in a cross-sectional view in the channel length direction of the transistor 500, the distance between the conductor 542a1 and the conductor 542b1 is shorter than the distance between the conductor 542a2 and the conductor 542b2. With such a structure, the distance between the source and the drain can be shorter and accordingly the channel length can be shortened. Thus, the frequency characteristics of the transistor 500 can be improved. Accordingly, a semiconductor device with an increased operation speed can be provided.

The insulator 555 is preferably an insulator that is not easily oxidized, such as a nitride, for example. The insulator 555 is formed in contact with the side surface of the conductor 542a2 and the side surface of the conductor 542b2 and has a function of protecting the conductor 542a2 and the conductor 542b2. The insulator 555 is preferably an inorganic insulator that is not easily oxidized because it is exposed to an oxidizing atmosphere. Since the insulator 555 is in contact with the conductor 542a2 and the conductor 542b2, the insulator 555 is preferably an inorganic insulator that does not easily oxidize the conductor 542a2 and the conductor 542b2. Thus, an insulator having a barrier property against oxygen is preferably used for the insulator 555.

For example, silicon nitride can be used as the insulator 555.

The transistor 500 illustrated in FIG. 13 is formed by formation of the opening in the insulator 580 and the insulator 544, formation of the insulator 555 in contact with the side surface of the opening, and separation of the conductor 542a1 and the conductor 542b1 with the use of a mask. Here, the opening overlaps with the region between the conductor 542a2 and the conductor 542b2. In addition, parts of the conductor 542a1 and the conductor 542b1 are formed to protrude inside the opening. Thus, the insulator 555 is in contact with, in the opening, the top surface of the conductor 542a1, the top surface of the conductor 542b1, the side surface of the conductor 542a2, and the side surface of the conductor 542b2. The insulator 545 is in contact with the top surface of the oxide 530 in the region between the conductor 542a1 and the conductor 542b1.

After the conductor 542a1 and the conductor 542b1 are separated, heat treatment is preferably performed in an oxygen-containing atmosphere before deposition of the insulator 545. Thus, oxygen can be supplied to the oxide 530a and the oxide 530b to reduce oxygen vacancies. In addition, when the insulator 555 is formed in contact with the side surface of the conductor 542a2 and the side surface of the conductor 542b2, the conductor 542a2 and the conductor 542b2 can be prevented from being excessively oxidized. Accordingly, the transistor can have favorable electrical characteristics and higher reliability. In addition, variations in electrical characteristics of a plurality of transistors formed over the same substrate can be reduced.

Note that the transistor 500 illustrated in FIG. 11, FIG. 12A, and FIG. 12B and the transistor 500 illustrated in FIG. 13 are examples and the structure is not limited thereto. The capacitor 590 illustrated in FIG. 11 is an example and the structure is not limited thereto.

### Structure Example 2 of Transistor and Capacitor

Another structure example of the transistor and the capacitor of one embodiment of the present invention, which is different from the example described above, is described.

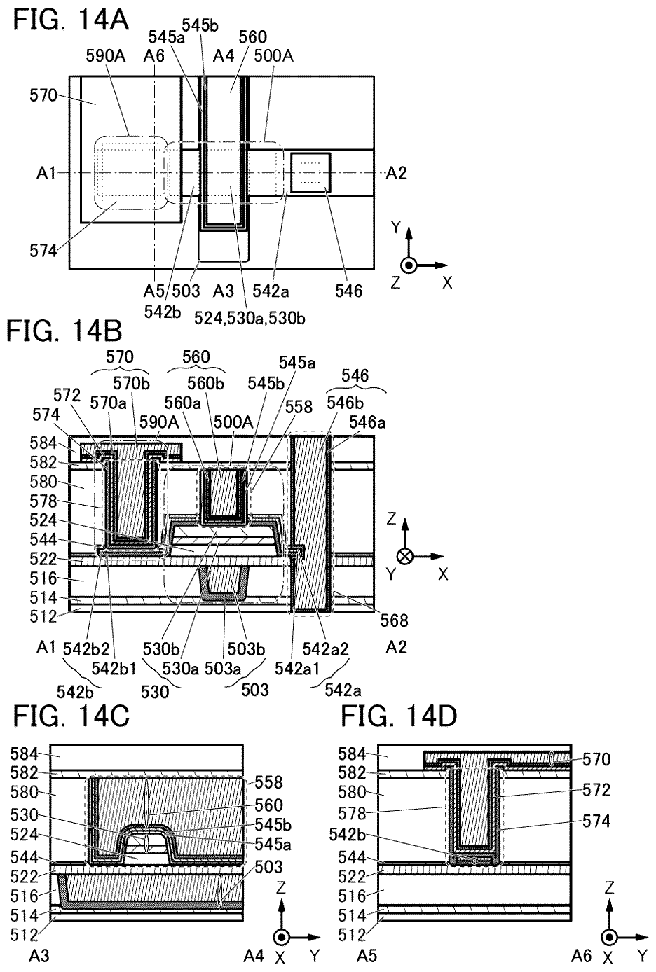

FIG. 14A to FIG. 14D are a top view and cross-sectional views of a semiconductor device including a transistor 500A and a capacitor 590A. FIG. 14A is a top view of the semiconductor device. FIG. 14B to FIG. 14D are cross-sectional views of the semiconductor device. Here, FIG. 14B is a cross-sectional view of a portion indicated by dashed-dotted line A1-A2 in FIG. 14A and is also a cross-sectional view of the transistor 500A in the channel length direction (shown as the X direction). FIG. 14C is a cross-sectional view of a portion indicated by dashed-dotted line A3-A4 in FIG. 14A and is also a cross-sectional view of the transistor 500A in the channel width direction (shown as the Y direction). FIG. 14D is a cross-sectional view of a portion indicated by dashed-dotted line A5-A6 in FIG. 14A and is also a cross-sectional view of the capacitor 590A in the Y direction. Note that for clarity of the drawing, some components are omitted in the top view of FIG. 14A.

The semiconductor device illustrated in FIG. 14A to FIG. 14D includes the insulator 514, the transistor 500A and the capacitor 590A over the insulator 514, the insulator 580 over the insulator 544 provided for the transistor 500A, the insulator 582 over the insulator 580, the insulator 584 over the capacitor 590A and the insulator 582, and the conductor 546 (a conductor 546a and a conductor 546b). The insulator 514, the insulator 580, the insulator 582, and the insulator 584 function as interlayer films. As illustrated in FIG. 14B, at least parts of the transistor 500A and the capacitor 590A are placed to be embedded in the insulator 580.

Note that each of the insulator 582 and the insulator 522 may have a function of capturing or fixing hydrogen, for example. Thus, hydrogen contained in the insulator 580, the insulator 524, an insulator 545a, an insulator 545b, and the like can be captured or fixed by the insulator 582 or the insulator 522, for example.

The conductor 546 (the conductor 546a and the conductor 546b) functions as a plug (can also be referred to as a connection electrode) when being electrically connected to the transistor 500A.

The conductor 546 is placed inside an opening 568 formed in the insulator 580 and the like, for example. The conductor 546 includes a region in contact with part of the top surface of the conductor 542a and part of the side surface of the conductor 542a.

Here, the transistor 500A includes the oxide 530 functioning as a semiconductor film including a channel formation region, the conductor 560 functioning as a first gate (also simply referred to as a gate) electrode, the conductor 503 functioning as a second gate (also referred to as a back gate) electrode, the conductor 542b functioning as one of a source electrode and a drain electrode, and the conductor 542a functioning as the other of the source electrode and the drain electrode. The insulator 545a and the insulator 545b functioning as a first gate insulating film are also included. The insulator 522 and the insulator 524 functioning as a second gate insulating film are also included.

The first gate electrode and the first gate insulating film are placed in an opening 558 formed in the insulator 580 and the insulator 544. That is, the conductor 560, the insulator 545b, and the insulator 545a are placed in the opening 558.

The capacitor 590A includes a conductor 574 functioning as a lower electrode, an insulator 572 functioning as a dielectric, and a conductor 570 functioning as an upper electrode. That is, the capacitor 590A forms a MIM (Metal-Insulator-Metal) capacitor.

The upper electrode, the dielectric, and part of the lower electrode of the capacitor 590A are placed in an opening 578 formed in the insulator 580 and the insulator 544. That is, the conductor 570, the insulator 572, and the conductor 574 are placed in the opening 578.

### Transistor 500A

As illustrated in FIG. 14A to FIG. 14C, the transistor 500A includes the insulator 516 over the insulator 514, the conductor 503 (the conductor 503a and the conductor 503b) placed to be embedded in the insulator 516, the insulator 522 over the insulator 516 and the conductor 503, the insulator 524 over the insulator 522, the oxide 530a over the insulator 524, the oxide 530b over the oxide 530a, the conductor 542a (the conductor 542a1 and the conductor 542a2) and the conductor 542b (the conductor 542b1 and the conductor 542b2) over the oxide 530b, the insulator 545a over the oxide 530b, the insulator 545b over the insulator 545a, the conductor 560 (the conductor 560a and the conductor 560b) positioned over the insulator 545b and overlapping with part of the oxide 530b, and the insulator 544 placed over the insulator 522, the insulator 524, the oxide 530a, the oxide 530b, the conductor 542a, and the conductor 542b.

Note that the oxide 530a and the oxide 530b are collectively referred to as the oxide 530 in some cases. The conductor 542a and the conductor 542b are collectively referred to as a conductor 542 in some cases.

The opening 558 reaching the oxide 530b is provided in the insulator 580 and the insulator 544. In other words, the opening 558 includes a region overlapping with the oxide 530b. It can also be said that the insulator 544 includes an opening overlapping with the opening included in the insulator 580. That is, the opening 558 includes an opening included in the insulator 580 and an opening included in the insulator 544.

The insulator 545a, the insulator 545b, and the conductor 560 are placed in the opening 558. That is, the conductor 560 includes a region overlapping with the oxide 530b with the insulator 545a and the insulator 545b therebetween. The conductor 560, the insulator 545a, and the insulator 545b are provided between the conductor 542a and the conductor 542b in the channel length direction of the transistor 500A. The insulator 545b includes a region in contact with the side surface of the conductor 560 and a region in contact with the bottom surface of the conductor 560.

As illustrated in FIG. 14C, the top surface of the insulator 522 is exposed in a region of the opening 558 that does not overlap with the oxide 530.

Note that a material having a high capability of capturing or fixing hydrogen may be used as the insulator 545a, and a material having a high barrier property against hydrogen may be used as the insulator 545b. Thus, diffusion of impurities such as water or hydrogen into the oxide 530 can be inhibited. For example, aluminum oxide or the like may be used as the insulator 545a, and silicon nitride or the like may be used as the insulator 545b.

The oxide 530 preferably includes the oxide 530a placed over the insulator 524 and the oxide 530b placed over the oxide 530a. Including the oxide 530a under the oxide 530b makes it possible to inhibit diffusion of impurities into the oxide 530b from components formed below the oxide 530a.

Although a structure of the transistor 500A in which two layers, the oxide 530a and the oxide 530b, are stacked as the oxide 530 is illustrated, one embodiment of the present invention is not limited thereto. For example, the oxide 530 may have a single-layer structure of the oxide 530b. Alternatively, a stacked-layer structure of three or more layers may be employed. Alternatively, the oxide 530a and the oxide 530b may each have a stacked-layer structure.

The conductor 560 functions as the first gate electrode and the conductor 503 functions as the second gate electrode. The insulator 545a and the insulator 545b function as a first gate insulating film, and the insulator 522 and the insulator 524 function as a second gate insulating film. The conductor 542b functions as one of a source electrode and a drain electrode, and the conductor 542a functions as the other of the source electrode and the drain electrode. At least part of a region of the oxide 530 that overlaps with the conductor 560 functions as a channel formation region.

### Capacitor 590A

As illustrated in FIG. 14A, FIG. 14B, and FIG. 14D, the capacitor 590A includes the conductor 574, the insulator 572, and the conductor 570 (the conductor 570a and the conductor 570b). The conductor 574 functions as one of a pair of electrodes of the capacitor 590A (also referred to as a lower electrode), the conductor 570 functions as the other of the pair of electrodes of the capacitor 590A (also referred to as an upper electrode), and the insulator 572 functions as a dielectric of the capacitor 590A.

At least parts of the conductor 574, the insulator 572, the conductor 570a, and the conductor 570b are placed in the opening 578 provided in the insulator 544, the insulator 580, and the insulator 582. The conductor 574 is provided over the conductor 542b, the insulator 572 is provided over the conductor 574, the conductor 570a is provided over the insulator 572, and the conductor 570b is provided over the conductor 570a.

The conductor 574 is placed along the opening 578 formed in the insulator 544, the insulator 580, and the insulator 582. The level of part of the top surface of the conductor 574 is preferably higher than the level of the top surface of the insulator 582. The top surface of the conductor 542b is in contact with the bottom surface of the conductor 574.

The conductor 574 is preferably deposited by a deposition method that offers excellent coverage, such as an ALD method or a CVD method, for example.

As the conductor 574, a material that can be used as the conductor 503, the conductor 560, or the conductor 542, which are described above, may be used, for example. When the same conductive material as the conductor 542b is used for the conductor 574, for example, the contact resistance between the conductor 574 and the conductor 542b can be reduced. Titanium nitride or tantalum nitride deposited by an ALD method can be used as the conductor 574, for example.

The insulator 572 is placed to cover the conductor 574 and part of the insulator 582.

The insulator 572 is preferably deposited by a deposition method that offers excellent coverage, such as an ALD method or a CVD method, for example.

As the insulator 572, a high dielectric constant (high-k) material (material with a high relative permittivity) is preferably used. As the insulator 572, any of the above-described materials that can be used for the insulator 592 may be used, for example.

The conductor 570 is placed to fill the opening 578 formed in the insulator 544, the insulator 580, and the insulator 582.

The conductor 570 is preferably deposited by an ALD method, a CVD method, or the like, for example.

As the conductor 570, any of the above-described materials that can be used as the conductor 503 or the conductor 560 may be used, for example. For example, titanium nitride deposited by an ALD method can be used as the conductor 570a, and tungsten deposited by a CVD method can be used as the conductor 570b. Note that in the case where the adhesion of tungsten to the insulator 572 is sufficiently high, a single-layer structure of tungsten deposited by a CVD method may be used as the conductor 570.

The opening 578 is provided to reach the conductor 542b. That is, the opening 578 includes a region overlapping with the conductor 542b. The conductor 542b is one of the source electrode and the drain electrode of the transistor 500A and is in contact with the bottom surface of the conductor 574 provided in the opening 578; thus, the conductor 542b can electrically connect the transistor 500A and the capacitor 590A to each other.

In the top view, the distance between the opening 578 and the oxide 530 is preferably short. Such a structure can reduce the area occupied by the capacitor 590A and the transistor 500A. Note that the shape of the opening 578 in the top view may be a tetragonal shape, a polygonal shape other than a tetragonal shape, a polygonal shape with rounded corners, or a circular shape including an elliptical shape.

As illustrated in FIG. 14B and FIG. 14D, the conductor 574 is provided along the opening 578. Thus, the conductor 574 is in contact with the side surfaces of the insulator 544, the insulator 580, and the insulator 582, the side surface of the conductor 542b1, the side surface and the top surface of the conductor 542b2, and the top surface of the insulator 522. The insulator 572 is provided in contact with the top surface of the conductor 574, the conductor 570a is provided in contact with the top surface of the insulator 572, and the conductor 570b is provided in contact with the top surface of the conductor 570a.

When the capacitor 590A has the above-described structure, the capacitor 590A in which the conductor 574 and the conductor 570 face each other with the insulator 572 therebetween in the opening 578 can be formed, as illustrated in FIG. 14B and FIG. 14D. Thus, increasing the depth of the opening 578 (which can also be referred to as the thickness of the insulator 580) can increase the electrostatic capacitance of the capacitor 590A.

As illustrated in FIG. 14B, part of the conductor 574, part of the insulator 572, and part of the conductor 570 are provided to be exposed out from the opening 578. In other words, part of the conductor 574, part of the insulator 572, and part of the conductor 570 are formed above the top surface of the conductor 560 or the top surface of the insulator 582.

Part of the conductor 574 and part of the insulator 572 are in contact with the top surface of the insulator 582. That is, a side end portion of the conductor 574 is covered with the insulator 572. Furthermore, the conductor 570 preferably includes a region overlapping with the insulator 582 with the insulator 572 therebetween. Here, as illustrated in FIG. 14B, a side end portion of the conductor 570 and a side end portion of the insulator 572 are aligned or substantially aligned with each other. With such a structure, the conductor 570 and the conductor 574 can be separated from each other by the insulator 572, so that a short circuit between the conductor 570 and the conductor 574 can be inhibited.

Furthermore, a portion above the insulator 582 of the conductor 570 may be extended and formed in a wiring shape. For example, as illustrated in FIG. 14C, the conductor 570 can be provided to extend in the channel width direction of the transistor 500A. Thus, in the case where a plurality of the transistors 500A and a plurality of the capacitors 590A are provided, the conductor 570 can also function as a wiring. In this case, the insulator 572 can also be provided to extend together with the conductor 570.

### Variation Examples of Transistor 500A and Capacitor 590A

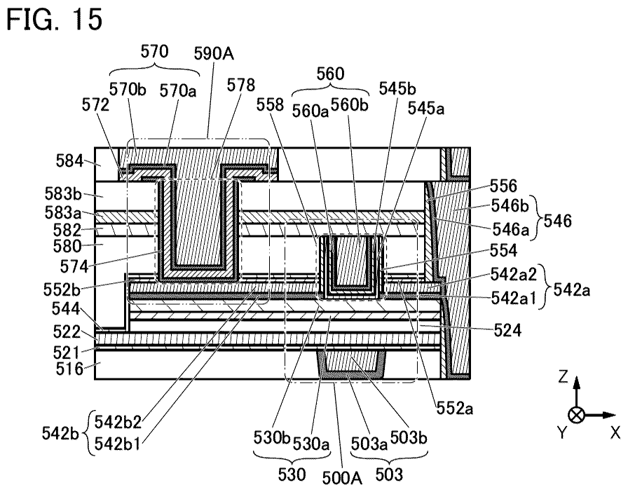

FIG. 15 is a cross-sectional view illustrating another structure example of the transistor 500A and the capacitor 590A included in the semiconductor device illustrated in FIG. 14B. Here, differences between the semiconductor device illustrated in FIG. 15 and the semiconductor device illustrated in FIG. 14B are mainly described.

The semiconductor device illustrated in FIG. 15 is different from the semiconductor device illustrated in FIG. 14B in that side end portions of the insulator 524, the oxide 530a, the oxide 530b, the conductor 542a1, and the conductor 542a2 are formed to be aligned or substantially aligned with each other.

The semiconductor device illustrated in FIG. 15 includes an insulator 552a, an insulator 552b, an insulator 554, an insulator 556, an insulator 521, an insulator 583a, and an insulator 583b in addition to the semiconductor device illustrated in FIG. 14B.

As illustrated in FIG. 15, the insulator 552a is provided between the conductor 542a2 and the insulator 544. The insulator 552b is provided between the conductor 542b2 and the insulator 544. Here, the insulator 552a and the insulator 552b may have a function of an etching stopper that protects the conductor 542a2 and the conductor 542b2 when the insulator 524, the oxide 530a, the oxide 530b, the conductor 542a1, the conductor 542a2, the insulator 552a, and the insulator 552b are collectively processed.

As illustrated in FIG. 15, the insulator 554 is provided between the insulator 545a and the conductor 542a2, the conductor 542b2, the insulator 552a, the insulator 552b, the insulator 544, and the insulator 580 and in contact with part of the top surface of the conductor 542a1 and part of the top surface of the conductor 542b1 in the opening 558. In other words, the insulator 554 is formed in a sidewall shape to be in contact with the side surface of the opening 558. Here, the insulator 554 may have a function of a protective film that prevents excessive oxidation of the conductor 542a2 and the conductor 542b2 in the case where heat treatment is performed in an oxygen-containing atmosphere after separation into the conductor 542a1 and the conductor 542b1 is performed.

As illustrated in FIG. 15, the insulator 521 is provided in contact with the bottom surface of the insulator 522. The insulator 583a is provided in contact with the top surface of the insulator 582. Here, the insulator 521 may have a function of inhibiting diffusion of impurities such as water and hydrogen from an interlayer insulator placed below the insulator 521 into the transistor 500A. The insulator 583a may have a function of inhibiting diffusion of impurities such as water or hydrogen from an interlayer insulator placed above the insulator 583a into the transistor 500A.

As illustrated in FIG. 15, the insulator 583b is provided between the insulator 583a and the insulator 584. Here, the insulator 583b has a function of changing the electrostatic capacitance of the capacitor 590A in accordance with the thickness. That is, when the depth of the opening 578 in the capacitor 590A is large (e.g., the thickness of the insulator 583b is large), the electrostatic capacitance of the capacitor 590A can be increased, for example.

As illustrated in FIG. 15, the insulator 556 is provided in contact with the side surface of the conductor 546. Specifically, the insulator 556 is formed in contact with the side surfaces of the insulator 516, the insulator 521, the insulator 522, the insulator 544, the insulator 580, the insulator 582, the insulator 583a, the insulator 583b, and the insulator 584 in the opening (corresponding to the opening 568 illustrated in FIG. 14B). The insulator 556 is formed to protrude inside the opening. The insulator 556 is formed also on the side surfaces of the insulator 524, the oxide 530, and the conductor 542a. Here, at least part of the conductor 542a is exposed from the insulator 556 and is in contact with the conductor 546. That is, the conductor 546 is formed to fill the opening with the insulator 556 therebetween.

The uppermost portion of the insulator 556 formed below the conductor 542a is preferably positioned below the top surface of the conductor 542a. With this structure, the conductor 546 can be in contact with at least part of the side end portion of the conductor 542a. Note that the insulator 556 formed under the conductor 542a preferably includes a region in contact with the side surface of the oxide 530. With this structure, impurities such as water and hydrogen, for example, included in the insulator 580 and the like, for example, can be inhibited from entering the oxide 530 through the conductor 546. Note that the insulator 556 may have a stacked-layer structure of two or more layers.

Note that the transistor 500A and the capacitor 590A illustrated in FIG. 14A to FIG. 14D and the transistor 500A and the capacitor 590A illustrated in FIG. 15 are examples and the structures are not limited thereto.

### Structure Example 3 of Transistor and Capacitor

Another structure example of the transistor and the capacitor of one embodiment of the present invention, which is different from the example described above, is described.

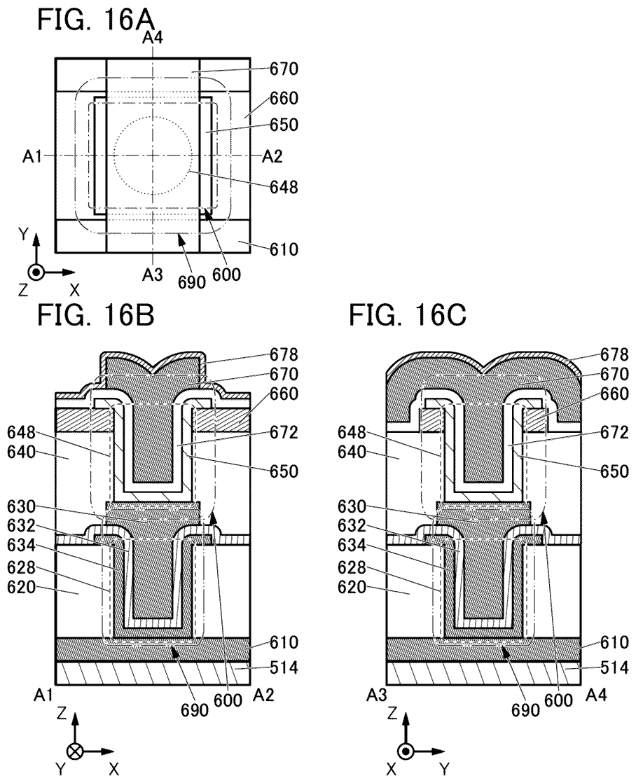

FIG. 16A to FIG. 16C are a top view and cross-sectional views of a semiconductor device including a transistor 600 and a capacitor 690. FIG. 16A is a top view of the semiconductor device. FIG. 16B and FIG. 16C are cross-sectional views of the semiconductor device. Here, FIG. 16B is a cross-sectional view of a portion indicated by the dashed-dotted line A1-A2 in FIG. 16A. FIG. 16C is a cross-sectional view of a portion indicated by the dashed-dotted line A3-A4 in FIG. 16A. Note that for clarity of the drawing, some components are omitted in the top view of FIG. 16A.

FIG. 16A to FIG. 16C illustrate the insulator 514, a conductor 610 over the insulator 514, the transistor 600 and the capacitor 690 over the conductor 610, an insulator 620 over the conductor 610, an insulator 640 over the insulator 620, and an insulator 678 over the transistor 600 and the capacitor 690. The insulator 514, the insulator 620, the insulator 640, and the insulator 678 function as interlayer films. The conductor 610 functions as a wiring.

As illustrated in FIG. 16A to FIG. 16C, the transistor 600 is provided to overlap with the capacitor 690. An opening 648 where part of the structure of the transistor 600 is provided includes a region overlapping with an opening 628 where part of the structure of the capacitor 690 is provided. In particular, a conductor 630 has a function of one of a source electrode and a drain electrode of the transistor 600 and a function of one of a pair of electrodes of the capacitor 690; thus, the transistor 600 and the capacitor 690 share part of the structure. With such a structure, the transistor 600 and the capacitor 690 can be provided without a significant increase in the occupied area in the top view.

### Capacitor 690

The capacitor 690 includes a conductor 634 over the conductor 610, an insulator 632 over the conductor 634, and the conductor 630 over the insulator 632. The conductor 630 functions as one of a pair of electrodes (sometimes referred to as an upper electrode), the conductor 634 functions as the other of the pair of electrodes (sometimes referred to as a lower electrode), and the insulator 632 functions as a dielectric. That is, the capacitor 690 forms a MIM (Metal-Insulator-Metal) capacitor.

As illustrated in FIG. 16B and FIG. 16C, an opening 628 reaching the conductor 610 is provided in the insulator 620. At least part of the conductor 634 is placed in the opening 628. The conductor 634 includes a region in contact with the top surface of the conductor 610 in the opening 628, a region in contact with the side surface of the insulator 620 in the opening 628, and a region in contact with at least part of the top surface of the insulator 620. The insulator 632 is placed such that at least part of the insulator 632 is positioned in the opening 628. The conductor 630 is placed so that at least part of the conductor 630 is positioned in the opening 628. The conductor 630 is preferably provided to fill the opening 628 as illustrated in FIG. 16B and FIG. 16C.

The capacitor 690 has a structure in which the upper electrode and the lower electrode face each other with the dielectric therebetween on the side surface as well as on the bottom portion of the opening 628; thus, the electrostatic capacitance per unit area can be increased. Thus, the deeper the opening 628 is, the larger the electrostatic capacitance of the capacitor 690 can be.

The side surface of the opening 628 (sometimes referred to as the side surface of the insulator 620 in the opening 628) is preferably perpendicular to the top surface of the conductor 610. In other words, the insulator 620 has the opening 628 provided to extend in the direction perpendicular to the top surface of the conductor 610. At this time, the opening 628 has a cylindrical shape.

Although this embodiment describes an example in which the opening 628 is circular in the top view, one embodiment of the present invention is not limited thereto. For example, the opening 628 in the top view may have an almost circular shape such as an elliptical shape, a polygonal shape such as a quadrangular shape, or a polygonal shape with rounded corners such as a quadrangular shape with rounded corners. In that case, the maximum width of the opening 628 can be calculated as appropriate in accordance with the top-view shape of the uppermost portion of the opening 628.

For example, in the case where the opening 628 is quadrangular in the top view, the maximum width of the opening 628 may be the length of a diagonal line of the quadrangle. Alternatively, for example, in the case where the opening 628 has an almost circular shape such as an elliptical shape, a polygonal shape, or a polygonal shape with rounded corners in the top view, the maximum width of the opening 628 may be the maximum width of the shape of the opening 628 in the top view.

Portions of the conductor 634, the insulator 632, and the conductor 630 that are placed in the opening 628 reflect the shape of the opening 628. Thus, the conductor 634 is provided along the opening 628, the insulator 632 is provided to cover the conductor 634, and the conductor 630 is provided to fill a depressed portion of the insulator 632 that reflects the shape of the opening 628

That is, part of the dielectric (corresponding to the insulator 632) of the capacitor 690 is provided along the side surface of the opening 628. That is, part of the dielectric of the capacitor 690 is provided in the direction perpendicular to the top surface of the conductor 610. In other words, a surface where the upper electrode and the dielectric of the capacitor 690 are in contact with each other and a surface where the lower electrode and the dielectric of the capacitor 690 are in contact with each other each include a component in the direction perpendicular to the top surface of the conductor 610.

Although the opening 628 is provided such that the side surface of the opening 628 is perpendicular to the top surface of the conductor 610 in FIG. 16B and FIG. 16C, one embodiment of the present invention is not limited thereto. The side surface of the opening 628 may have a tapered shape, for example.

Note that in this specification and the like, a tapered shape refers to a shape in which at least part of a side surface of a structure is inclined with respect to a substrate surface. An angle formed between an inclined side surface and a substrate surface is referred to as a taper angle. Specifically, in this specification and the like, a tapered shape having a taper angle greater than 0° and less than 90° may be referred to as a forward tapered shape, and a tapered shape having a taper angle greater than 90° and less than 180° may be referred to as an inverse tapered shape.

The conductor 634 and the insulator 632 are provided to be stacked along the side surface of the opening 628 and the top surface of the conductor 610. The conductor 630 is provided over the insulator 632 to fill the opening 628. In this specification and the like, the capacitor 690 having such a structure is sometimes referred to as a trench-type capacitor, a trench capacitor, a deep-trench stacked capacitor, or the like.

The insulator 640 is placed over the capacitor 690. That is, the insulator 640 is placed above the conductor 634, the insulator 632, and the conductor 630. In other words, the conductor 630 is placed below the insulator 640.

The conductor 610 is provided below the conductor 634. The conductor 634 includes a region in contact with the conductor 610.

The conductor 610 is provided over the insulator 514. The conductor 610 can be provided in a planar shape, for example.

As the conductor 610, a conductive material having high conductivity is preferably used. Note that the conductor 610 may have a single-layer structure or a structure in which different materials are stacked. As the conductor 610, any of the above-described materials that can be used as the conductor 503 or the conductor 560 may be used, for example. For example, tungsten can be used.

It is preferable to use, for the conductor 634, a single layer or stacked layers of a conductive material that is not easily oxidized, a conductive material having a function of inhibiting diffusion of oxygen, or the like. Thus, in the case where an oxide insulator is used as the insulator 632, oxidation of the conductor 634 by the insulator 632 can be inhibited. In the case where an oxide insulator is used as the insulator 620, the conductor 634 can be inhibited from being oxidized by the insulator 620.

As the conductor 634, a material that can be used as the conductor 503, the conductor 560, or the conductor 574, which are described above, may be used, for example. For example, titanium nitride, indium tin oxide to which silicon is added, or the like may be used. For example, a structure in which titanium nitride is stacked over tungsten may be used. For another example, a structure in which tungsten is stacked over first titanium nitride and second titanium nitride is stacked over the tungsten may be used.

The insulator 632 is provided over the conductor 634. The insulator 632 is provided in contact with the top surface and the side surface of the conductor 634. That is, the insulator 632 preferably covers the side end portion of the conductor 634. This can prevent a short circuit between the conductor 634 and the conductor 630.

As illustrated in FIG. 16B and FIG. 16C, the insulator 632 may be provided to extend and be in contact with the top surface of the insulator 620.

The side end portion of the insulator 632 and the side end portion of the conductor 634 may be aligned with each other. With such a structure, the insulator 632 and the conductor 634 can be formed using the same mask, so that the manufacturing process can be simplified.

As the insulator 632, a material with a high relative permittivity, what is called a high-k material, is preferably used. Using a high-k material as the insulator 632 allows the insulator 632 to be thick enough to inhibit a gate leakage current and the capacitor 690 to have a sufficiently high electrostatic capacitance.

As the insulator 632, any of the above-described materials that can be used as the insulator 592 or the insulator 572 may be used, for example.

The conductor 630 is provided in contact with part of the top surface of the insulator 632. A side end portion of the conductor 630 is preferably positioned inward from the side end portion of the conductor 634 in both the X direction and the Y direction. In the structure in which the insulator 632 covers the side end portion of the conductor 634, the side end portion of the conductor 630 may be positioned outward from the side end portion of the conductor 634.

A single layer or stacked layers of a conductive material can be used as the conductor 630. For example, a conductive material that is not easily oxidized, a conductive material having a function of inhibiting diffusion of oxygen, or the like is preferably used for the conductor 630.

As the conductor 630, a material that can be used as the conductor 503, the conductor 560, the conductor 542, or the conductor 570, which are described above, may be used, for example. For example, titanium nitride, tantalum nitride, or the like can be used.

The insulator 620, which functions as an interlayer film, preferably has a low relative permittivity. When a material with low relative permittivity is used for an interlayer film, parasitic capacitance generated between wirings can be reduced. As the insulator 620, a single layer or stacked layers of an insulator containing a material with a low relative permittivity can be used.

As the insulator 620, any of the above-described materials that can be used for the insulator 516 may be used, for example. For example, silicon oxide or silicon oxynitride, which is thermally stable, is preferably used.

### Transistor 600

The transistor 600 includes the conductor 630, a conductor 660 over the insulator 640, an oxide 650, an insulator 672 over the oxide 650, and a conductor 670 over the insulator 672. The oxide 650 functions as a semiconductor film including a channel formation region, the conductor 670 functions as a gate electrode, the insulator 672 functions as a gate insulating film, the conductor 630 functions as one of a source electrode and a drain electrode, and the conductor 660 functions as the other of the source electrode and the drain electrode.

In the transistor 600, a metal oxide functioning as an oxide semiconductor is used as the oxide 650 including a channel formation region. As the oxide 650, a metal oxide that can be used as the above-described oxide 530 may be used, for example.

As illustrated in FIG. 16B and FIG. 16C, the opening 648 reaching the conductor 630 is provided in the insulator 640 and the conductor 660. At least part of the oxide 650 is placed in the opening 648. Note that the oxide 650 includes a region in contact with the top surface of the conductor 630 in the opening 648, a region in contact with the side surface of the conductor 660 in the opening 648, and a region in contact with at least part of the top surface of the conductor 660. The insulator 672 is placed such that at least part of the insulator 672 is positioned in the opening 648. The conductor 670 is placed such that at least part of the conductor 670 is positioned in the opening 648. In addition, the conductor 670 is preferably provided to fill the opening 648 as illustrated in FIG. 16B and FIG. 16C.

For example, the conductor 630 may have a structure in which tantalum nitride is stacked over titanium nitride. In that case, the titanium nitride may be in contact with the insulator 632 and the tantalum nitride may be in contact with the oxide 650. Such a structure can inhibit the conductor 630 from being excessively oxidized by the oxide 650. In the case where an oxide insulator is used as the insulator 632, such a structure can inhibit the conductor 630 from being excessively oxidized by the insulator 632. Note that the conductor 630 may have a structure in which tungsten is stacked over titanium nitride, for example.

The conductor 630 includes a region in contact with the oxide 650 and thus is preferably formed using a conductive material containing oxygen. With such a structure, the conductivity can be maintained even when the conductor 630 absorbs oxygen. Also in the case where a material containing oxygen is used as the insulator 632, the conductivity of the conductor 630 can be maintained.

As the conductor 630, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

The oxide 650 includes the region in contact with the side surface of the conductor 660 in the opening 648 and the region in contact with part of the top surface of the conductor 660. When the oxide 650 is in contact with not only the side surface but also the top surface of the conductor 660 in this manner, the area where the oxide 650 and the conductor 660 are in contact with each other can be increased.

FIG. 16C illustrates a structure in which the side end portion of the oxide 650 is positioned inward from the side end portion of the conductor 660. Note that one embodiment of the present invention is not limited thereto. For example, the side end portion of the oxide 650 and the side end portion of the conductor 660 may be aligned with each other in the Y direction. Alternatively, the side end portion of the oxide 650 may be positioned outward from the side end portion of the conductor 660.

As illustrated in FIG. 16A to FIG. 16C, it is preferable that the conductor 670 be provided to extend in the Y direction and the conductor 660 be provided to extend in the X direction. With such a structure, the conductor 670 and the conductor 660 are provided to intersect with each other. Although the conductor 610 is provided in a planar shape in FIG. 16A, one embodiment of the present invention is not limited thereto. For example, the conductor 610 may be provided parallel to the conductor 670 or may be provided parallel to the conductor 660.

The side surface of the opening 648 (sometimes referred to as the side surface of the insulator 640 in the opening 648) is preferably perpendicular to the top surface of the conductor 610. In other words, the insulator 640 has the opening 648 provided to extend in the direction perpendicular to the top surface of the conductor 610. In that case, the opening 648 has a cylindrical shape.

Although this embodiment describes an example in which the opening 648 is circular in the plan view, one embodiment of the present invention is not limited thereto. For example, the opening 648 in the plan view may have an almost circular shape such as an elliptical shape, a polygonal shape such as a quadrangular shape, or a polygonal shape with rounded corners such as a quadrangular shape with rounded corners. In that case, the maximum width of the opening 648 can be calculated as appropriate in accordance with the top-view shape of the uppermost portion of the opening 648.

In the case where the opening 648 is quadrangular in the top view, for example, the maximum width of the opening 648 may be the length of a diagonal line of the quadrangle. Alternatively, for example, in the case where the opening 648 has an almost circular shape such as an elliptical shape, a polygonal shape, or a polygonal shape with rounded corners in the top view, the maximum width of the opening 648 may be the maximum width of the shape of the opening 648 in the top view.

Portions of the oxide 650, the insulator 672, and the conductor 670 that are placed in the opening 648 reflect the shape of the opening 648. Thus, the oxide 650 is provided along the opening 648, the insulator 672 is provided to cover the oxide 650, and the conductor 670 is provided to fill a depressed portion of the insulator 672 that reflects the shape of the opening 648.

That is, part of the semiconductor film (corresponding to the oxide 650) including a channel formation region of the transistor 600 is provided along the side surface of the opening 648. That is, part of the semiconductor film is provided in the direction perpendicular to the top surface of the conductor 610. In other words, the channel length direction of the transistor 600 includes a component in the direction perpendicular to the top surface of the conductor 610. That is, the channel length direction includes a component in the vertical direction (which is the Z direction in FIG. 16A to FIG. 16C and is also referred to as the height direction or the direction perpendicular to a formation surface). In other words, the source electrode and the drain electrode are positioned at different levels, and a drain current flows in the vertical direction. Thus, the transistor of one embodiment of the present invention is a transistor whose channel length direction includes a component in the vertical direction (i.e., a transistor in which a drain current flows in the vertical direction), and can be referred to as a VFET (Vertical Field Effect Transistor), a vertical transistor, a transistor of a vertical type, a vertical channel transistor, a transistor of a vertical channel type, or the like, for example.

Here, as the conductor 660, a material that can be used as the conductor 630 can be used, for example. As the conductor 670, a material that can be used as the conductor 630 may be used, for example. As the insulator 672, a material that can be used as the insulator 522, the insulator 524, or the insulator 545, which are described above, may be used, for example. As the insulator 640, a material that can be used for the insulator 620 may be used, for example. As the insulator 678, a material that can be used as the insulator 514 or the insulator 586, which are described above, may be used, for example.

Although the opening 648 is provided such that the side surface of the opening 648 is perpendicular to the top surface of the conductor 610 in FIG. 16B and FIG. 16C, one embodiment of the present invention is not limited thereto. For example, the side surface of the opening 648 may have a tapered shape.

Although the oxide 650 being a single layer is illustrated in FIG. 16B and FIG. 16C, one embodiment of the present invention is not limited thereto. The oxide 650 may have a stacked-layer structure of a plurality of oxide layers with different chemical compositions.

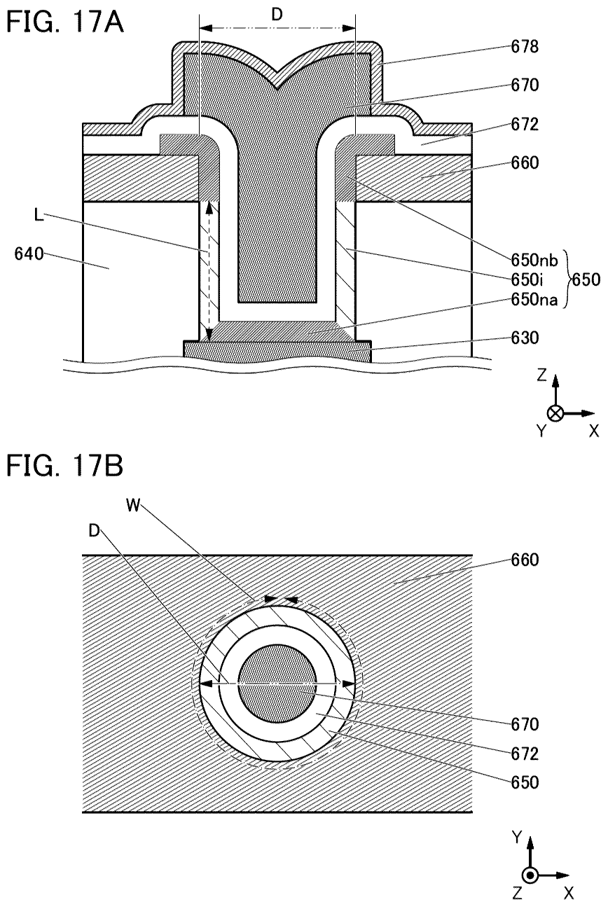

FIG. 17A is an enlarged view of the oxide 650 and its vicinity in FIG. 16B. FIG. 17B is a cross-sectional view taken along the XY plane including the conductor 660.

As illustrated in FIG. 17A, the oxide 650 includes a region 650i, and a region 650na and a region 650nb provided such that the region 650i is sandwiched therebetween.

The region 650na is a region in contact with the conductor 630 in the oxide 650. At least part of the region 650na functions as one of the source region and the drain region of the transistor 600. The region 650nb is a region of the oxide 650 that is in contact with the conductor 660. At least part of the region 650nb functions as the other of the source region and the drain region of the transistor 600. As illustrated in FIG. 17B, the conductor 660 is in contact with all the outer circumference of the oxide 650. Thus, the other of the source region and the drain region of the transistor 600 can be formed in all the outer circumference of a portion of the oxide 650 that is formed in the same layer as the conductor 660.

The region 650i is a region of the oxide 650 between the region 650na and the region 650nb. At least part of the region 650i functions as the channel formation region of the transistor 600. In other words, the channel formation region of the transistor 600 is positioned in a region of the oxide 650 that is between the conductor 630 and the conductor 660. It can also be said that the channel formation region of the transistor 600 is positioned in a region of the oxide 650 that is in contact with the insulator 640 or a region in the vicinity thereof.

The channel length of the transistor 600 is a distance between the source region and the drain region. In other words, the channel length of the transistor 600 is determined by the thickness of the insulator 640 over the conductor 630. In FIG. 17A, the channel length L of the transistor 600 is indicated by a dashed double-headed arrow. In a cross-sectional view, the channel length L is a distance between an end portion of a region where the oxide 650 and the conductor 630 are in contact with each other and an end portion of a region where the oxide 650 and the conductor 660 are in contact with each other. In other words, the channel length L corresponds to the length of the side surface of the insulator 640 on the opening 648 side in the cross-sectional view.

Here, in a planar transistor, the channel length is determined by the light exposure limit of photolithography; however, in one embodiment of the present invention, the channel length can be determined by the thickness of the insulator 640. Thus, the transistor 600 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 600 can have a higher on-state current and improved frequency characteristics.

As described above, the channel formation region, the source region, and the drain region can be formed in the opening 648. Thus, the area occupied by the transistor 600 can be smaller than the area occupied by a planar transistor in which a channel formation region, a source region, and a drain region are provided separately on the XY plane.

Furthermore, in the XY plane including the channel formation region of the oxide 650, as in FIG. 17B, the oxide 650, the insulator 672, and the conductor 670 are provided concentrically. Thus, the side surface of the conductor 670 provided at the center faces the side surface of the oxide 650 with the insulator 672 therebetween. That is, in the top view, all the perimeter of the oxide 650 serves as the channel formation region. In this case, for example, the channel width of the transistor 600 is determined by the length of the outer circumference of the oxide 650. In other words, it can be said that the channel width of the transistor 600 is determined by the maximum width of the opening 648 (the maximum diameter when the opening 648 is circular in the top view). In FIG. 17A and FIG. 17B, a maximum width D of the opening 648 is indicated by a dashed double-dotted double-headed arrow. In FIG. 17B, the channel width W of the transistor 600 is indicated by a dashed-dotted double-headed arrow. When the maximum width D of the opening 648 is increased, the channel width per unit area can be increased, so that the on-state current can be increased.

In the case where the opening 648 is formed by a photolithography method, the maximum width D of the opening 648 is set by the light exposure limit of photolithography. The maximum width D of the opening 648 is determined by the thicknesses of the oxide 650, the insulator 672, and the conductor 670 provided in the opening 648. The maximum width D of the opening 648 is preferably greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm, for example. Note that in the case where the opening 648 is circular in the top view, the maximum width D of the opening 648 corresponds to the diameter of the opening 648, and the channel width W can be calculated to be “D×π.”

The channel length L of the transistor 600 of one embodiment of the present invention is preferably shorter than at least the channel width W of the transistor 600. The channel length L of the transistor 600 of one embodiment of the present invention is greater than or equal to 0.1 times and less than or equal to 0.99 times, preferably greater than or equal to 0.5 times and less than or equal to 0.8 times the channel width W of the transistor 600. This structure enables a transistor with favorable electrical characteristics and high reliability.

In the case where the opening 648 is formed to be circular in a top view, the oxide 650, the insulator 672, and the conductor 670 are provided concentrically. This makes the distance between the conductor 670 and the oxide 650 uniform or substantially uniform, so that a gate electric field can be uniformly or substantially uniformly applied to the oxide 650.

Note that the transistor 600 and the capacitor 690 illustrated in FIGS. 16A to 16C are examples and the structures are not limited thereto.

In one embodiment of the present invention, a transistor in which the above-described structures of the transistor 500, the transistor 500A, and the transistor 600 are combined as appropriate can be used. Furthermore, a capacitor in which the above-described structures of the capacitor 590, the capacitor 590A, and the capacitor 690 are combined as appropriate can be used.

### Constituent Materials of Semiconductor Device

Constituent materials that can be used for a semiconductor device including a transistor and a capacitor are not limited to those in the above-described structure examples. In addition to the above-described constituent materials, any of the following constituent materials can be used as appropriate in one embodiment of the present invention.

### Substrate

Examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and an SOI (Silicon on Insulator) substrate. Alternatively, a plastic substrate having heat resistance may be used as the substrate. Examples of the glass substrate include barium borosilicate glass, aluminosilicate glass, aluminoborosilicate glass, and soda lime glass. Alternatively, crystallized glass or the like may be used for the glass substrate, for example.

Alternatively, a flexible substrate; an attachment film; paper or a base film including a fibrous material; or the like can be used as the substrate, for example. Examples of the flexible substrate, the attachment film, the base material film, and the like include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Other examples include polyamide, polyimide, an aramid resin, an epoxy resin, an inorganic vapor deposition film, and paper. Specifically, for example, the use of a semiconductor substrate, a single crystal substrate, an SOI substrate, or the like for the manufacture of transistors enables the manufacture of small-sized transistors with a small variation in characteristics, size, shape, or the like and with a high current capability. When a circuit is formed with such transistors, lower power consumption of the circuit or higher integration of the circuit can be achieved.

A flexible substrate may be used as the substrate, and one or more of a transistor, a resistor, a capacitor, and the like may be formed directly over the flexible substrate, for example. Alternatively, a separation layer may be provided between the substrate and one or more of the transistor, the resistor, the capacitor, and the like. After part or the whole of a semiconductor device is completed over the separation layer, the separation layer can be used for separation from the substrate and transfer to another substrate. In such a case, for example, one or more of the transistor, the resistor, the capacitor, and the like can be transferred to a substrate having low heat resistance, a flexible substrate, or the like. As the above-described separation layer, a stacked-layer structure of a tungsten film and a silicon oxide film that are inorganic films, a structure in which an organic resin film of polyimide or the like is formed over a substrate, a silicon film containing hydrogen, or the like can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, a flexible semiconductor device or a highly durable semiconductor device can be manufactured. Provision of heat resistance to the semiconductor device can be achieved. A reduction in weight or thickness of the semiconductor device can be achieved.

Providing a semiconductor device over a flexible substrate can suppress an increase in weight and can produce a non-breakable semiconductor device.

### Ferroelectric

A material that can have ferroelectricity may be used as an insulator functioning as a dielectric (e.g., the insulator 592, the insulator 572, the insulator 632, or the like) that can be used for the semiconductor device of one embodiment of the present invention. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like, for example) is added to hafnium oxide. Note that the atomic ratio of hafnium to the element J1 can be set as appropriate. For example, the atomic ratio of hafnium to the element J1 can be 1:1 or in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like, for example) is added to zirconium oxide. Note that the atomic ratio of zirconium to the element J2 can be set as appropriate. For example, the atomic ratio of zirconium to the element J2 can be 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used, for example.

Examples of the material that can have ferroelectricity also include a metal nitride containing an element M1, an element M2, and nitrogen. Here, the element M1 is one or more selected from aluminum, gallium, indium, and the like, for example. The element M2 is one or more selected from boron, scandium, yttrium, lanthanum, cerium, neodymium, europium, titanium, zirconium, hafnium, vanadium, niobium, tantalum, chromium, and the like, for example. Note that the ratio of the number of atoms of the element M1 to the number of atoms of the element M2 can be set as appropriate. A metal nitride containing the element M1 and nitrogen has ferroelectricity in some cases even though the metal nitride does not contain the element M2. Examples of the material that can have ferroelectricity also include a material in which an element M3 is added to the above metal nitride. Here, the element M3 is one or more selected from magnesium, calcium, strontium, zinc, cadmium, and the like, for example. Note that the atomic ratio between the element M1, the element M2, and the element M3 can be set as appropriate.

Examples of the material that can have ferroelectricity also include perovskite-type oxynitrides such as SrTaO₂N and BaTaO₂N and GaFeO₃ with a k-alumina-type structure.

Although metal oxides and metal nitrides are given as examples in the above description, there is not limitation thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator including the material that can have ferroelectricity can have a stacked-layer structure of a plurality of materials selected from the above-listed materials. The above-listed materials and the like may change their crystal structures (characteristics) according to a variety of processes and the like as well as film formation conditions. Thus, in this specification and the like, not only a material that exhibits ferroelectricity but also a material that can have ferroelectricity may be referred to as a ferroelectric.

A metal oxide containing one or both of hafnium and zirconium is preferable because the metal oxide can have ferroelectricity even when being processed into a thin film of several nanometers. Here, the thickness of the insulator including the material that can have ferroelectricity can be less than or equal to 100 nm, preferably less than or equal to 50 nm, further preferably less than or equal to 20 nm, still further preferably less than or equal to 10 nm (typically, greater than or equal to 2 nm and less than or equal to 9 nm). The thickness of the insulator is preferably greater than or equal to 8 nm and less than or equal to 12 nm, for example. When the insulator functioning as a dielectric of a capacitor is a ferroelectric layer that can be thin, for example, the capacitor can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupied area) in a top view of less than or equal to 100 μm², less than or equal to 10 μm², less than or equal to 1 μm², or less than or equal to 0.1 μm². Furthermore, even with an area less than or equal to 10000 nm² or less than or equal to 1000 nm², a ferroelectric layer has ferroelectricity in some cases. With a small-area ferroelectric layer, the area occupied by the capacitor can be reduced.

A ferroelectric is an insulator and has a property of causing internal polarization by application of an electric field from the outside and maintaining the polarization even after the electric field is made zero. Thus, with the use of a capacitor that uses this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory) or a ferroelectric memory, for example. A ferroelectric memory includes a transistor and a ferroelectric capacitor, and one of a source and a drain of the transistor is electrically connected to one terminal of the ferroelectric capacitor, for example.

Note that ferroelectricity is exhibited by displacement of oxygen or nitrogen of a crystal included in a ferroelectric layer due to an electric field applied from the outside. Ferroelectricity is presumably exhibited depending on the crystal structure of a crystal included in a ferroelectric layer. Thus, in order for the insulator including the material that can have ferroelectricity to exhibit ferroelectricity, the insulator needs to include a crystal. It is particularly preferable that the insulator include a crystal having an orthorhombic crystal structure to exhibit ferroelectricity. Incidentally, a crystal included in the insulator may have one or more selected from cubic, tetragonal, orthorhombic, monoclinic, hexagonal crystal structures. The insulator may have an amorphous structure. In that case, the insulator may have a composite structure including an amorphous structure and a crystal structure.

The semiconductor device according to one embodiment of the present invention is not limited to the semiconductor device described in this embodiment. At least part of the structure examples, the operation examples, the drawings corresponding thereto, and the like described in this embodiment can be combined with the other structure examples, the other operation examples, the other drawings, the other embodiments, and the like described in this specification and the like as appropriate.

### Embodiment 3

In this embodiment, a transistor including an oxide semiconductor in a channel formation region (OS transistor) will be described. In the description of the OS transistor, comparison with a transistor including silicon in a channel formation region (also referred to as a Si transistor) is also described simply.

### OS Transistor

An oxide semiconductor having a low carrier concentration is preferably used in an OS transistor. For example, the carrier concentration of an oxide semiconductor in the channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor, the impurity concentration in the oxide semiconductor may be reduced so that the density of defect states in the oxide semiconductor can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that impurities in an oxide semiconductor refer to, for example, elements other than the main components of an oxide semiconductor. For example, an element with a concentration lower than 0.1 atomic % can be regarded as an impurity.

When impurities or oxygen vacancies are in a channel formation region of the oxide semiconductor included in an OS transistor, electrical characteristics of the OS transistor may vary easily and the reliability thereof may worsen. In some cases, a defect that is an oxygen vacancy into which hydrogen enters (hereinafter sometimes referred to as V_{O}H) is formed in the oxide semiconductor of the OS transistor, which generates an electron serving as a carrier. Formation of V_{O}H in the channel formation region may increase the donor concentration in the channel formation region of the OS transistor. An increase in the donor concentration in the channel formation region of the OS transistor may lead to a variation in threshold voltage. Thus, the oxygen vacancies in the channel formation region of the oxide semiconductor allow the OS transistor to easily have normally-on characteristics (to cause the drain current to flow at a gate voltage of 0 V). Therefore, impurities, oxygen vacancies, and V_{O}H are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current of the transistor (also referred to as Ioff) can be reduced.

In a Si transistor, a short-channel effect (SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as an S value), and an increase in leakage current. Here, the S value means the amount of change in gate voltage in the subthreshold region when the drain voltage is constant and the drain current is changed by one order of magnitude.

The characteristic length is widely used as an indicator of resistance to the short-channel effect. The characteristic length is an indicator of curving of a potential in a channel formation region. The smaller the characteristic length is, the more sharply the potential rises; thus, a smaller characteristic length indicates higher resistance to the short-channel effect.

The OS transistor is an accumulation-type transistor and the Si transistor is an inversion-type transistor. Thus, the OS transistor has a shorter characteristic length between the source region and the channel formation region and a shorter characteristic length between the drain region and the channel formation region than the Si transistor has. Accordingly, the OS transistor has higher resistance to the short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region each become an n⁺-type region in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be used as a short-channel transistor than the Si transistor. Note that the gate length refers to the length of a gate electrode in a direction in which carriers move inside a channel formation region during operation of the transistor and to the width of the bottom surface of the gate electrode in a top view of the transistor.

Miniaturization of the OS transistor can improve the high frequency characteristics of the transistor. Specifically, the cutoff frequency of the transistor can be improved. When the gate length of the OS transistor is within the above-described range, the cutoff frequency of the transistor can be greater than or equal to 50 GHz, preferably greater than or equal to 100 GHz, further preferably greater than or equal to 150 GHz at room temperature, for example.

The above-described comparison of the OS transistor with the Si transistor demonstrates that the OS transistor has an effect superior to the Si transistor, such as a low off-state current and capability of short-channel transistor formation.

The structures, configurations, methods, and the like described in this embodiment can be used in combination as appropriate with the structures, configurations, methods, and the like described in the other embodiments and the like.

### Embodiment 4

In this embodiment, a semiconductor device of one embodiment of the present invention and an arithmetic processing device (also referred to as an arithmetic device) are described. A semiconductor device 900 of one embodiment of the present invention can function as a memory device. An arithmetic processing device that can use the semiconductor device 900 and a semiconductor device including the arithmetic processing device are described. Note that at least part of the semiconductor device described above in Embodiment 1 can be used for the semiconductor device and the arithmetic processing device described in this embodiment.

### Semiconductor Device 900

FIG. 18 illustrates a block diagram illustrating a structure example of the semiconductor device 900. The semiconductor device 900 illustrated in FIG. 18 includes a driver circuit 910 and a memory array 920. The memory array 920 includes one or more memory cells 950. FIG. 18 illustrates an example in which the memory array 920 includes a plurality of memory cells 950 arranged in a matrix.

The driver circuit 910 includes a power switch 931, a power switch 932, and a peripheral circuit 915. The peripheral circuit 915 includes a peripheral circuit 911, a control circuit 912, and a voltage generator circuit 928.

Signals are supplied to a terminal BW, a terminal CE, a terminal GW, a terminal MCK, a terminal WAKE, a terminal ADDR, a terminal WDA, a terminal PON1, and a terminal PON2 from the outside of the semiconductor device 900, for example. Furthermore, for example, a signal is output from a terminal RDA to the outside of the semiconductor device 900.

For example, a clock signal is supplied to the terminal MCK. Control signals are supplied to the terminal BW, the terminal CE, and the terminal GW. A chip enable signal is supplied to the terminal CE. A global write enable signal is supplied to the terminal GW. A byte write enable signal is supplied to the terminal BW. An address signal is supplied to the terminal ADDR. Data to be written is supplied to the terminal WDA. The read data is supplied to the terminal RDA. Power gating control signals are supplied to the terminal PONI and the terminal PON2. Note that the signals supplied to the terminal PON1 and the terminal PON2 may be generated in the control circuit 912, for example.

The control circuit 912 has a function of controlling the operation of the semiconductor device 900. The control circuit 912 has a function of performing a logic operation of the signals supplied to the terminal CE, the terminal GW, and the terminal BW to determine an operation mode (e.g., a writing operation or a reading operation) of the semiconductor device 900, for example. The control circuit 912 also has a function of generating a signal for controlling the peripheral circuit 911 so that the operation mode is executed.

The voltage generator circuit 928 has a function of generating a potential for operating the driver circuit 910. The voltage generator circuit 928 has a function of generating a potential in response to the input of a clock signal supplied to the terminal MCK in accordance with the signal supplied to the terminal WAKE, for example. To the terminal WAKE, a signal for controlling whether the clock signal supplied to the terminal MCK is input to the voltage generator circuit 928 is supplied, for example.

The peripheral circuit 911 has a function of writing and reading data to/from the memory cells 950. The peripheral circuit 911 has a function of generating a variety of signals for controlling the operation of the memory cells 950, for example. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding an address signal supplied to the terminal ADDR. The row decoder 941 has a function of specifying a row to be accessed. The column decoder 942 has a function of specifying a column to be accessed. The row driver 923 has a function of selecting the row specified by the row decoder 941 and supplying a desired signal to the corresponding memory cells 950 or the like, for example. The column driver 924 has a function of selecting the column specified by the column decoder 942 and supplying a desired signal to the corresponding sense amplifier 927 or the like, for example.

The sense amplifier 927 has a function of writing and reading data to/from the memory cells 950 selected by the row driver and the column driver. The input circuit 925 has a function of retaining data supplied to the terminal WDA from the outside of the semiconductor device 900. Data (data Din) retained in the input circuit 925 is written to the memory cell 950 through the sense amplifier 927. Data stored in the memory cell 950 is read out to the output circuit 926 through the sense amplifier 927. The output circuit 926 has a function of retaining the read data (data Dout). In addition, the output circuit 926 has a function of outputting the retained data from the terminal RDA to the outside of the semiconductor device 900.

The power switch 931 has a function of controlling whether a potential supplied to a terminal VMD is supplied to the peripheral circuit 915. The power switch 932 has a function of controlling whether a potential supplied to a terminal VMH is supplied to the row driver 923. Here, for example, a high power supply potential (e.g., the potential VDD) for operating the driver circuit 910 is supplied to the terminal VMD, and a low power supply potential (e.g., the potential VSS) is supplied to a terminal VMS. For example, a high power supply potential (e.g., a potential VDH which is a potential higher than the potential VDD) for operating the memory cells 950 or the like is supplied to the terminal VMH. The power switch 931 is controlled to be in the conduction state or the non-conduction state by the signal supplied to the terminal PON1. The power switch 932 is controlled to be in the conduction state or the non-conduction state by the signal supplied to the terminal PON2.

Note that circuits and terminals are selected as appropriate in the driver circuit 910. Another circuit and another terminal may be added as appropriate.

In one embodiment of the present invention, for example, power gating can be controlled by using at least part of the semiconductor device described above in Embodiment 1 for the control of the power switch 931 and the power switch 932. For example, when the transistor M102 illustrated in FIG. 1A or the like or the transistor M102p illustrated in FIG. 2A or the like corresponds to each of the power switch 931 and the power switch 932, power gating can be controlled with at least part of the semiconductor device 100.

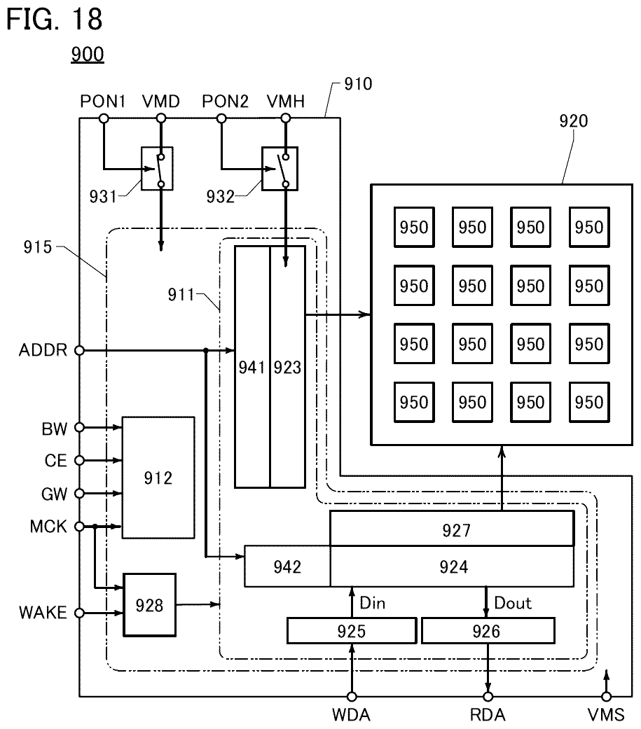

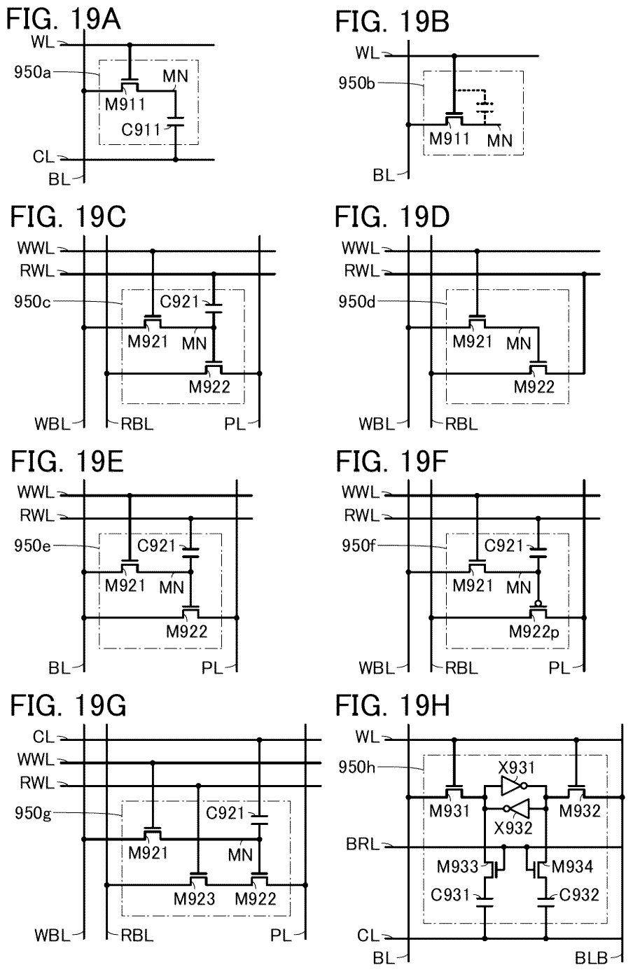

With FIG. 19A to FIG. 19H, structure examples of memory cell applicable to the memory cell 950 are described.

A memory cell 950a illustrated in FIG. 19A includes a transistor M911 and a capacitor C911. One of a source and a drain of the transistor M911 is electrically connected to the one terminal of the capacitor C911. The other of the source and the drain of the transistor M911 is electrically connected to a wiring BL functioning as a bit line. A gate of the transistor M911 is electrically connected to a wiring WL functioning as word line. The other terminal of the capacitor C911 is electrically connected to a wiring CL. Note that a wiring where the one of the source and the drain of the transistor M911 and the one terminal of the capacitor C911 are electrically connected to each other is referred to as a wiring MN in some cases.

The memory cell 950a can store binary data when the potential corresponding to the amount of charge accumulated in the capacitor C911, that is, the amount of charge retained in the wiring MN, is made to correspond to “1” or “0”. Note that ternary or higher-level data may be stored, for example. In the case where data is written to the memory cell 950a, the conduction state of the transistor M911 is controlled, whereby a potential corresponding to data can be supplied from the wiring BL to the wiring MN and charge corresponding to the potential can be retained. In the case where data is read from the memory cell 950a, the conduction state of the transistor M911 is controlled, so that charge retained in the wiring MN can be extracted to the wiring BL.

Note that reading of data from the memory cell 950a means extraction of the charge retained in the wiring MN to the wiring BL and thus changes the potential of the wiring MN. That is, by reading data from the memory cell 950a, stored data is destroyed. In other words, reading of data from the memory cell 950a is destructive reading. Thus, the memory cell 950a needs writing back (refresh) of data after data reading.

In one embodiment of the present invention, an n-channel OS transistor can be used as the transistor M911, for example.

Note that the memory cell 950a illustrated in FIG. 19A is a memory cell of a DRAM (Dynamic Random Access Memory), and a structure using an OS transistor as the transistor M911 is particularly referred to as a DOSRAM (registered trademark) in some cases. The DOSRAM is an abbreviation for a Dynamic Oxide Semiconductor RAM (Random Access Memory). Since an OS transistor having an extremely low off-state current is used in the DOSRAM, data can be stored for a long time. In addition, multilevel data or analog data can be stored. Data once written can be stored for a long period, and thus the frequency of data refresh can be decreased. In addition, the electrostatic capacitance of the cell capacitor (the capacitor C911) can be reduced, so that the cell size can be reduced. Thus, the use of the DOSRAM can reduce power consumption of a semiconductor device and a memory device and increase the recording density thereof.

A memory cell 950b illustrated in FIG. 19B is a variation example of the memory cell 950a illustrated in FIG. 19A and is different from the memory cell 950a in not including the capacitor C911.

In the memory cell 950b illustrated in FIG. 19B, charge can be accumulated in a parasitic capacitor (capacitance between the gate and one of the source and the drain of the transistor M911) indicated by a dashed line or the like. With such a structure, for example, the cell size can be reduced, so that the recording density of a semiconductor device and a memory device can be increased.

A memory cell 950c illustrated in FIG. 19C includes a transistor M921, a transistor M922, and a capacitor C921. One of a source and a drain of the transistor M921 is electrically connected to a gate of the transistor M922 and one terminal of the capacitor C921. The other of the source and the drain of the transistor M921 is electrically connected to a wiring WBL functioning as a write bit line. A gate of the transistor M921 is electrically connected to a wiring WWL functioning as a write word line. One of a source and a drain of the transistor M922 is electrically connected to a wiring RBL functioning as a read bit line. The other of the source and the drain of the transistor M922 is electrically connected to a wiring PL. The other terminal of the capacitor C921 is electrically connected to a wiring RWL functioning as a read word line. Note that a wiring where the one of the source and the drain of the transistor M921, the gate of the transistor M922, and the one terminal of the capacitor C921 are electrically connected to one another is referred to as the wiring MN in some cases.

The memory cell 950c can store binary data when the potential corresponding to the amount of charge accumulated in the capacitor C921, that is, the amount of charge retained in the wiring MN, is made to correspond to “1” or “0”. Note that ternary or higher-level data may be stored, for example. In the case where data is written to the memory cell 950c, the conduction state of the transistor M921 is controlled, whereby a potential corresponding to data can be supplied from the wiring WBL to the wiring MN and charge corresponding to the potential can be retained. In the case where data is read from the memory cell 950c, the transistor M922 is brought into the conduction state or the non-conduction state in accordance with the potential of the wiring MN, whereby a potential corresponding to the data can be extracted to the wiring RBL.

In one embodiment of the present invention, an n-channel OS transistor can be used as the transistor M921, for example. As the transistor M922, an n-channel transistor (e.g., an OS transistor or a Si transistor) can be used, for example.

Note that the memory cell 950c illustrated in FIG. 19C is a gain-cell memory cell; in particular, a structure in which an OS transistor is used as the transistor M921 is referred to as a NOSRAM (registered trademark) in some cases. The NOSRAM is an abbreviation for a Nonvolatile Oxide Semiconductor RAM. When an OS transistor having an extremely low off-state current is used in the NOSRAM, data can be stored for a long time. In addition, multilevel data or analog data can be stored. Since the transistor for writing (the transistor M921) and the transistor for reading (the transistor M922) are different from each other, non-destructive reading is performed in data reading. Thus, the memory cell can be used as a nonvolatile memory, for example.

A memory cell 950d illustrated in FIG. 19D is a modification example of the memory cell 950c illustrated in FIG. 19C and is different from the memory cell 950c in not including the capacitor C921 and in that the other of the source and the drain of the transistor M922 is electrically connected to the wiring RWL.

In the memory cell 950d illustrated in FIG. 19D, charge can be accumulated in a parasitic capacitor added to the wiring MN. With such a structure, for example, the cell size can be reduced, so that the recording density of a semiconductor device and a memory device can be increased.

A memory cell 950e illustrated in FIG. 19E is a modification example of the memory cell 950c illustrated in FIG. 19C and is different from the memory cell 950c in that the other of the source and the drain of the transistor M921 is electrically connected to the wiring BL and the one of the source and the drain of the transistor M922 is electrically connected to the wiring BL.

In the memory cell 950e illustrated in FIG. 19E, the wiring BL can function as a bit line for both writing and reading. With such a structure, for example, the cell size can be reduced, so that the recording density of a semiconductor device and a memory device can be increased.

A memory cell 950f illustrated in FIG. 19F is a modification example of the memory cell 950c illustrated in FIG. 19C and is different from the memory cell 950c in including a transistor M922p instead of the transistor M922. As the transistor M922p, a p-channel Si transistor can be used, for example.

In the memory cell 950f illustrated in FIG. 19F, data is read using the p-channel transistor; thus, the structure, operation, and the like of the sense amplifier can be simplified in some cases, for example. With such a structure, for example, the layout area of the driver circuit can be reduced, so that a semiconductor device and a memory device can be downsized.

A memory cell 950g illustrated in FIG. 19G is a modification example of the memory cell 950c illustrated in FIG. 19B and is different from the memory cell 950c in including a transistor M923. One of the source and the drain of the transistor M922 is electrically connected to one of a source and a drain of the transistor M923, the other of the source and the drain of the transistor M922 is electrically connected to the wiring PL, the other of the source and the drain of the transistor M923 is electrically connected to the wiring RBL, and a gate of the transistor M923 is electrically connected to the wiring RWL. As the transistor M923, an n-channel transistor (e.g., an OS transistor or a Si transistor) can be used, for example.

In the memory cell 950g illustrated in FIG. 19G, the parasitic capacitance between the wiring MN and the wiring RBL can be reduced. Such a structure can, for example, inhibit noise from being mixed into the wiring MN via the gate capacitance of the transistor M922 and improve the reliability of a semiconductor device and a memory device.

A memory cell 950h illustrated in FIG. 19H includes a transistor M931, a transistor M932, a transistor M933, a transistor M934, a capacitor C931, a capacitor C932, an inverter X931, and an inverter X932. One of a source and a drain of the transistor M931 is electrically connected to one of a source and a drain of the transistor M933, an input terminal of the inverter X931, and an output terminal of the inverter X932. One of a source and a drain of the transistor M932 is electrically connected to one of a source and a drain of the transistor M934, an output terminal of the inverter X931, and an input terminal of the inverter X932. The other of the source and the drain of the transistor M933 is electrically connected to the one terminal of the capacitor C931. The other of the source and the drain of the transistor M934 is electrically connected to the one terminal of the capacitor C932. The other of the source and the drain of the transistor M931 is electrically connected to the wiring BL functioning as one of a pair of bit lines. The other of the source and the drain of the transistor M932 is electrically connected to a wiring BLB functioning as the other of the pair of bit lines. A gate of the transistor M931 and a gate of the transistor M932 are electrically connected to the wiring WL functioning as a word line. A gate of the transistor M933 and a gate of the transistor M934 are electrically connected to a wiring BRL. The other terminal of the capacitor C931 and the other terminal of the capacitor C932 are electrically connected to the wiring CL.

In the memory cell 950h, binary data of “1” or “0” can be stored in an inverter loop composed of the inverter X931 and the inverter X932. In writing data to the memory cell 950h, the conduction states of the transistor M931 and the transistor M932 are controlled, so that a potential corresponding to data can be supplied from each of the wiring BL and the wiring BLB to the inverter loop. In reading data from the memory cell 950h, the conduction states of the transistor M931 and the transistor M932 are controlled, so that a potential corresponding to the data stored in the inverter loop can be extracted to each of the wiring BL and the wiring BLB.

In the memory cell 950h, by controlling the conduction states of the transistor M933 and the transistor M934, a potential corresponding to the data stored in the inverter loop can be supplied to each of the one terminal of the capacitor C931 and the one terminal of the capacitor C932 and charge corresponding to the potential can be retained. That is, data backup can be performed. Furthermore, in the memory cell 950h, charge retained in the one terminal of the capacitor C931 and the one terminal of the capacitor C932 can be extracted to the inverter loop by controlling the conduction states of the transistor M933 and the transistor M934. That is, data recovery can be performed.

In one embodiment of the present invention, n-channel OS transistors can be used as the transistor M931, the transistor M932, the transistor M933, and the transistor M934, for example. As each of the inverter X931 and the inverter X932, an inverter circuit prepared in a standard circuit library can be used. That is, as transistors included in the inverter X931 and the inverter X932, n-channel and p-channel Si transistors can be used, for example.

Note that the memory cell 950h illustrated in FIG. 19H is a memory cell of an SRAM (Static Random Access Memory) capable of backup operation; in particular, a structure in which OS transistors are used as the transistor M931, the transistor M932, the transistor M933, and the transistor M934 is referred to as an OS-SRAM (Oxide Semiconductor-SRAM) in some cases.

In one embodiment of the present invention, there is no limitation to the memory cell 950a to the memory cell 950h, and a memory cell in which the structures of the memory cells are combined as appropriate can be formed.

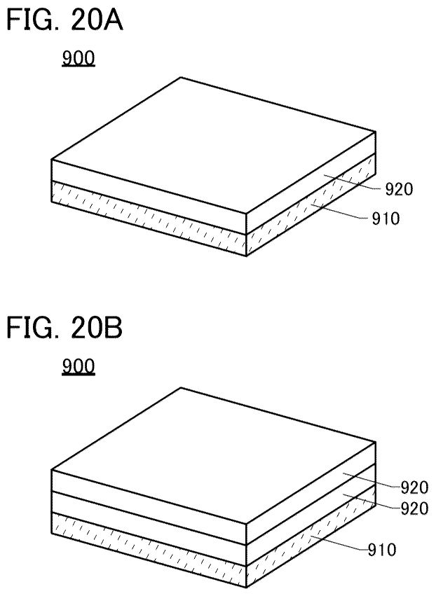

The driver circuit 910 and the memory array 920 that are included in the semiconductor device 900 may be provided on the same plane. As illustrated in FIG. 20A, the driver circuit 910 and the memory array 920 may be provided to overlap with each other. When the driver circuit 910 and the memory array 920 are provided to overlap with each other, the signal transmission distance can be shortened. Alternatively, a plurality of memory arrays 920 may be provided over the driver circuit 910 as illustrated in FIG. 20B.

### Arithmetic Device 960

Next, an example of an arithmetic processing device that can include the semiconductor device, such as the memory device described above, is described.

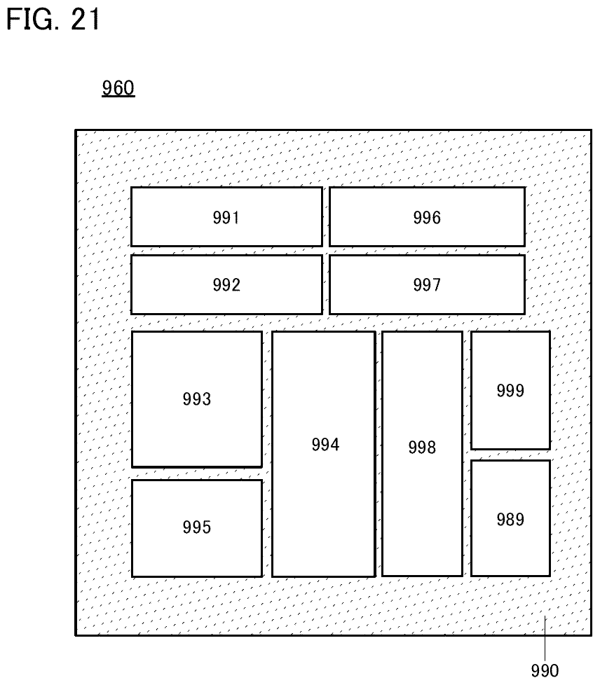

FIG. 21A illustrates a block diagram of an arithmetic device 960. The arithmetic device 960 illustrated in FIG. 21 can be used for a CPU (Central Processing Unit) , for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), and a NPU (Neural Processing Unit).

The arithmetic device 960 illustrated in FIG. 21 includes, over a substrate 990, an ALU 991 (ALU: Arithmetic logic unit, arithmetic circuit), an ALU controller 992, an instruction decoder 993, an interrupt controller 994, a timing controller 995, a register 996, a register controller 997, a bus interface 998, a cache 999 (also referred to as a cache memory), and a cache interface 989. A semiconductor substrate, an SOI substrate, a glass substrate, or the like is used as the substrate 990. A rewritable ROM (Read Only Memory) and a ROM interface may be included. In addition, the cache 999 and the cache interface 989 may be provided in a separate chip.

The cache 999 can exchange data with a main memory provided in a separate chip through the cache interface 989. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 21 is only an example with a simplified structure, and the actual arithmetic device 960 has a variety of structures depending on the application. For example, what is called a multicore structure is preferably employed in which a plurality of cores each including the arithmetic device 960 in FIG. 21 are included and operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore structure including 16 or more, preferably 32 or more, further preferably 64 or more cores. In addition, the number of bits that the arithmetic device 960 can process in an internal arithmetic circuit, a data bus, or the like can be 8 bits, 16 bits, 32 bits, 64 bits, or the like, for example.

An instruction that is input to the arithmetic device 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority or a mask state, and processes the request. The register controller 997 generates an address of the register 996, and performs reading or writing from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 illustrated in FIG. 21, the register controller 997 selects a retention operation in the register 996 in accordance with an instruction from the ALU 991. That is, the register controller 997 selects whether data is retained by a flip-flop or by a capacitor in the memory cell included in the register 996. When data retention by the flip-flop is selected, power is supplied to the memory cell in the register 996. When data retention by the capacitor is selected, the data is rewritten in the capacitor, and power supply to the memory cell in the register 996 can be stopped.

That is, in the case where power gating is performed in the arithmetic device 960, for example, in the memory cell included in the register 996, the data retained in the flip-flop can be backed up to the capacitor before the transition to the power-off state (the stop of power supply), and the data retained in the capacitor can be recovered to the flip-flop after the return to the power-on state (the restart of power supply). Thus, the time required for power gating can be shortened and power consumption can be reduced.

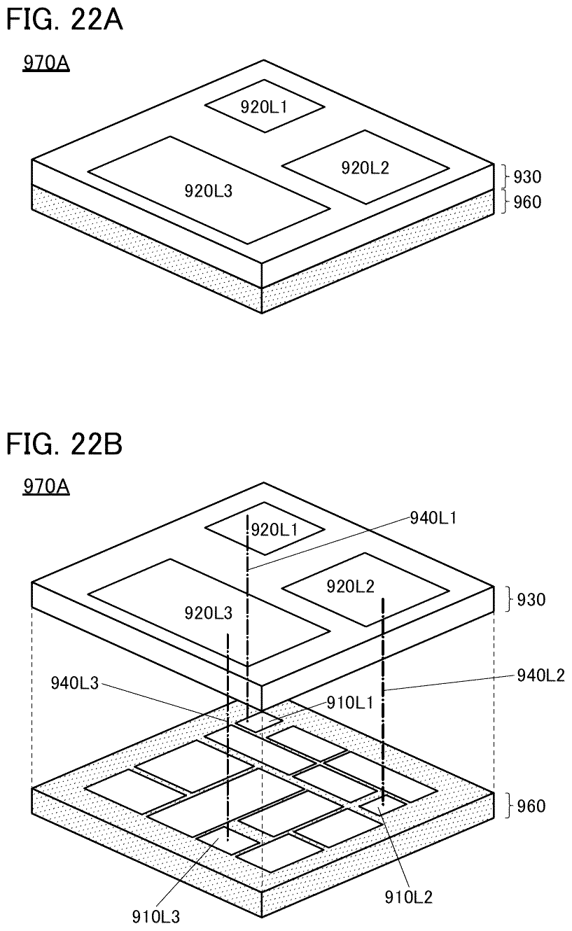

The memory array 920 and the arithmetic device 960 can be provided to overlap with each other. FIG. 22A and FIG. 22B illustrate perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 22B.

Providing the arithmetic device 960 and the layer 930 including the memory arrays to overlap with each other can shorten the wiring distance therebetween. Accordingly, the communication speed therebetween can be increased. Moreover, power consumption can be reduced.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking method) and a method in which the arithmetic device 960 and the layer 930 are formed over two different substrates, the substrates are bonded to each other, and the arithmetic device 960 and the layer 930 are stacked with a technique for forming a through via (e.g., TSV (Through Silicon Via)) or by a technique for bonding (e.g., Cu—Cu bonding). The monolithic stacking method does not require consideration of misalignment in bonding; thus, not only the chip size but also the manufacturing cost can be reduced.

Here, it is possible that the arithmetic device 960 does not include the cache 999 and the memory array 920L1, the memory array 920L2, and the memory array 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 22B, a driver circuit 910L1, a driver circuit 910L2, and a driver circuit 910L3 are provided. The driver circuit 910L1 can exchange data, a signal, and the like with the memory array 920L1 through an electrode 940L1. Similarly, the driver circuit 910L2 can exchange data, a signal, and the like with the memory array 920L2 through an electrode 940L2, and the driver circuit 910L3 can exchange data, a signal, and the like with the memory array 920L3 through an electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 989 or may have a structure that exchanges data, a signal, or the like with the cache interface 989. Similarly, the driver circuit 910L2 and the driver circuit 910L3 may also function as part of the cache interface 989 or may have a structure that exchanges data, a signal, or the like with the cache interface 989.

Whether the memory array 920 functions as the cache or the main memory is determined by the control circuit 912 included in each of the driver circuits 910. The control circuit 912 can make some of the plurality of memory cells 950 included in the semiconductor device 900 function as a RAM (Random Access Memory) on the basis of a signal supplied from the arithmetic device 960.

In the semiconductor device 900, some of the plurality of memory cells 950 can function as the cache and the other memory cells as the main memory. That is, the semiconductor device 900 can have both the function of the cache and the function of the main memory. The semiconductor device 900 of one embodiment of the present invention can function as a universal memory, for example.

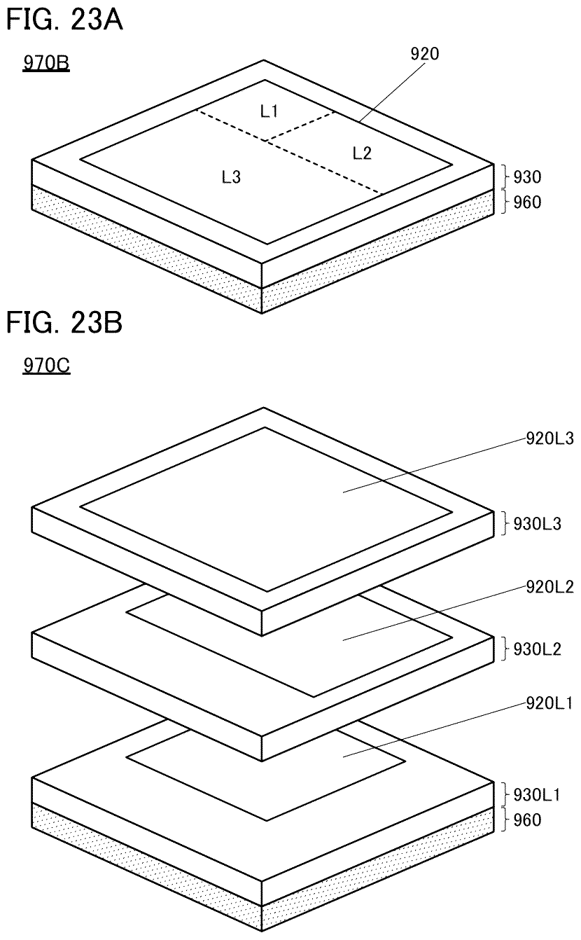

The layer 930 including one memory array 920 may be provided to overlap with the arithmetic device 960. FIG. 23A is a perspective view of a semiconductor device 970B.

In the semiconductor device 970B, one memory array 920 can be divided into a plurality of areas having different functions. FIG. 23A illustrates an example in which a region L1, a region L2, and a region L3 are used as the L1 cache, the L2 cache, and the L3 cache, respectively.

In the semiconductor device 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 23B illustrates a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

In one embodiment of the present invention, power gating can be performed in the semiconductor device 970A, for example. In that case, for example, by using at least part of the semiconductor device described above in Embodiment 1, power gating can be controlled on the component basis in the semiconductor device 970A. For example, in the semiconductor device 970A, power gating of each of the driver circuit 910L1, the driver circuit 910L2, and the driver circuit 910L3 can be controlled in accordance with the usage conditions of each of the memory array 920L1, the memory array 920L2, and the memory array 920L3.

For example, in the case where at least part of the semiconductor device 100 described above in Embodiment 1 is used in the semiconductor device 970A, the power management portion 101 can be provided in the arithmetic device 960 or in the same layer as the arithmetic device 960, and the setting information retention portion 102 and the power switch portion 103 can be provided in the layer 930. That is, for example, in the layer 930, the setting information retention portion 102 and the power switch portion can be provided near the driver circuit 910L1, the driver circuit 910L2, and the driver circuit 910L3 and in a space where the memory array 920L1, the memory array 920L2, and the memory array 920L3 are not provided. Accordingly, the layer 930 can be effectively utilized to reduce the area overhead.

Note that this embodiment can be combined with any of the other embodiments in this specification and the like as appropriate.

### Embodiment 5

In this embodiment, application examples of the memory device of one embodiment of the present invention are described.

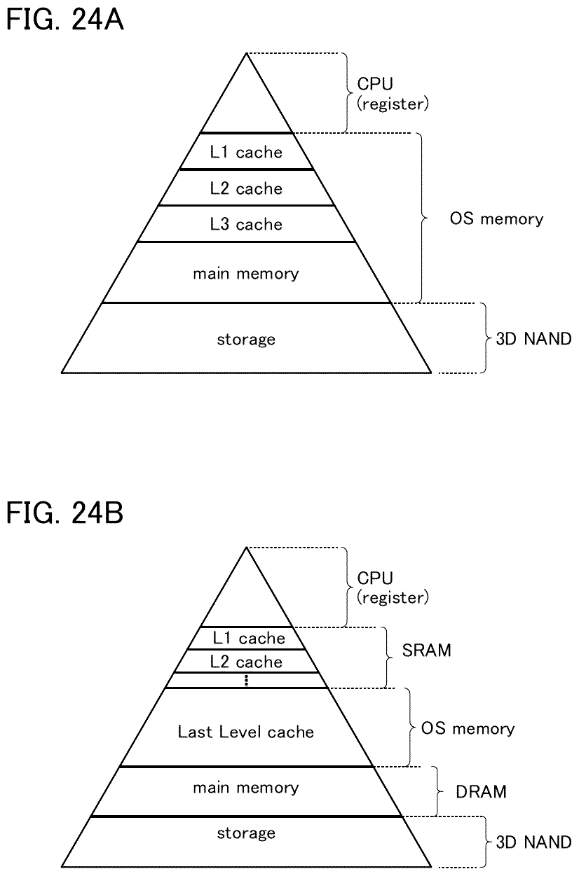

In general, a variety of memory devices are used in semiconductor devices such as computers in accordance with the intended use. FIG. 24A illustrates the hierarchy of various memory devices used in a semiconductor device. The memory devices at the upper levels require higher operating speeds, whereas the memory devices at the lower levels require larger storage capacities and higher recording densities. FIG. 24A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

The memory included as the register in the arithmetic processing device such as a CPU is used for temporary storage of arithmetic operation results, for example, and thus is very frequently accessed by the arithmetic processing device. Accordingly, rapid operation is more important than the storage capacity of the memory. The register also has a function of retaining setting information or the like of the arithmetic processing device.

The cache has a function of duplicating and retaining part of data retained in the main memory. Duplicating frequently used data and retaining the duplicated data in the cache facilitates rapid data access. The cache requires a smaller storage capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and a variety of programs used in the arithmetic processing device, for example. Therefore, the storage is required to have a large storage capacity and a high recording density rather than operating speed. For example, a high-capacity nonvolatile memory device such as a 3D NAND memory device can be used.

The memory device including an oxide semiconductor (the OS memory) of one embodiment of the present invention operates at high speed and can retain data for a long time. Thus, as illustrated in FIG. 24A, the memory device of one embodiment of the present invention can be used at both the level including the cache and the level including the main memory. The memory device of one embodiment of the present invention can also be used at the level including the storage.

FIG. 24B illustrates an example in which an SRAM is used as some of the caches and the OS memory of one embodiment of the present invention is used as another one of the caches.

The lowest-level cache can be referred to as an LLC (Last Level cache). The LLC does not require a higher operation speed than a higher-level cache, but desirably has large storage capacity. The OS memories of one embodiment of the present invention can have a large storage capacity and a high recording density by being stacked in the three-dimensional direction, and thus can be used as the LLC. Note that the OS memory of one embodiment of the present invention can also be used as an FLC (Final Level cache).

For example, as illustrated in FIG. 24B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 24B.

Note that this embodiment can be combined with any of the other embodiments in this specification and the like as appropriate.

### Embodiment 6

This embodiment will describe an electronic component, an electronic device, a large computer, a device for space, and a data center (also referred to as a DC) that can use the semiconductor device described in the above embodiment. An electronic component, an electronic device, a large computer, a device for space, and a data center each using the semiconductor device of one embodiment of the present invention are effective in achieving high performance, e.g., reducing power consumption.

### Electronic Component

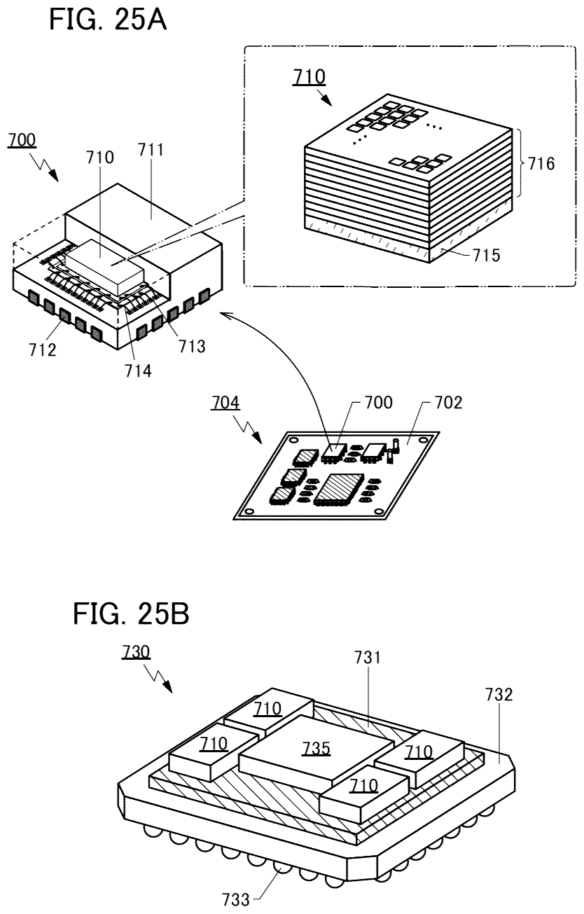

FIG. 25A is a perspective view of an electronic component 700 and a substrate (a circuit board 704) on which the electronic component 700 is mounted. The electronic component 700 illustrated in FIG. 25A includes a semiconductor device 710 in a mold 711. FIG. 25A omits illustrations of some parts to show the inside of the electronic component 700. The electronic component 700 includes a land 712 outside the mold 711. The land 712 is electrically connected to an electrode pad 713. The electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, whereby the circuit board 704 is completed.

The semiconductor device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu-Cu direct bonding, for example. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as a TSV is employed, for example; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of the plurality of memory cell arrays can improve the bandwidth of the memory and/or the access latency of the memory. Note that the bandwidth refers to the data transfer volume per unit time. The access latency refers to a period of time from data access to the start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

That is, an OS transistor has an excellent effect of achieving a wide memory bandwidth as compared with a Si transistor.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon, silicon carbide, and gallium nitride. A die obtained from a silicon substrate (also referred to as a silicon wafer) may be referred to as a silicon die, for example.

FIG. 25B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

In the electronic component 730, the semiconductor device 710 can be used as a memory device such as a high bandwidth memory (HBM), for example. The semiconductor device 735 can be used for an integrated circuit (e.g., an arithmetic device, a control device, or a signal processing device) such as a CPU (Central Processing Unit), a GPU (Graphics Processing Unit), or an FPGA (Field Programmable Gate Array), for example.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches through the plurality of wirings. The plurality of wirings have a single-layer structure or a multilayer structure. The interposer 731 has a function of electrically connecting an integrated circuit provided on the interposer 731 to an electrode provided on the package substrate 732. Accordingly, the interposer 731 is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer as the interposer 731, a TSV can also be used as the through electrode.

A silicon interposer is preferably used as the interposer 731. The silicon interposer can be formed at lower cost than an integrated circuit because it is not necessary to provide an active element. Furthermore, since wirings of a silicon interposer can be formed through a semiconductor process, formation of minute wirings, which is difficult for a resin interposer, is easy.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

For example, in a SiP, an MCM, or the like using a silicon interposer, a decrease in reliability due to a difference in the coefficient of expansion between an integrated circuit and the interposer is less likely to occur. Furthermore, the surface of a silicon interposer has high planarity, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected with use of a silicon interposer, a TSV, and the like, a space for a width of the terminal pitch and the like is needed. Thus, in the case where the size of the electronic component 730 is to be reduced, the width of the terminal pitches causes a problem, which sometimes makes it difficult to provide a large number of wirings for obtaining a wide memory bandwidth. For this reason, the above-described monolithic stacked-layer structure using OS transistors is suitable. Furthermore, a composite structure combining memory cell arrays stacked using a TSV and monolithically stacked memory cell arrays may be employed.

The substrate on which the electronic component 730 is mounted may be provided with a heat sink (a radiator plate) overlapping with the electronic component 730. In the case of providing a heat sink, the heights of integrated circuits provided on the interposer 731 are preferably equal to each other. For example, in the electronic component 730, the heights of the semiconductor device 710 and the semiconductor device 735 are preferably equal to each other.

An electrode 733 may be provided on the bottom portion of the package substrate 732 to mount the electronic component 730 on another substrate. FIG. 25B illustrates an example in which the electrode 733 is formed of a solder ball. Solder balls are provided in a matrix on the bottom portion of the package substrate 732, whereby BGA (Ball Grid Array) mounting can be achieved in the electronic component 730. Note that the electrode 733 may be formed of a conductive pin. When conductive pins are provided in a matrix on the bottom portion of the package substrate 732, PGA (Pin Grid Array) mounting can be achieved in the electronic component 730.

The electronic component 730 can be mounted on another substrate by various mounting methods not limited to BGA or PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

### Electronic Device

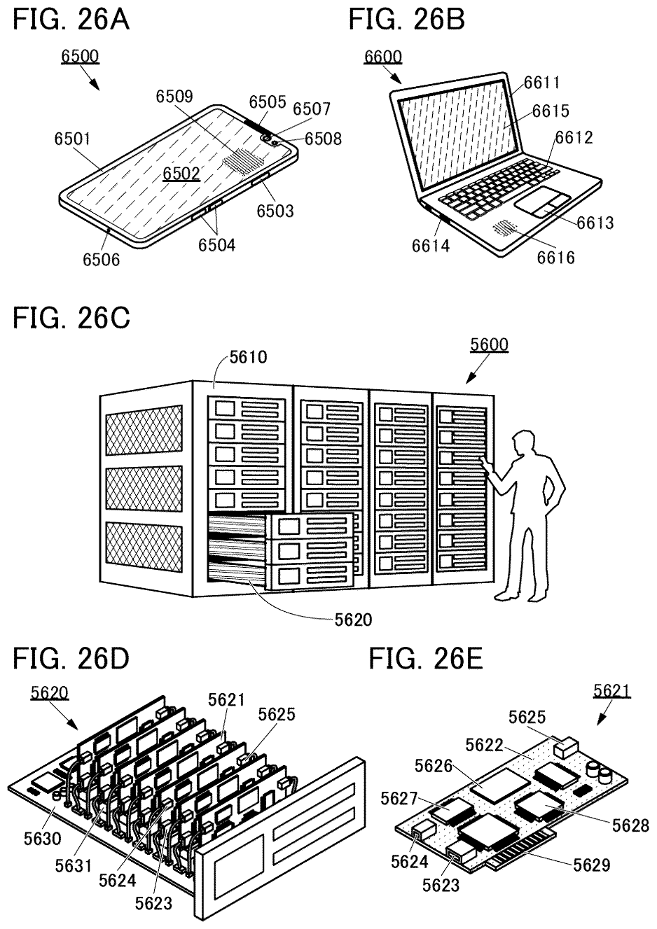

FIG. 26A is a perspective view of an electronic device 6500. The electronic device 6500 illustrated in FIG. 26A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509, for example. Note that the control device 6509 includes one or more selected from a CPU, a GPU, and a memory device, for example. The semiconductor device of one embodiment of the present invention can be used for the display portion 6502 or the control device 6509, for example. The semiconductor device of one embodiment of the present invention is preferably used for the control device 6509, in which case power consumption can be reduced.

FIG. 26B is a perspective view of an electronic device 6600. The electronic device 6600 illustrated in FIG. 26B is an information terminal that can be used as a notebook personal computer. The electronic device 6600 includes a housing 6611, a keyboard 6612, a pointing device 6613, an external connection port 6614, a display portion 6615, and a control device 6616, for example. Note that the control device 6616 includes one or more selected from a CPU, a GPU, and a memory device, for example. The semiconductor device of one embodiment of the present invention can be employed for the control device 6509 or the control device 6616, for example. The semiconductor device of one embodiment of the present invention is preferably used as the control device 6616, in which case power consumption can be reduced.

### Large Computer

FIG. 26C is a perspective view of a large computer 5600. In the large computer 5600 illustrated in FIG. 26C, a plurality of rack mount computers 5620 are stored in a rack 5610. Note that the large computer 5600 may be referred to as a supercomputer.

FIG. 26D is a perspective view illustrating a structure example of the computer 5620. In FIG. 26D, the computer 5620 includes a motherboard 5630. The motherboard 5630 includes a plurality of slots 5631 and a plurality of connection terminals (not illustrated). A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26E is an example of a processing board provided with a CPU, a GPU, and a memory device, for example. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 26E illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe (Peripheral Component Interconnect Express).

Each of the connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), SCSI (Small Computer System Interface), and the like. In the case where video signals are output from the connection terminal 5623, the connection terminal 5624, and the connection terminal 5625, an example of the standard therefor is HDMI (registered trademark) (High-Definition Multimedia Interface).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the above-described electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the above-described electronic component 700 can be used, for example.

The large computer 5600 can also function as a parallel computer. When the large computer 5600 is used as a parallel computer, large-scale computation necessary for artificial intelligence learning and inference can be performed, for example.

### Device for Space

The semiconductor device of one embodiment of the present invention can be used as a device for space such as devices processing and storing information, for example.

The semiconductor device of one embodiment of the present invention can include an OS transistor. A change in electrical characteristics of the OS transistor due to radiation irradiation is small. That is, the OS transistor is highly resistant to radiation, and thus can be suitably used in an environment where radiation can enter. For example, the OS transistor is suitably used in outer space.

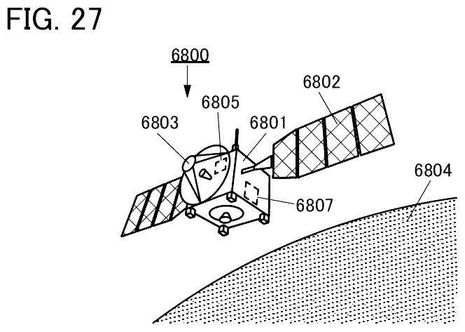

FIG. 27 illustrates an artificial satellite 6800 as an example of a device for space. The artificial satellite 6800 includes a body 6801, a solar panel 6802, an antenna 6803, a secondary battery 6805, and a control device 6807. In FIG. 27, a planet 6804 in outer space is illustrated as an example. Note that outer space refers to, for example, space at an altitude greater than or equal to 100 km, and outer space described in this specification and the like may include thermosphere, mesosphere, and stratosphere.

Although not illustrated in FIG. 27, the secondary battery 6805 may be provided with a battery management system (also referred to as a BMS) or a battery control circuit. The battery management system or the battery control circuit preferably uses the OS transistor, in which case power consumption is low and high reliability is achieved even in outer space.

The amount of radiation in outer space is 100 or more times that on the ground. Note that examples of radiation include electromagnetic waves (electromagnetic radiation) typified by X-rays or gamma rays and particle radiation typified by alpha rays, beta rays, neutron beams, proton beams, heavy-ion beams, and meson beams.

When the solar panel 6802 is irradiated with sunlight, power required for the operation of the artificial satellite 6800 is generated. However, for example, in the situation where the solar panel 6802 is not irradiated with sunlight or the amount of sunlight with which the solar panel 6802 is irradiated is small, the amount of power generated by the solar panel 6802 is small. Accordingly, a sufficient amount of power required for the operation of the artificial satellite 6800 might not be generated. In order to operate the artificial satellite 6800 even with a small amount of power generated by the solar panel 6802, the artificial satellite 6800 may be provided with the secondary battery 6805. Note that the solar panel 6802 is referred to as a solar cell module in some cases.

The artificial satellite 6800 can generate a signal. The signal is transmitted through the antenna 6803. The signal can be received by a ground-based receiver or another artificial satellite, for example. When the receiver receives the signal transmitted by the artificial satellite 6800, the position of the receiver can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the semiconductor device including the OS transistor, which is one embodiment of the present invention, is suitably used for the control device 6807. A change in electrical characteristics due to radiation irradiation is smaller in an OS transistor than in a Si transistor. Accordingly, the OS transistor has high reliability even in an environment where radiation can enter and thus is preferable.

That is, an OS transistor has an excellent effect of being highly resistant to radiation as compared with a Si transistor.

The artificial satellite 6800 can include a sensor. For example, with a structure including a visible light sensor, the artificial satellite 6800 can have a function of sensing sunlight reflected by a ground-based object. With a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be used for a device for space such as a spacecraft, a space capsule, or a space probe, for example.

### Data Center

The semiconductor device of one embodiment of the present invention can be used for a storage system in a data center, for example. Long-term management of data, such as guarantee of data immutability, is required for the data center, for example. In the case where data is managed for a long term, installation of storages and servers for storing an enormous amount of data, ensuring stable electric power for data retention, ensuring cooling equipment for data retention, or the like is necessary, for example. Therefore, for example, an increase in the scale of data center facility is necessary.

With use of the semiconductor device of one embodiment of the present invention for a storage system used in a data center, power used for retaining data can be reduced and the semiconductor device for retaining data can be downsized. Accordingly, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a peripheral module. Furthermore, the use of the semiconductor device of one embodiment of the present invention enables a data center that operates stably even in a high-temperature environment. Thus, the reliability of the data center can be increased.

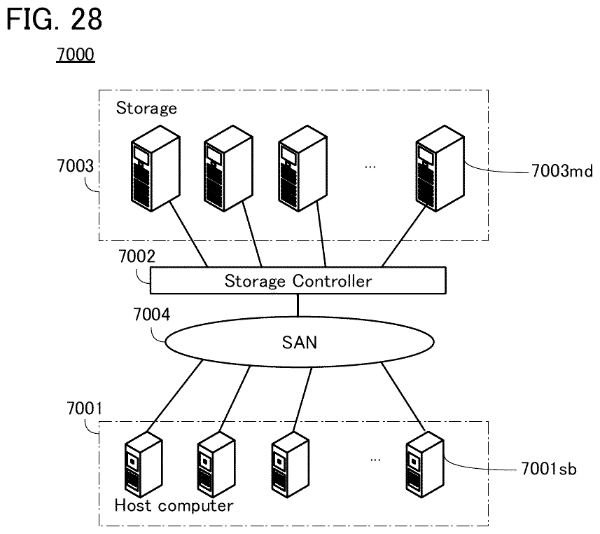

FIG. 28 illustrates a storage system that can be used in a data center. A storage system 7000 illustrated in FIG. 28 includes a plurality of servers 7001sb as a host 7001 (indicated as “Host Computer” in the diagram). The storage system 7000 includes a plurality of memory devices 7003md as a storage 7003 (indicated as “Storage” in the diagram). Furthermore, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for writing or reading data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for writing or reading data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the above-described cache memory to retain a potential based on data can reduce the refresh frequency of the above-described cache memory, so that power consumption of the above-described cache memory can be reduced. Furthermore, with a structure in which memory cell arrays are stacked, the cache memory can be downsized.

Note that with the use of the semiconductor device of one embodiment of the present invention for one or more selected from an electronic component, an electronic device, a large computer, a device for space, and a data center, power consumption can be reduced. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

The structures, configurations, methods, and the like described in this embodiment can be used in combination as appropriate with the structures, configurations, methods, and the like described in the other embodiments and the like.

### Supplementary Notes on Description in This Specification and the Like

The following are notes on the description of the foregoing embodiments and the structures in the embodiments.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

Here, the expression “X and Y are electrically connected” means the case where electric signals can be transmitted and received between X and Y when an object having any electric action is present between X and Y. For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit (e.g., a step-up circuit or a step-down circuit) or a level shifter circuit for changing the potential level of a signal); a voltage source; a current source; a switch circuit; an amplifier circuit (e.g., a circuit that can increase signal amplitude, the current amount, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (sometimes called one of a first terminal and a second terminal in this specification and the like) of a transistor, and a drain (sometimes called the other of the first terminal and the second terminal in this specification and the like) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression like the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: the wiring and the electrode. Thus, electrical connection in this specification and the like includes, in its category, such a case where one conductive film has functions of a plurality of components.

In this specification and the like, as a “resistor”, a circuit element, a wiring, or the like having a resistance value higher than 0Ω can be used, for example. Accordingly, in this specification and the like, examples of the “resistor” include a wiring having a resistance value, a transistor in which a current flows from a drain to a source, a diode, and a coil. Thus, the term “resistor” can be replaced with the term “resistance”, “load”, “region having a resistance value”, or the like. Conversely, the terms “resistance”, “load”, and “region having a resistance value” can be replaced with the term “resistor”, or the like. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance value may be higher than or equal to 1Ω and lower than or equal to 1×10⁹Ω.

In the case where a wiring is used as a resistor, the resistance value of the resistor is sometimes determined depending on the length of the wiring. Alternatively, a conductor with resistivity different from that of a conductor used as a wiring is sometimes used as a resistor. Alternatively, in the case where a semiconductor is used as a resistor, the resistance value of the resistor is sometimes determined by doping the semiconductor with an impurity.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Thus, in this specification and the like, a “capacitor” is not limited to only a circuit element that has a pair of electrodes and a dielectric between the electrodes. A “capacitor” includes, for example, parasitic capacitance generated between wirings, gate capacitance generated between a gate and one of a source and a drain of a transistor, and the like. The term “capacitor”, “parasitic capacitance”, “gate capacitance”, or the like can be replaced with the term “capacitance” and the like, for example. Conversely, the term “capacitance” can be replaced with the term “capacitor”, “parasitic capacitance”, “gate capacitance”, or the like, for example. The term “a pair of electrodes” of a “capacitor” can be replaced with “a pair of conductors”, “a pair of conductive regions”, “a pair of regions”, or the like, for example. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

A transistor in this specification and the like has three terminals called a gate (also referred to as a gate terminal, a gate region, or a gate electrode), a source (also referred to as a source terminal, a source region, or a source electrode), and a drain (also referred to as a drain terminal, a drain region, or a drain electrode). The transistor has a region where a channel is formed (also referred to as a channel formation region) between the drain and the source. In the transistor, a current can flow through the channel formation region between the source and the drain. The channel formation region refers to a region through which a current mainly flows. The gate is a control terminal for controlling the amount of current flowing through the channel formation region between the source and the drain. Two terminals functioning as the source and the drain are input/output terminals of the transistor.

Note that one of the two input/output terminals serves as the source and the other serves as the drain depending on the conductivity type (n-channel type or p-channel type) of the transistor and the levels of potentials supplied to the three terminals of the transistor. In some cases, the function of the source and the function of the drain are replaced with each other when the direction of current flow is changed in circuit operation, for example. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relationship of a transistor.

Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, each of the gates may be referred to as a first gate, a second gate, or a third gate, for example, in this specification and the like.

In this specification and the like, a transistor having a multi-gate structure having two or more gate electrodes can be used as the transistor. In the transistor having the multi-gate structure, channel formation regions are connected in series; accordingly, a plurality of transistors are connected in series. Thus, in the transistor having the multi-gate structure, the amount of off-state current can be reduced, and the withstand voltage of the transistor can be increased (the reliability can be improved). Alternatively, in the transistor having the multi-gate structure, a drain-source current does not change very much even if a drain-source voltage changes at the time of operation in a saturation region, so that a flat slope of voltage-current characteristics can be obtained. The transistor having the flat slope of the voltage-current characteristics enables an ideal current source circuit or an active load having an extremely high resistance value. As a result, the transistor having the flat slope of the voltage-current characteristics enables, for example, a differential circuit, a current mirror circuit, or the like having high characteristics.

In this specification and the like, the case where a single circuit element is illustrated in a circuit diagram may indicate a case where the circuit element includes a plurality of circuit elements. For example, the case where a single resistor is illustrated in a circuit diagram may indicate a case where two or more resistors are electrically connected to each other in series. As another example, the case where a single capacitor is illustrated in a circuit diagram may indicate a case where two or more capacitors are electrically connected to each other in parallel. As another example, the case where a single transistor is illustrated in a circuit diagram may indicate a case where two or more transistors are electrically connected to each other in series and their gates are electrically connected to each other. Similarly, as another example, the case where a single switch is illustrated in a circuit diagram may indicate a case where the switch includes two or more transistors which are electrically connected to each other in series or in parallel and whose gates are electrically connected to each other.

In this specification and the like, a “node” can be referred to as a “terminal”, a “wiring”, an “electrode”, a “conductive layer”, a “conductor”, an “impurity region”, or the like depending on the circuit structure, the device structure, or the like, for example. Furthermore, a “terminal”, a “wiring”, or the like can be referred to as a “node”, for example.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values. That is, a potential supplied to a wiring, a potential applied to a circuit and the like, or a potential output from a circuit and the like, are changed with a change of the reference potential.

In this specification and the like, the terms “high-level potential” (also referred to as “H potential” or “H”) and “low-level potential” (also referred to as “L potential” or “L”) do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

In this specification and the like, a “current” means a charge transfer (electrical conduction). For example, the description “electrical conduction of positively charged particles occurs” can be rephrased as “electrical conduction of negatively charged particles occurs in the opposite direction”. Thus, unless otherwise specified, a “current” in this specification and the like refers to a charge transfer (electrical conduction) accompanied by carrier movement. Examples of a carrier here include an electron, a hole, an anion, a cation, and a complex ion. The type of carrier differs depending on current-flowing systems (e.g., a semiconductor, a metal, an electrolyte solution, or a vacuum). For example, the “direction of current” in a wiring or the like refers to the direction in which a positive carrier moves, and the amount of current is expressed as a positive value. In other words, the direction in which a negative carrier moves is opposite to the direction of current, and the amount of current is expressed as a negative value. Thus, in the case where the polarity of current (or the direction of current) is not specified in this specification and the like, the description “a current flows from element A to element B” can be rephrased as “a current flows from element B to element A” and the like, for example. The description “a current is input to element A” and the like can be rephrased as “a current is output from element A” and the like, for example.

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the scope of claims, or the like. Furthermore, for example, a “first” component in one embodiment in this specification and the like can be omitted in other embodiments, the scope of claims, or the like.

In this specification and the like, for example, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the terms for describing arrangement in this specification and the like are not limited to those and can be replaced with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°. Moreover, the expression “an insulator positioned over (on) a top surface of a conductor” can be replaced with the expression “an insulator positioned on a left surface (or a right surface) of a conductor” when the direction of a drawing illustrating these components is rotated by 90°.

The term “over” or “under” does not necessarily mean that a component is placed directly over or directly under and directly in contact with another component. For example, the expression “electrode B over insulating layer A” does not necessarily mean that the electrode Bis formed over and in direct contact with the insulating layer A, and does not exclude the case where another component is provided between the insulating layer A and the electrode B.

In this specification and the like, components arranged in a matrix and their positional relationship are sometimes described using a term such as “row” or “column”, for example. The positional relationship between components is changed as appropriate in accordance with a direction in which each component is described. Thus, for example, the terms such as “row” and “column” are not limited to those described in this specification and the like and can be replaced with another term as appropriate depending on the situation. For example, the term “row direction” can be replaced with the term “column direction” when the direction of the diagram is rotated by 90°.

Furthermore, the term “overlap”, for example, in this specification and the like does not limit a state such as the stacking order of components. For example, the expression “electrode B overlapping with insulating layer A” does not necessarily mean the state where the electrode B is formed over the insulating layer A. The expression “electrode B overlapping with insulating layer A”, for example, does not exclude the state where the electrode B is formed under the insulating layer A and the state where the electrode B is formed on the right side (or the left side) of the insulating layer A.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is placed between the insulating layer A and the electrode B.

In this specification and the like, the term “film”, “layer”, or the like can be, for example, interchanged with each other depending on the situation, in some cases. For example, the term “conductive layer” can be changed into the term “conductive film” in some cases. For another example, the term “insulating film” can be changed into the term “insulating layer” in some cases. Alternatively, for example, the term “film”, “layer”, or the like is not used and can be interchanged with another term depending on the situation, in some cases. For example, the term “conductive layer” or “conductive film” can be changed into the term “conductor” in some cases. Furthermore, the term “conductor” can be changed into the term “conductive layer” or “conductive film” in some cases. For example, the term “insulating layer” or “insulating film” can be changed into the term “insulator” in some cases. Furthermore, the term “insulator” can be changed into the term “insulating layer” or “insulating film” in some cases.

In addition, in this specification and the like, for example, the term such as “electrode”, “wiring”, or “terminal” does not limit the function of a component. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Thus, for example, an “electrode” can be part of a “wiring” or a “terminal”. Furthermore, a “terminal” can be part of a “wiring” or an “electrode”. Moreover, the term “electrode”, “wiring”, “terminal”, or the like is sometimes replaced with the term “region”, for example.

In addition, in this specification and the like, for example, the terms such as “wiring”, “signal line”, and “power supply line” can be interchanged with each other depending on the situation, in some cases. For example, the term “wiring” can be changed into the term “signal line” in some cases. For another example, the term “wiring” can be changed into the term “power supply line” or the like in some cases. Conversely, for example, the term “signal line”, “power supply line”, or the like can be changed into the term “wiring” in some cases. Furthermore, for example, the term “power supply line” or the like can be changed into the term “signal line” or the like in some cases. Conversely, for example, the term “signal line” or the like can be changed into the term “power supply line” or the like in some cases. Moreover, the term “potential” that is applied to a wiring can be changed into the term “signal” or the like depending on the situation, for example. Conversely, for example, the term “signal” or the like can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether a current flows therethrough or not. Alternatively, a switch has a function of selecting and changing a current path. For example, an electrical switch or a mechanical switch can be used as the switch. That is, a switch is not limited to a particular element.

Note that as a kind of a switch, there is a switch which is normally in a non-conduction state and brought into a conduction state by controlling a conduction state; such a switch is referred to as an “A contact” in some cases. Furthermore, as another kind of a switch, there is a switch which is normally in a conduction state and brought into a non-conduction state by controlling a conduction state; such a switch is referred to as a “B contact” in some cases.

Examples of an electrical switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. Note that in the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically, and selects a conduction or non-conduction state with the movement of the electrode.

In this specification and the like, the “channel length” of the transistor sometimes refers to, for example, the distance between a source and a drain in a region where a semiconductor (or a portion where a current flows in a semiconductor when a transistor is in an on state) and a gate overlap with each other or the distance between the source and the drain of a region where a channel is formed.

In this specification and the like, the “channel width” of the transistor sometimes refers to, for example, the length of a portion where a source and a drain face each other in a region where a semiconductor (or a portion where a current flows in a semiconductor when a transistor is an on state) and a gate overlap with each other or the length of a portion where a source and a drain face each other in a region where a channel is formed.

In this specification and the like, for example, the terms such as “substrate”, “wafer”, and “die” do not functionally limit these components. For example, the terms such as “substrate,” “wafer,” and “die” can be interchanged with each other depending on the situation in some cases.

In this specification and the like, the term “parallel” does not necessarily mean a state being exactly parallel. Hence, for example, the term “parallel” can be replaced with the term “approximately parallel,” “substantially parallel,” “practically parallel,” or the like as appropriate. In addition, the term “parallel”, “approximately parallel,” “substantially parallel,” or “practically parallel,” may be applied to the case where the angle between two straight lines or planes is greater than or equal to −5° and less than or equal to 5°. Alternatively, these terms may be applied to the case where the angle between two straight lines or planes is greater than or equal to −10° and less than or equal to 10°. Alternatively, these terms may be applied to the case where the angle between two straight lines or planes is greater than or equal to −30° and less than or equal to 30°. Accordingly, the term “parallel” sometimes means a state being “parallel or substantially parallel,” for example. Moreover, the term “perpendicular” does not necessarily mean a state being exactly perpendicular. Hence, for example, the term “perpendicular” can be replaced with the term “approximately perpendicular,” “substantially perpendicular,” “practically perpendicular,” or the like as appropriate. The term “perpendicular”, “approximately perpendicular,” “substantially perpendicular,” or “practically perpendicular,” may be applied to the case where the angle between two straight lines or planes is greater than or equal to 85° and less than or equal to 95°. Alternatively, these terms may be applied to the case where the angle between two straight lines or planes is greater than or equal to 80° and less than or equal to 100°. Alternatively, these terms may be applied to the case where the angle between two straight lines or planes is greater than or equal to 60° and less than or equal to 120°. Accordingly, the term “perpendicular” sometimes means a state being “perpendicular or substantially perpendicular,” for example.

Note that in this specification and the like, the expression “level or substantially level” indicates having the same level from a reference surface (e.g., a flat surface such as a substrate surface) in a cross-sectional view. For example, in a manufacturing process of the semiconductor device, planarization treatment is performed, whereby the surface(s) of a single layer or a plurality of layers are exposed in some cases. In this case, the surfaces on which the planarization treatment has been performed are at the same level as a reference surface. Note that a plurality of layers having the surfaces on which the planarization treatment has been performed are not level with each other in the strict sense in some cases, depending on a treatment apparatus, a treatment method, or a material of the treated surfaces on which the planarization treatment is performed. This case is also regarded as being “level or substantially level” in this specification and the like. For example, the expression “level or substantially level” also includes the case where two layers (here, given as a first layer and a second layer) whose levels with respect to the reference surface are different from each other are provided to have a difference between the top-surface level of the first layer and the top-surface level of the second layer of less than or equal to 20 nm.

Note that in this specification and the like, the expression “end portions are aligned or substantially aligned” means that at least outlines of stacked layers partly overlap with each other in a top view. For example, the case of processing the upper layer and the lower layer with use of the same mask pattern or mask patterns that are partly the same in a manufacturing process of a semiconductor device is included. However, in some cases, the outlines do not exactly overlap with each other and the outline of the upper layer is positioned inward from the outline of the lower layer or the outline of the upper layer is positioned outward from the outline of the lower layer. This case is also described with the expression “end portions are aligned or substantially aligned” in this specification and the like.

Note that in this specification and the like, for example, the terms “identical”, “the same”, “equal”, “uniform”, and the like (including synonyms of these words) used in describing calculation values and measurement values or in describing objects, methods, events, and the like that can be converted into calculation values or measurement values, allow for a margin of error of ±20% unless otherwise specified.

In this specification and the like, an impurity in a semiconductor refers to a component other than a main component of a semiconductor, for example. For example, an element with a concentration of lower than 0.1 atomic % is an impurity. When an impurity is contained in a semiconductor, for example, the density of defect states in a semiconductor is increased, carrier mobility is decreased, or crystallinity is decreased in some cases. In the case where the semiconductor is an oxide semiconductor, examples of an impurity that changes the characteristics of the semiconductor include Group 1 elements, Group 2 elements, Group 13 elements, Group 14 elements, Group 15 elements, or transition metals other than the main components of the oxide semiconductor. Specific examples include hydrogen (included also in water), lithium, sodium, silicon, boron, phosphorus, carbon, and nitrogen. In addition, oxygen vacancies are formed in an oxide semiconductor in some cases by entry of impurities, for example.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like, for example. For example, in the case where a metal oxide is used in a semiconductor including a channel formation region of a transistor, the metal oxide is referred to as an oxide semiconductor in some cases. That is, when a metal oxide is used as a material that can be used for a channel formation region of a transistor that has at least one of an amplifying function, a rectifying function, and a switching function, the metal oxide can be referred to as a metal oxide semiconductor. In addition, the term “OS transistor” can also be referred to as a transistor containing a metal oxide or an oxide semiconductor.

In this specification and the like, a metal oxide containing nitrogen is also collectively referred to as a metal oxide in some cases. A metal oxide containing nitrogen may be referred to as a metal oxynitride.

In the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

### REFERENCE NUMERALS

100: semiconductor device, 101: power management portion, 102: setting information retention portion, 103: power switch portion, 104: data retention portion, 105: backup portion, M101: transistor, M102: transistor, M103: transistor, M104: transistor, M105: transistor, C101: capacitor, C102: capacitor, L101: wiring, L102: wiring, L103: wiring, L104: wiring, 183: layer, 185: layer, M102p: transistor, 200: semiconductor device, 160: register unit, 140: scan flip-flop circuit, 150: backup circuit, CON: control portion, PCS: arithmetic processing portion, PMU: power management unit, PRG: setting register, GRG: general register, PSW: switch circuit group, ISW: switch circuit group, OSW: switch circuit group, PW_gbl: power line group, PW_lcl: power line group, PG_con: wiring group, PG_dat: wiring group, PG_sel: wiring group, D: wiring, Q: wiring, 121a: retention circuit, 121a_1: retention circuit, 121a_2: retention circuit, 121b: retention circuit, 121c: retention circuit, 121d: retention circuit, 122: retention circuit, M111: transistor, M112: transistor, M121: transistor, M122: transistor, M123: transistor, M124: transistor, M125: transistor, M126: transistor, M127: transistor, M128: transistor, C111: capacitor, C112: capacitor, C121: capacitor, CK: wiring, CKB: wiring, DB: wiring, QB: wiring, VDDG: wiring, VSSG: wiring, 141: selector circuit, 142: flip-flop circuit, 151: retention circuit, M151: transistor, M152: transistor, M153: transistor, C151: capacitor, SWP: switch circuit, SWA: switch circuit, SWB: switch circuit, SWC: switch circuit, SD: wiring, Q_I: wiring, SN: wiring, PSE: wiring, PEN: wiring, PEN_I: wiring, PCK1: wiring, PCK2: wiring, PCK_I: wiring, BK: wiring, BK_I: wiring, RV: wiring, RV_I: wiring, SE: wiring, SE_I: wiring, GBK: wiring, SD_IN: wiring, VDDL: wiring, VSSL: wiring, VSSL_I: wiring, M131: transistor, M141: transistor, M142: transistor, M142p: transistor, M143: transistor, M144: transistor, M145: transistor, M146: transistor, M147: transistor, M148: transistor, S141: analog switch, S143: analog switch, S145: analog switch, S146: analog switch, S147: analog switch, IN: wiring, IN1: wiring, IN2: wiring, OUT: wiring, SEL: wiring, SELB: wiring, VSWH: wiring, VSWL: wiring, PMU_A: power management unit, PMU_B: power management unit, PRG_A: setting register, PRG_B: setting register, ISW_A: switch circuit group, ISW_B: switch circuit group, 500: transistor, 500A: transistor, 550: transistor, 600: transistor, 590: capacitor, 590A: capacitor, 690: capacitor

1. A semiconductor device comprising:
a power management portion, a setting information retention portion, a power switch portion, a data retention portion, and a backup portion,
wherein the power management portion and the data retention portion are provided in a first layer,
wherein the setting information retention portion, the power switch portion, and the backup portion are provided in a second layer over the first layer,
wherein the data retention portion is configured to retain data,
wherein the power management portion is configured to supply an instruction for controlling power gating to the power switch portion and to supply, to the setting information retention portion, setting information indicating whether to block power supply to the data retention portion by the power gating,
wherein the setting information retention portion is configured to retain the setting information supplied from the power management portion,
wherein the power switch portion is configured to switch whether to block power supply to the data retention portion on the basis of the instruction and the setting information retained in the setting information retention portion, and
wherein the backup portion is configured to store and retain the data on the basis of a signal supplied from the power management portion.

2. The semiconductor device according to claim 1,
wherein at least part of the backup portion is provided to overlap the data retention portion.

313. The semiconductor device according to claim 1,
wherein at least part of the power switch portion is provided to overlap the data retention portion.

4. The semiconductor device according to claim 1,
wherein transistors included in the setting information retention portion, the power switch portion, and the backup portion include an oxide semiconductor in channel formation regions.

5. A semiconductor device comprising:
a power management portion, a setting information retention portion, a power switch portion, a data retention portion, and a backup portion,
wherein the power management portion and the data retention portion are provided in a first layer,
wherein the setting information retention portion, the power switch portion, and the backup portion are provided in a second layer over the first layer,
wherein the data retention portion is configured to retain data,
wherein the power management portion is configured to supply an instruction for controlling power gating to the power switch portion and to supply, to the setting information retention portion, setting information indicating whether to block power supply to the data retention portion by the power gating,
wherein the setting information retention portion comprises a first transistor and a first capacitor,
wherein one of a source and a drain of the first transistor is electrically connected to one terminal of the first capacitor,
wherein a first potential based on the setting information supplied from the power management portion is supplied to the other of the source and the drain of the first transistor,
wherein a signal which controls a conduction state of the first transistor is supplied from the power management portion to a gate of the first transistor,
wherein a second potential corresponding to the first potential is retained in the one terminal of the first capacitor,
wherein the power switch portion comprises a second transistor and a third transistor,
wherein a gate of the second transistor is electrically connected to one of a source and a drain of the third transistor,
wherein one of a source and a drain of the second transistor is electrically connected to a first wiring through which a third potential is supplied,
wherein the other of the source and the drain of the second transistor is electrically connected to a second wiring for supplying a fourth potential corresponding to the third potential to the data retention portion,
wherein a signal based on the instruction is supplied to the other of the source and the drain of the third transistor,
wherein a signal based on the second potential is supplied to a gate of the third transistor,
wherein the backup portion comprises a fourth transistor, a fifth transistor, and a second capacitor,
wherein one of a source and a drain of the fourth transistor is electrically connected to one of a source and a drain of the fifth transistor and one terminal of the second capacitor,
wherein the other of the source and the drain of the fourth transistor is electrically connected to the data retention portion through a third wiring,
wherein the other of the source and the drain of the fifth transistor is electrically connected to the data retention portion through a fourth wiring,
wherein a signal which controls a conduction state of the fourth transistor is supplied from the power management portion to a gate of the fourth transistor,
wherein a signal which controls a conduction state of the fifth transistor is supplied from the power management portion to a gate of the fifth transistor, and
wherein a fifth potential corresponding to the data is retained in the one terminal of the second capacitor.

6. The semiconductor device according to claim 5,
wherein at least part of the backup portion is provided to overlap the data retention portion.

7. The semiconductor device according to claim 5,
wherein at least part of the power switch portion is provided to overlap the data retention portion.

8. The semiconductor device according to claim 5,
wherein the first transistor, the second transistor, the third transistor, the fourth transistor, and the fifth transistor include an oxide semiconductor in channel formation regions.

9. A semiconductor device comprising:
a power management portion, a setting information retention portion, a power switch portion, a data retention portion, and a backup portion,
wherein the power management portion, the power switch portion, and the data retention portion are provided in a first layer,
wherein the setting information retention portion and the backup portion are provided in a second layer over the first layer,
wherein the data retention portion is configured to retain data,
wherein the power management portion is configured to supply an instruction for controlling power gating to the power switch portion and to supply, to the setting information retention portion, setting information indicating whether to block power supply to the data retention portion by the power gating,
wherein the setting information retention portion is configured to retain the setting information supplied from the power management portion,
wherein the power switch portion is configured to switch whether to block power supply to the data retention portion on the basis of the instruction and the setting information retained in the setting information retention portion, and
wherein the backup portion is configured to store and retain the data on the basis of a signal supplied from the power management portion.

10. The semiconductor device according to claim 9,
wherein at least part of the backup portion is provided to overlap the data retention portion.

11. The semiconductor device according to claim 9,
wherein at least part of the setting information retention portion is provided to overlap the power switch portion.

12. The semiconductor device according to claim 9,
wherein transistors included in the setting information retention portion and the backup portion include an oxide semiconductor in channel formation regions.

13. A semiconductor device comprising:
a power management portion, a setting information retention portion, a power switch portion, a data retention portion, and a backup portion,
wherein the power management portion, the power switch portion, and the data retention portion are provided in a first layer,
wherein the setting information retention portion and the backup portion are provided in a second layer over the first layer,
wherein the data retention portion is configured to retain data,
wherein the power management portion is configured to supply an instruction for controlling power gating to the power switch portion and to supply, to the setting information retention portion, setting information indicating whether to block power supply to the data retention portion by the power gating,
wherein the setting information retention portion comprises a first transistor and a first capacitor,
wherein one of a source and a drain of the first transistor is electrically connected to one terminal of the first capacitor,
wherein a first potential based on the setting information supplied from the power management portion is supplied to the other of the source and the drain of the first transistor,
wherein a signal which controls a conduction state of the first transistor is supplied from the power management portion to a gate of the first transistor,
wherein a second potential corresponding to the first potential is retained in the one terminal of the first capacitor,
wherein the power switch portion comprises a second transistor and a third transistor,
wherein a gate of the second transistor is electrically connected to one of a source and a drain of the third transistor,
wherein one of a source and a drain of the second transistor is electrically connected to a first wiring through which a third potential is supplied,
wherein the other of the source and the drain of the second transistor is electrically connected to a second wiring for supplying a fourth potential corresponding to the third potential to the data retention portion,
wherein a signal based on the instruction is supplied to the other of the source and the drain of the third transistor,
wherein a signal based on the second potential is supplied to a gate of the third transistor,
wherein the backup portion comprises a fourth transistor, a fifth transistor, and a second capacitor,
wherein one of a source and a drain of the fourth transistor is electrically connected to one of a source and a drain of the fifth transistor and one terminal of the second capacitor,
wherein the other of the source and the drain of the fourth transistor is electrically connected to the data retention portion through a third wiring,
wherein the other of the source and the drain of the fifth transistor is electrically connected to the data retention portion through a fourth wiring,
wherein a signal which controls a conduction state of the fourth transistor is supplied from the power management portion to a gate of the fourth transistor,
wherein a signal which controls a conduction state of the fifth transistor is supplied from the power management portion to a gate of the fifth transistor, and
wherein a fifth potential corresponding to the data is retained in the one terminal of the second capacitor.

14. The semiconductor device according to claim 13,
wherein at least part of the backup portion is provided to overlap the data retention portion.

15. The semiconductor device according to claim 13,
wherein at least part of the setting information retention portion is provided to overlap the power switch portion.

16. The semiconductor device according to claim 13,
wherein the first transistor, the fourth transistor, and the fifth transistor include an oxide semiconductor in channel formation regions.
